(19) United States
(12) Patent Application Publication
(10) Pub. No.: US 2024/0431198 A1
(43) Pub. Date: Dec. 26, 2024

(54) ORGANIC ELECTROLUMINESCENT MATERIALS AND DEVICES

(71) Applicants: The University of Southern California, Los Angeles, CA (US); Universal Display Corporation, Ewing, NJ (US)

(72) Inventors: Wei Wei, Los Angeles, CA (US); Jie Ma, Los Angeles, CA (US); Jonas Schaab, Los Angeles, CA (US); Peter I. Djurovich, Los Angeles, CA (US); Mark E. Thompson, Los Angeles, CA (US); Jason Brooks, Ewing, NJ (US)

(21) Appl. No.: 18/740,886

(22) Filed: Jun. 12, 2024

Related U.S. Application Data
(60) Provisional application No. 63/507,773, filed on Jun. 13, 2023.

(51) Int. Cl. H10K 85/40; H10K 50/12; H10K 85/30; H10K 85/60; H10K 101/25

(52) U.S. Cl. CPC H10K 85/40; H10K 50/12; H10K 85/324; H10K 85/342; H10K 85/346; H10K 85/348; H10K 85/371; H10K 85/381; H10K 85/623; H10K 85/633; H10K 85/636; H10K 85/653; H10K 85/654; H10K 85/655; H10K 85/6572; H10K 85/6574; H10K 85/6576; H10K 2101/25

(57) ABSTRACT

Provided are compounds of Formula I wherein at least one of R^{A}, R^{B}, R^{C}, and R^{D} represents a group of Formula A. Also provided are formulations comprising these compounds. Further provided are OLEDs and related consumer products that utilize these compounds.

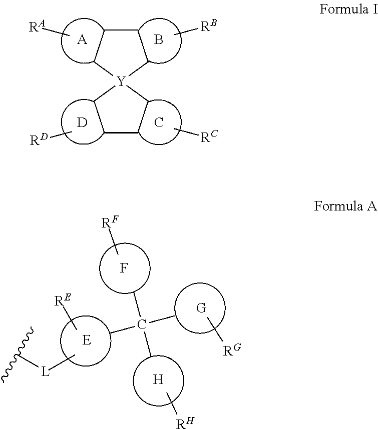

### CROSS-REFERENCE TO RELATED APPLICATIONS

This application claims priority under 35 U.S.C. § 119(e) to U.S. Provisional Application No. 63/507,773, filed Jun. 13, 2023, the entire contents of which are incorporated herein by reference FIELD

The present disclosure generally relates to organometallic compounds and formulations and their various uses including as hosts or emitters in devices such as organic light emitting diodes and related electronic devices.

### BACKGROUND

Opto-electronic devices that make use of organic materials are becoming increasingly desirable for various reasons. Many of the materials used to make such devices are relatively inexpensive, so organic opto-electronic devices have the potential for cost advantages over inorganic devices. In addition, the inherent properties of organic materials, such as their flexibility, may make them well suited for particular applications such as fabrication on a flexible substrate. Examples of organic opto-electronic devices include organic light emitting diodes/devices (OLEDs), organic phototransistors, organic photovoltaic cells, and organic photodetectors. For OLEDs, the organic materials may have performance advantages over conventional materials.

OLEDs make use of thin organic films that emit light when voltage is applied across the device. OLEDs are becoming an increasingly interesting technology for use in applications such as flat panel displays, illumination, and backlighting.

One application for phosphorescent emissive molecules is a full color display. Industry standards for such a display call for pixels adapted to emit particular colors, referred to as “saturated” colors. In particular, these standards call for saturated red, green, and blue pixels. Alternatively, the OLED can be designed to emit white light.

In conventional liquid crystal displays emission from a white backlight is filtered using absorption filters to produce red, green and blue emission. The same technique can also be used with OLEDs. The white OLED can be either a single emissive layer (EML) device or a stack structure. Color may be measured using CIE coordinates, which are well known to the art.

### SUMMARY

In one aspect, the present disclosure provides a compound of Formula I:

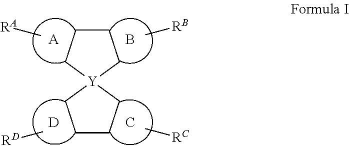

wherein ring A, ring B, ring C, and ring D are each independently a 5- or 6-membered aromatic or heteroaromatic ring;
Y is Si or C;
R^{A}, R^{B}, R^{C}, and R^{D} each represents mono to the maximum allowable substitution, or no substitution;
each R^{A}, R^{B}, R^{C}, and R^{D} are independently hydrogen or a substituent selected from the group consisting of deuterium, alkyl, haloalkyl, cycloalkyl, heteroalkyl, heterocycloalkyl, arylalkyl, alkoxy, aryloxy, silyl, alkenyl, cyano, cycloalkenyl, heteroalkenyl, alkynyl, aryl, heteroaryl, acyl, carboxylic acid, ether, ester, nitro, nitrile, isonitrile, sulfanyl, sulfinyl, sulfonyl, phosphino, and combinations thereof; wherein any two adjacent R^{A}, R^{B}, R^{C}, and R^{D} may optionally join to form a fused ring, which is optionally further substituted;
wherein at least one of R^{A}, R^{B}, R^{C}, and R^{D} represents a group of Formula A:

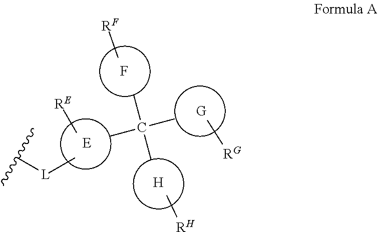

wherein ring E, ring F, ring G, and ring H are each independently an aromatic or heteroaromatic ring;
the wavy line represents connection to Formula I;
L represents a divalent linker or a single bond; wherein when L represents a single bond, ring E is directly connected to Formula I;
R^{E}, R^{F}, R^{G}, and R^{H} each represents mono to the maximum allowable substitution, or no substitution; each R^{E}, R^{F}, R^{G}, and R^{H} are independently hydrogen or a substituent selected from the group consisting of deuterium, halogen, alkyl, cycloalkyl, heteroalkyl, heterocycloalkyl, arylalkyl, alkoxy, aryloxy, amino, silyl, alkenyl, cyano, cycloalkenyl, heteroalkenyl, alkynyl, aryl, heteroaryl, acyl, carboxylic acid, ether, ester, nitro, nitrile, isonitrile, sulfanyl, sulfinyl, sulfonyl, phosphino, and combinations thereof; provided that no two adjacent R^{E}, R^{F}, R^{G}, and R^{H} join to form a fused ring.

In another aspect, the present disclosure provides a formulation comprising the compound of Formula I as described herein.

In yet another aspect, the present disclosure provides an OLED having an organic layer comprising the compound of Formula I as described herein.

In yet another aspect, the present disclosure provides a consumer product comprising an OLED with an organic layer comprising the compound of Formula I as described herein.

### BRIEF DESCRIPTION OF THE DRAWINGS

FIG. 1 shows an organic light emitting device.

FIG. 2 shows an inverted organic light emitting device that does not have a separate electron transport layer.

FIG. 3 shows X-ray crystal structures of SB—C(left) and SB—Si (right).

FIG. 4 depicts the packing of Ph₃CSBFL (left) and Ph₃SiSBFL (right) molecules in a unit cell.

FIG. 5 depicts the calculated Hirshfeld surfaces of Ph₃CSBFL and Ph₃SiSBFL, which are shown in different viewing angles (front, left and back).

FIG. 6 shows intermolecular interactions between molecules in SB—C and SB—Si crystals calculated using Crystal Explorer software package. Different colors indicate different types of close intermolecular interactions (C—H, C—C or H—H). The x-axis shows the percentage of each interaction and is tabulated in the table. An illustration of a Hirshfeld surface for SB—C also shown.

FIG. 7 depicts DFT-calculated HOMO (solid) and LUMO (mesh) surface and levels of Ph₃CSBFL and Ph₃SiSBFL. Calculated values are compared to the measured values.

FIG. 8 depicts the cyclic voltammetry curves of Ph₃SiSBFL and Ph₃CSBFL.

FIG. 9 depicts the differential scanning calorimetric (DSC) thermograms of Ph₃SiSBFL and Ph₃CSBFL.

FIG. 10 depicts the absorption and emission spectra of SB—C and SB—Si in 2-MeTHF solution.

FIG. 11 depicts the excitation and emission spectra of SB—C and SB—Si from sublimed crystals.

FIG. 12 depicts the absorption and photoluminescence (PL) spectra of SB—C and SB—Si from amorphous thin films (40 nm).

FIG. 13 shows plots of the voltage dependence of EL spectra of the undoped devices.

FIG. 14 is a plot of the EL spectra at 9 V of undoped SB—C and SB—Si devices.

FIG. 15 is a J-V plot of undoped SB—C and SB—Si devices.

FIG. 16 is a plot of the EL spectra of Ir(ppy)₃ SB—C and SB—Si devices.

FIG. 17 is a J-V plot of Ir(ppy)₃ SB—C and SB—Si devices.

FIG. 18 is an L-V plot of Ir(ppy)₃ SB—C and SB—Si devices.

FIG. 19 is an EQE-current density plot of Ir(ppy)₃ SB—C and SB—Si devices.

FIG. 20 is a plot of the EL spectra of Ir(tpz)₃ SB—C and SB—Si devices.

FIG. 21 is a J-V plot of Ir(tpz)₃ SB—C and SB—Si devices.

FIG. 22 is an L-Vplot of Ir(tpz)₃ SB—C and SB—Si devices.

FIG. 23 is an EQE-current density plot of Ir(tpz)₃ SB—C and SB—Si devices.

### DETAILED DESCRIPTION

### A. Terminology

Unless otherwise specified, the below terms used herein are defined as follows:

As used herein, the term “organic” includes polymeric materials as well as small molecule organic materials that may be used to fabricate organic opto-electronic devices. “Small molecule” refers to any organic material that is not a polymer, and “small molecules” may actually be quite large. Small molecules may include repeat units in some circumstances. For example, using a long chain alkyl group as a substituent does not remove a molecule from the “small molecule” class. Small molecules may also be incorporated into polymers, for example as a pendent group on a polymer backbone or as a part of the backbone. Small molecules may also serve as the core moiety of a dendrimer, which consists of a series of chemical shells built on the core moiety. The core moiety of a dendrimer may be a fluorescent or phosphorescent small molecule emitter. A dendrimer may be a “small molecule,” and it is believed that all dendrimers currently used in the field of OLEDs are small molecules.

As used herein, “top” means furthest away from the substrate, while “bottom” means closest to the substrate. Where a first layer is described as “disposed over” a second layer, the first layer is disposed further away from substrate. There may be other layers between the first and second layer, unless it is specified that the first layer is “in contact with” the second layer. For example, a cathode may be described as “disposed over” an anode, even though there are various organic layers in between.

As used herein, “solution processable” means capable of being dissolved, dispersed, or transported in and/or deposited from a liquid medium, either in solution or suspension form.

A ligand may be referred to as “photoactive” when it is believed that the ligand directly contributes to the photoactive properties of an emissive material. A ligand may be referred to as “ancillary” when it is believed that the ligand does not contribute to the photoactive properties of an emissive material, although an ancillary ligand may alter the properties of a photoactive ligand.

As used herein, and as would be generally understood by one skilled in the art, a first “Highest Occupied Molecular Orbital” (HOMO) or “Lowest Unoccupied Molecular Orbital” (LUMO) energy level is “greater than” or “higher than” a second HOMO or LUMO energy level if the first energy level is closer to the vacuum energy level. Since ionization potentials (IP) are measured as a negative energy relative to a vacuum level, a higher HOMO energy level corresponds to an IP having a smaller absolute value (an IP that is less negative). Similarly, a higher LUMO energy level corresponds to an electron affinity (EA) having a smaller absolute value (an EA that is less negative). On a conventional energy level diagram, with the vacuum level at the top, the LUMO energy level of a material is higher than the HOMO energy level of the same material. A “higher” HOMO or LUMO energy level appears closer to the top of such a diagram than a “lower” HOMO or LUMO energy level.

As used herein, and as would be generally understood by one skilled in the art, a first work function is “greater than” or “higher than” a second work function if the first work function has a higher absolute value. Because work functions are generally measured as negative numbers relative to vacuum level, this means that a “higher” work function is more negative. On a conventional energy level diagram, with the vacuum level at the top, a “higher” work function is illustrated as further away from the vacuum level in the downward direction. Thus, the definitions of HOMO and LUMO energy levels follow a different convention than work functions.

The terms “halo,” “halogen,” and “halide” are used interchangeably and refer to fluorine, chlorine, bromine, and iodine.

The term “acyl” refers to a substituted carbonyl radical (C(O)—Rₛ).

The term “ester” refers to a substituted oxycarbonyl (—O—C(O)—Rₛ or —C(O)—O—Rs) radical.

The term “ether” refers to an —ORₛ radical.

The terms “sulfanyl” or “thio-ether” are used interchangeably and refer to a —SRₛ radical.

The terms “selenyl” refers to a —SeRₛ radical.

The term “sulfinyl” refers to a —S(O)—Rₛ radical.

The term “sulfonyl” refers to a —SO₂—Rₛ radical.

The term “phosphino” refers to a —P(Rₛ)₃ radical, wherein each Rₛ can be same or different.

The term “silyl” refers to a —Si(Rₛ)₃ radical, wherein each Rₛ can be same or different.

The term “germyl” refers to a —Ge(Rₛ)₃ radical, wherein each Rₛ can be same or different.

The term “boryl” refers to a —B(Rₛ)₂ radical or its Lewis adduct —B(Rₛ)₃ radical, wherein Rₛ can be same or different.

In each of the above, Rₛ can be hydrogen or a substituent selected from the group consisting of deuterium, halogen, alkyl, cycloalkyl, heteroalkyl, heterocycloalkyl, arylalkyl, alkoxy, aryloxy, amino, silyl, alkenyl, cycloalkenyl, heteroalkenyl, alkynyl, aryl, heteroaryl, and combination thereof. Preferred Rₛ is selected from the group consisting of alkyl, cycloalkyl, aryl, heteroaryl, and combination thereof.

The term “alkyl” refers to and includes both straight and branched chain alkyl radicals. Preferred alkyl groups are those containing from one to fifteen carbon atoms and includes methyl, ethyl, propyl, 1-methylethyl, butyl, 1-methylpropyl, 2-methylpropyl, pentyl, 1-methylbutyl, 2-methylbutyl, 3-methylbutyl, 1,1-dimethylpropyl, 1,2-dimethylpropyl, 2,2-dimethylpropyl, and the like. Additionally, the alkyl group may be optionally substituted.

The term “cycloalkyl” refers to and includes monocyclic, polycyclic, and spiro alkyl radicals. Preferred cycloalkyl groups are those containing 3 to 12 ring carbon atoms and includes cyclopropyl, cyclopentyl, cyclohexyl, bicyclo[3.1.1]heptyl, spiro[4.5]decyl, spiro[5.5]undecyl, adamantyl, and the like. Additionally, the cycloalkyl group may be optionally substituted.

The terms “heteroalkyl” or “heterocycloalkyl” refer to an alkyl or a cycloalkyl radical, respectively, having at least one carbon atom replaced by a heteroatom. Optionally the at least one heteroatom is selected from O, S, N, P, B, Si and Se, preferably, O, S or N. Additionally, the heteroalkyl or heterocycloalkyl group may be optionally substituted.

The term “alkenyl” refers to and includes both straight and branched chain alkene radicals. Alkenyl groups are essentially alkyl groups that include at least one carbon-carbon double bond in the alkyl chain. Cycloalkenyl groups are essentially cycloalkyl groups that include at least one carbon-carbon double bond in the cycloalkyl ring.

The term “heteroalkenyl” as used herein refers to an alkenyl radical having at least one carbon atom replaced by a heteroatom. Optionally the at least one heteroatom is selected from O, S, N, P, B, Si, and Se, preferably, O, S, or N. Preferred alkenyl, cycloalkenyl, or heteroalkenyl groups are those containing two to fifteen carbon atoms.

Additionally, the alkenyl, cycloalkenyl, or heteroalkenyl group may be optionally substituted.

The term “alkynyl” refers to and includes both straight and branched chain alkyne radicals. Alkynyl groups are essentially alkyl groups that include at least one carbon-carbon triple bond in the alkyl chain. Preferred alkynyl groups are those containing two to fifteen carbon atoms. Additionally, the alkynyl group may be optionally substituted.

The terms “aralkyl” or “arylalkyl” are used interchangeably and refer to an alkyl group that is substituted with an aryl group. Additionally, the aralkyl group may be optionally substituted.

The term “heterocyclic group” refers to and includes aromatic and non-aromatic cyclic radicals containing at least one heteroatom. Optionally the at least one heteroatom is selected from O, S, N, P, B, Si, and Se, preferably, O, S, or N. Hetero-aromatic cyclic radicals may be used interchangeably with heteroaryl. Preferred hetero-non-aromatic cyclic groups are those containing 3 to 7 ring atoms which includes at least one hetero atom, and includes cyclic amines such as morpholino, piperidino, pyrrolidino, and the like, and cyclic ethers/thio-ethers, such as tetrahydrofuran, tetrahydropyran, tetrahydrothiophene, and the like. Additionally, the heterocyclic group may be optionally substituted.

The term “aryl” refers to and includes both single-ring aromatic hydrocarbyl groups and polycyclic aromatic ring systems. The polycyclic rings may have two or more rings in which two carbons are common to two adjoining rings (the rings are “fused”) wherein at least one of the rings is an aromatic hydrocarbyl group, e.g., the other rings can be cycloalkyls, cycloalkenyls, aryl, heterocycles, and/or heteroaryls. Preferred aryl groups are those containing six to thirty carbon atoms, preferably six to twenty carbon atoms, more preferably six to twelve carbon atoms. Especially preferred is an aryl group having six carbons, ten carbons or twelve carbons. Suitable aryl groups include phenyl, biphenyl, triphenyl, triphenylene, tetraphenylene, naphthalene, anthracene, phenalene, phenanthrene, fluorene, pyrene, chrysene, perylene, and azulene, preferably phenyl, biphenyl, triphenyl, triphenylene, fluorene, and naphthalene. Additionally, the aryl group may be optionally substituted.

The term “heteroaryl” refers to and includes both single-ring aromatic groups and polycyclic aromatic ring systems that include at least one heteroatom. The heteroatoms include, but are not limited to O, S, N, P, B, Si, and Se. In many instances, O, S, or N are the preferred heteroatoms. Hetero-single ring aromatic systems are preferably single rings with 5 or 6 ring atoms, and the ring can have from one to six heteroatoms. The hetero-polycyclic ring systems can have two or more rings in which two atoms are common to two adjoining rings (the rings are “fused”) wherein at least one of the rings is a heteroaryl, e.g., the other rings can be cycloalkyls, cycloalkenyls, aryl, heterocycles, and/or heteroaryls. The hetero-polycyclic aromatic ring systems can have from one to six heteroatoms per ring of the polycyclic aromatic ring system. Preferred heteroaryl groups are those containing three to thirty carbon atoms, preferably three to twenty carbon atoms, more preferably three to twelve carbon atoms. Suitable heteroaryl groups include dibenzothiophene, dibenzofuran, dibenzoselenophene, furan, thiophene, benzofuran, benzothiophene, benzoselenophene, carbazole, indolocarbazole, pyridylindole, pyrrolodipyridine, pyrazole, imidazole, triazole, oxazole, thiazole, oxadiazole, oxatriazole, dioxazole, thiadiazole, pyridine, pyridazine, pyrimidine, pyrazine, triazine, oxazine, oxathiazine, oxadiazine, indole, benzimidazole, indazole, indoxazine, benzoxazole, benzisoxazole, benzothiazole, quinoline, isoquinoline, cinnoline, quinazoline, quinoxaline, naphthyridine, phthalazine, pteridine, xanthene, acridine, phenazine, phenothiazine, phenoxazine, benzofuropyridine, furodipyridine, benzothienopyridine, thienodipyridine, benzoselenophenopyridine, and selenophenodipyridine, preferably dibenzothiophene, dibenzofuran, dibenzoselenophene, carbazole, indolocarbazole, imidazole, pyridine, triazine, benzimidazole, 1,2-azaborine, 1,3-azaborine, 1,4-azaborine, borazine, and aza-analogs thereof. Additionally, the heteroaryl group may be optionally substituted.

Of the aryl and heteroaryl groups listed above, the groups of triphenylene, naphthalene, anthracene, dibenzothiophene, dibenzofuran, dibenzoselenophene, carbazole, indolocarbazole, imidazole, pyridine, pyrazine, pyrimidine, triazine, and benzimidazole, and the respective aza-analogs of each thereof are of particular interest.

The terms alkyl, cycloalkyl, heteroalkyl, heterocycloalkyl, alkenyl, cycloalkenyl, heteroalkenyl, alkynyl, aralkyl, heterocyclic group, aryl, and heteroaryl, as used herein, are independently unsubstituted, or independently substituted, with one or more general substituents.

In many instances, the general substituents are selected from the group consisting of deuterium, halogen, alkyl, cycloalkyl, heteroalkyl, heterocycloalkyl, arylalkyl, alkoxy, aryloxy, amino, silyl, germyl, alkenyl, cycloalkenyl, heteroalkenyl, alkynyl, aryl, heteroaryl, acyl, carboxylic acid, ether, ester, nitrile, isonitrile, sulfanyl, selenyl, sulfinyl, sulfonyl, phosphino, boryl, and combinations thereof.

In some instances, the preferred general substituents are selected from the group consisting of deuterium, fluorine, alkyl, cycloalkyl, heteroalkyl, alkoxy, aryloxy, amino, silyl, germyl, boryl, alkenyl, cycloalkenyl, heteroalkenyl, aryl, heteroaryl, nitrile, isonitrile, sulfanyl, and combinations thereof.

In some instances, the more preferred general substituents are selected from the group consisting of deuterium, fluorine, alkyl, cycloalkyl, alkoxy, aryloxy, amino, silyl, boryl, aryl, heteroaryl, sulfanyl, and combinations thereof.

In yet other instances, the most preferred general substituents are selected from the group consisting of deuterium, fluorine, alkyl, cycloalkyl, aryl, heteroaryl, and combinations thereof.

The terms “substituted” and “substitution” refer to a substituent other than H that is bonded to the relevant position, e.g., a carbon or nitrogen. For example, when R¹ represents mono-substitution, then one R¹ must be other than H (i.e., a substitution). Similarly, when R¹ represents di-substitution, then two of R¹ must be other than H. Similarly, when R¹ represents zero or no substitution, R¹, for example, can be a hydrogen for available valencies of ring atoms, as in carbon atoms for benzene and the nitrogen atom in pyrrole, or simply represents nothing for ring atoms with fully filled valencies, e.g., the nitrogen atom in pyridine. The maximum number of substitutions possible in a ring structure will depend on the total number of available valencies in the ring atoms.

As used herein, “combinations thereof” indicates that one or more members of the applicable list are combined to form a known or chemically stable arrangement that one of ordinary skill in the art can envision from the applicable list. For example, an alkyl and deuterium can be combined to form a partial or fully deuterated alkyl group; a halogen and alkyl can be combined to form a halogenated alkyl substituent; and a halogen, alkyl, and aryl can be combined to form a halogenated arylalkyl. In one instance, the term substitution includes a combination of two to four of the listed groups. In another instance, the term substitution includes a combination of two to three groups. In yet another instance, the term substitution includes a combination of two groups. Preferred combinations of substituent groups are those that contain up to fifty atoms that are not hydrogen or deuterium, or those which include up to forty atoms that are not hydrogen or deuterium, or those that include up to thirty atoms that are not hydrogen or deuterium. In many instances, a preferred combination of substituent groups will include up to twenty atoms that are not hydrogen or deuterium.

The “aza” designation in the fragments described herein, i.e. aza-dibenzofuran, aza-dibenzothiophene, etc. means that one or more of the C—H groups in the respective aromatic ring can be replaced by a nitrogen atom, for example, and without any limitation, azatriphenylene encompasses both dibenzo[fh]quinoxaline and dibenzo[fh]quinoline. One of ordinary skill in the art can readily envision other nitrogen analogs of the aza-derivatives described above, and all such analogs are intended to be encompassed by the terms as set forth herein.

As used herein, “deuterium” refers to an isotope of hydrogen. Deuterated compounds can be readily prepared using methods known in the art. For example, U.S. Pat. No. 8,557,400, Patent Pub. No. WO 2006/095951, and U.S. Pat. Application Pub. No. US 2011/0037057, which are hereby incorporated by reference in their entireties, describe the making of deuterium-substituted organometallic complexes. Further reference is made to Ming Yan, et al., Tetrahedron 2015, 71, 1425-30 and Atzrodt et al., Angew. Chem. Int. Ed. (Reviews) 2007, 46, 7744-65, which are incorporated by reference in their entireties, describe the deuteration of the methylene hydrogens in benzyl amines and efficient pathways to replace aromatic ring hydrogens with deuterium, respectively.

It is to be understood that when a molecular fragment is described as being a substituent or otherwise attached to another moiety, its name may be written as if it were a fragment (e.g. phenyl, phenylene, naphthyl, dibenzofuryl) or as if it were the whole molecule (e.g. benzene, naphthalene, dibenzofuran). As used herein, these different ways of designating a substituent or attached fragment are considered to be equivalent.

In some instance, a pair of adjacent substituents can be optionally joined or fused into a ring. The preferred ring is a five, six, or seven-membered carbocyclic or heterocyclic ring, includes both instances where the portion of the ring formed by the pair of substituents is saturated and where the portion of the ring formed by the pair of substituents is unsaturated. As used herein, “adjacent” means that the two substituents involved can be on the same ring next to each other, or on two neighboring rings having the two closest available substitutable positions, such as 2, 2′ positions in a biphenyl, or 1, 8 position in a naphthalene, as long as they can form a stable fused ring system.

### B. The Compounds of the Present Disclosure

In one aspect, the present disclosure provides a compound of Formula I:

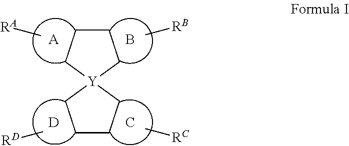

wherein ring A, ring B, ring C, and ring D are each independently a 5- or 6-membered aromatic or heteroaromatic ring;
Y is Si or C;
R^{A}, R^{B}, R^{C}, and R^{D} each represents mono to the maximum allowable substitution, or no substitution;
each R^{A}, R^{B}, R^{C}, and R^{D} are independently hydrogen or a substituent selected from the group consisting of deuterium, alkyl, haloalkyl, cycloalkyl, heteroalkyl, heterocycloalkyl, arylalkyl, alkoxy, aryloxy, silyl, alkenyl, cyano, cycloalkenyl, heteroalkenyl, alkynyl, aryl, heteroaryl, acyl, carboxylic acid, ether, ester, nitro, nitrile, isonitrile, sulfanyl, sulfinyl, sulfonyl, phosphino, and combinations thereof; wherein any two adjacent R^{A}, R^{B}, R^{C}, and R^{D} may optionally join to form a fused ring, which is optionally further substituted;
wherein at least one of R^{A}, R^{B}, R^{C}, and R^{D} represents a group of Formula A:

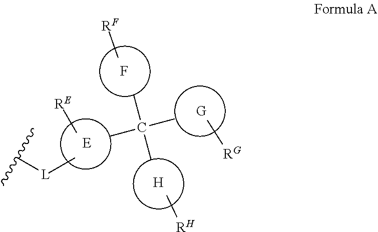

wherein ring E, ring F, ring G, and ring H are each independently an aromatic or heteroaromatic ring;
the wavy line represents connection to Formula I;
L represents a divalent linker or a single bond; wherein when L represents a single bond, ring E is directly connected to Formula I;
R^{E}, R^{F}, R^{G}, and R^{H} each represents mono to the maximum allowable substitution, or no substitution; each R^{E}, R^{F}, R^{G}, and R^{H} are independently hydrogen or a substituent selected from the group consisting of deuterium, halogen, alkyl, cycloalkyl, heteroalkyl, heterocycloalkyl, arylalkyl, alkoxy, aryloxy, amino, silyl, alkenyl, cyano, cycloalkenyl, heteroalkenyl, alkynyl, aryl, heteroaryl, acyl, carboxylic acid, ether, ester, nitro, nitrile, isonitrile, sulfanyl, sulfinyl, sulfonyl, phosphino, and combinations thereof; provided that no two adjacent R^{E}, R^{F}, R^{G}, and R^{H} join to form a fused ring.

In some embodiments, each of ring A, ring B, ring C, and ring D is a 6-membered aromatic ring. In some embodiments, at least one of ring A, ring B, ring C, and ring D is a 5-membered aromatic ring. In some embodiments, each of ring A, ring B, ring C, and ring D is a phenyl ring. In some embodiments, at least one of ring A, ring B, ring C, or ring D is a pyridine ring.

In some embodiments, each of ring E, ring F, ring G, and ring H is a 6-membered aromatic ring. In some embodiments, at least one of ring E, ring F, ring G, and ring H is a 5-membered aromatic ring. In some embodiments, each of ring E, ring F, ring G, and ring H is a phenyl ring. In some embodiments, at least one of ring E, ring F, ring G, or ring H is a pyridine ring.

In some embodiments, each of ring A, ring B, ring C, ring D, ring E, ring F, ring G, and ring H may be benzene, pyridine, pyrimidine, pyridazine, pyrazine, triazine, imidazole, pyrazole, pyrrole, oxazole, furan, thiophene, triazole, or thiazole. In some embodiments, each of ring A, ring B, ring C, ring D, ring E, ring F, ring G, and ring H may be benzene, or pyridine.

In some embodiments, at least one of R^{A}, R^{B}, R^{C}, or R^{D} is deuterium, F, an alkyl, cycloalkyl, aryl, heteroaryl, or their combinations. In some embodiments, at least one of R^{E}, R^{F}, R^{G}, and R^{H} is deuterium, F, an alkyl, cycloalkyl, aryl, heteroaryl, or their combinations.

In some embodiments, at least one of R^{A}, R^{B}, R^{C}, or R^{D} is deuterium. In some embodiments, all of R^{A}are deuterium. In some embodiments, all of R^{B} are deuterium. In some embodiments, all of R^{C} are deuterium. In some embodiments, all of R^{D} are deuterium. In some embodiments, all of R^{A}, R^{B}, R^{C}, and R^{D} are deuterium. In some embodiments, at least one of R^{E}, R^{F}, R^{G}, or R^{H} is deuterium. In some embodiments, all of R^{E} are deuterium. In some embodiments, all of R^{F} are deuterium. In some embodiments, all ofRG are deuterium. In some embodiments, all of R^{H} are deuterium. In some embodiments, all of R^{E}, R^{F}, R^{G}, and R^{H} are deuterium. In some embodiments, all of R^{A}, R^{B}, R^{C}, R^{D}, R^{E}, R^{F}, R^{G}, and R^{H} are deuterium.

In some embodiments, two R^{A} are joined to form a ring fused to ring A. In some embodiments, two R^{B} are joined to form a ring fused to ring B. In some embodiments, two R^{C} are joined to form a ring fused to ring C. In some embodiments, two R^{D} are joined to form a ring fused to ring D. In some embodiments, two R^{E} are joined to form a ring fused to ring E. In some embodiments, two R^{F} are joined to form a ring fused to ring F. In some embodiments, two R^{G} are joined to form a ring fused to ring G. In some embodiments, two R^{H} are joined to form a ring fused to ring H. In some such embodiments, the fused ring structure may be naphthalene, quinoline, isoquinoline, quinazoline, benzofuran, benzoxazole, benzothiophene, benzothiazole, benzoselenophene, indene, indole, benzimidazole, carbazole, dibenzofuran, dibenzothiophene, quinoxaline, phthalazine, phenanthrene, phenanthridine, or fluorene.

In one embodiment, each of ring A, ring B, ring C, ring D, ring E, ring F, ring G, and ring H represents a phenyl ring.

In one embodiment, Y is C. In one embodiment, Y is Si.

In some embodiments, L is a direct bond. In some embodiments, L is a divalent linker selected from BR, BRR′, NR, PR, P(O)R, O, S, Se, C═O, C═S, C═Se, C═NR, C═CRR′, S═O, SO₂, CRR′, SiRR′, GeRR′, alkylene, cycloalkyl, aryl, cycloalkylene, arylene, heteroarylene, and combinations thereof; wherein R and R′ are each independently hydrogen or a substituent selected from the group consisting of deuterium, halogen, alkyl, cycloalkyl, heteroalkyl, heterocycloalkyl, arylalkyl, alkoxy, aryloxy, amino, silyl, alkenyl, cyano, cycloalkenyl, heteroalkenyl, alkynyl, aryl, heteroaryl, acyl, carboxylic acid, ether, ester, nitro, nitrile, isonitrile, sulfanyl, sulfinyl, sulfonyl, phosphino, and combinations thereof.

In some embodiments, the compound may be represented by one of the following structures:

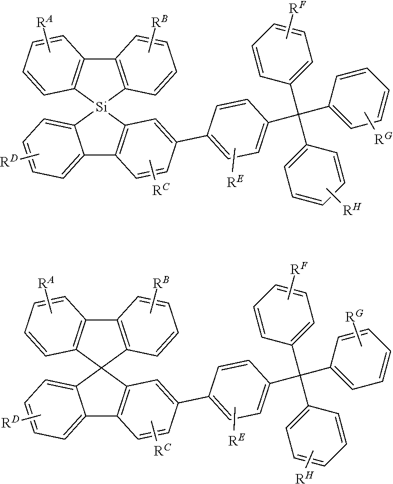

wherein the variables are the same as previously defined. In some embodiments, at least one of R^{A}, R^{B}, R^{C}, or R^{D} is deuterium. In some embodiments, all of R^{A}, R^{B}, R^{C}, and R^{D} are deuterium. In some embodiments, at least one of R^{E}, R^{F}, R^{G}, or R^{H} is deuterium. In some embodiments, all of R^{E}, R^{F}, R^{G}, and R^{H} are deuterium. In some embodiments, all of R^{A}, R^{B}, R^{C}, R^{D}, R^{E}, R^{F}, R^{G}, and R^{H} are deuterium.

In one embodiment, the compound is represented by one of the following structures:

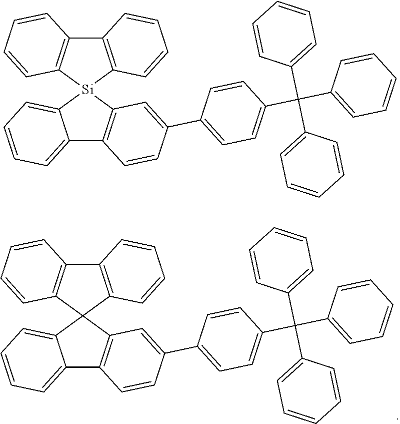

In some embodiments, the compound of Formula I described herein can be at least 30% deuterated, at least 40% deuterated, at least 50% deuterated, at least 60% deuterated, at least 70% deuterated, at least 80% deuterated, at least 90% deuterated, at least 95% deuterated, at least 99% deuterated, or 100% deuterated. As used herein, percent deuteration has its ordinary meaning and includes the percent of possible hydrogen atoms (e.g., positions that are hydrogen, deuterium, or halogen) that are replaced by deuterium atoms.).

### C. The OLEDs and the Devices of the Present Disclosure

In another aspect, the present disclosure also provides an OLED device comprising a first organic layer that contains a compound as disclosed in the above compounds section of the present disclosure.

In some embodiments, the first organic layer comprises a compound of Formula I.

In one embodiment, the organic layer is selected from the group consisting of a hole injection layer, hole transporting layer, electron blocking layer, emissive layer, hole blocking layer, electron transport layer, and electron injection layer.

In some embodiments, the compound may be a host, and the first organic layer may be an emissive layer that comprises a phosphorescent emitter.

In some embodiments, the phosphorescent emitter may be a transition metal complex having at least one ligand or part of the ligand if the ligand is more than bidentate selected from the group consisting of:

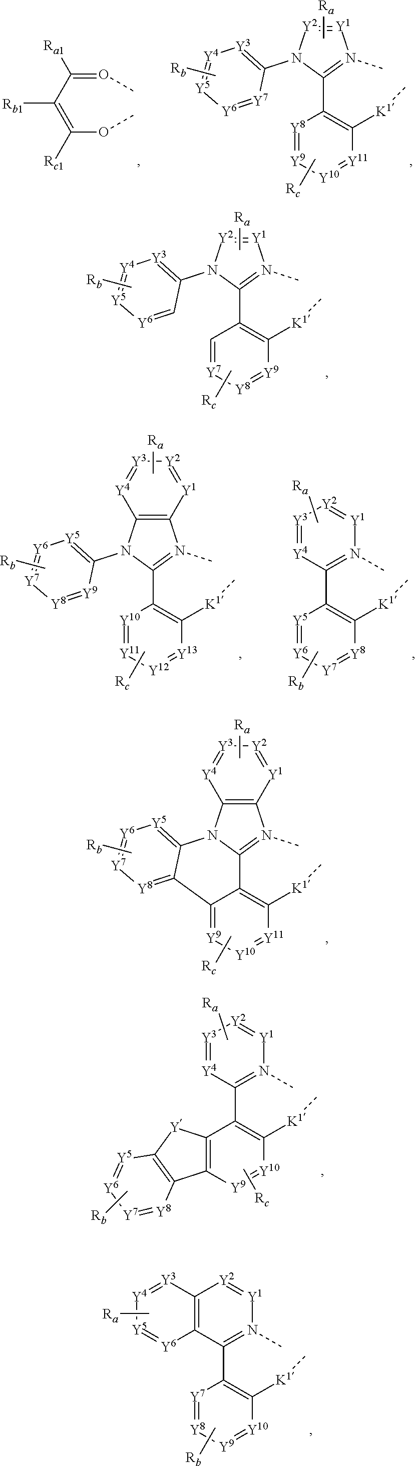

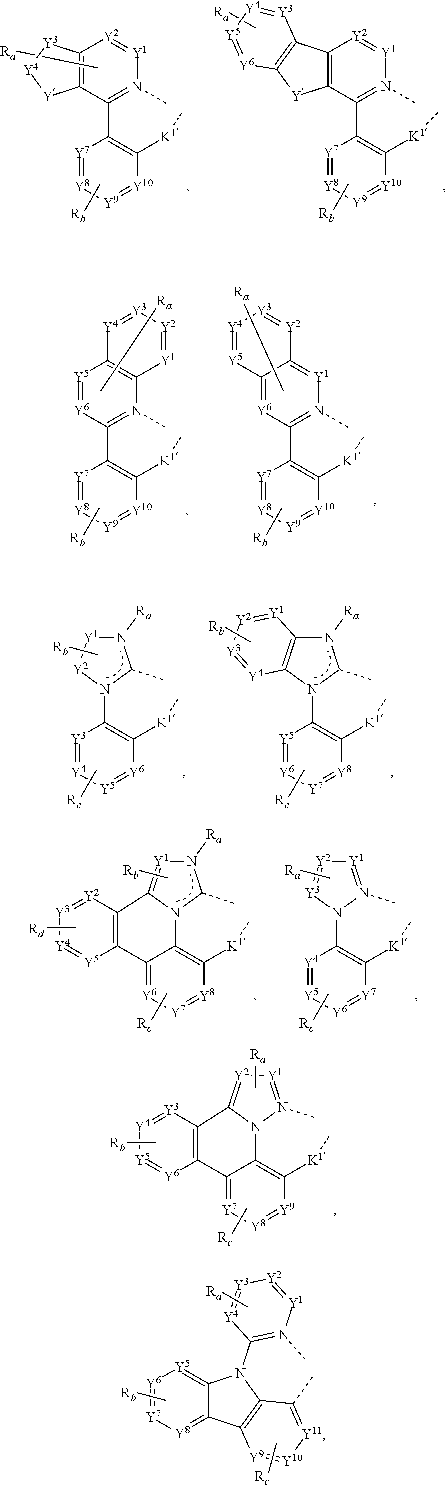

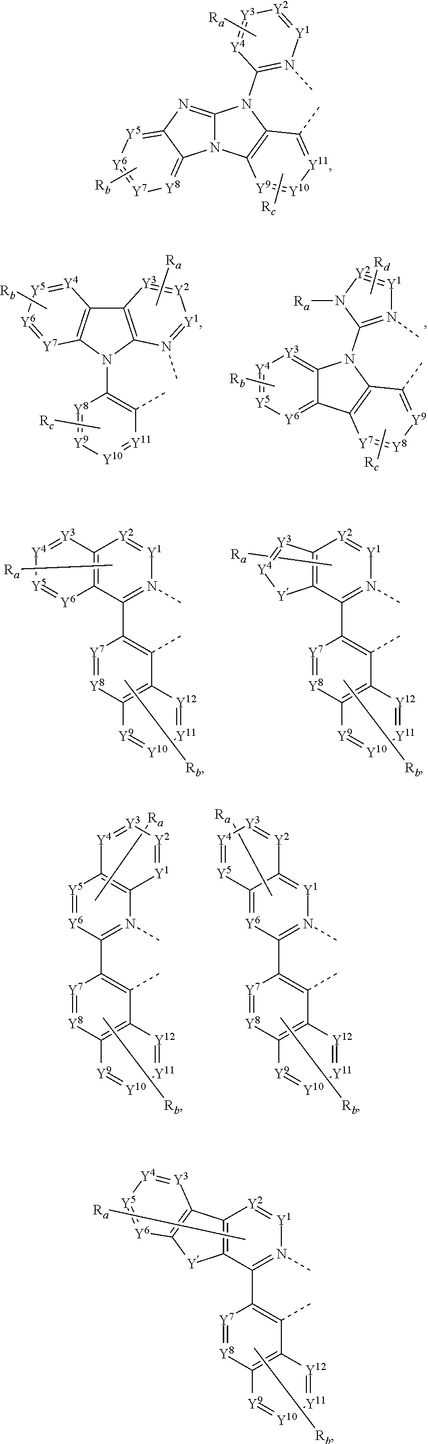

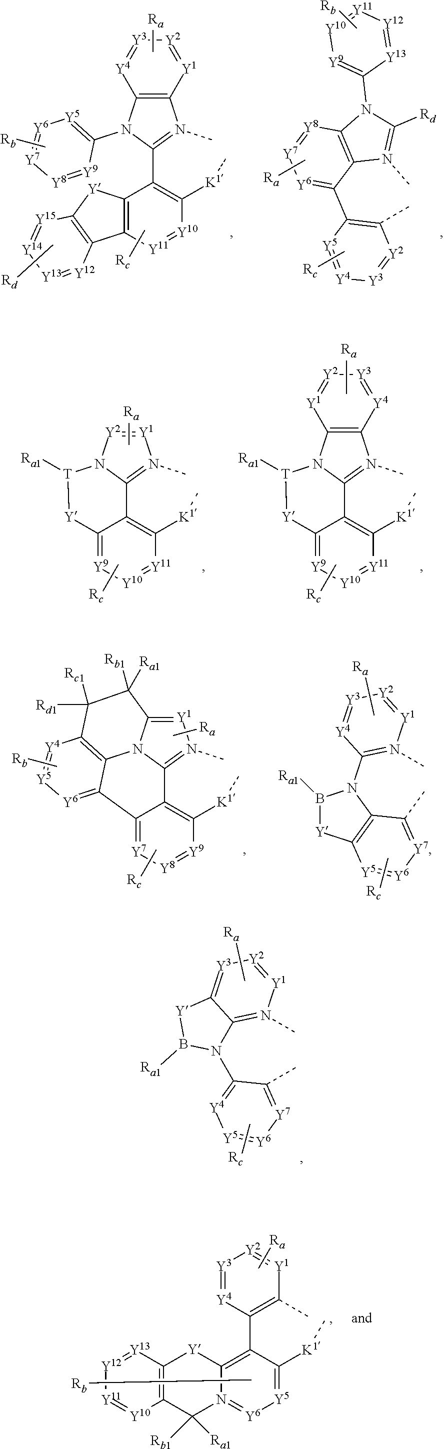

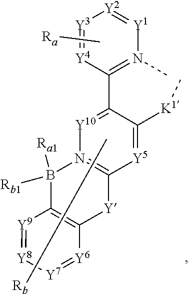

wherein:
T is selected from the group consisting of B, Al, Ga, and In;
K¹′ is selected from the group consisting of a single bond, O, S, NRₑ, PRₑ, BRₑ, CRₑR_{f}, and SiRₑR_{f};
each of Y¹ to Y¹³ is independently selected from the group consisting of C and N;
Y′ is selected from the group consisting of BRₑ, BRₑR_{f}, NRₑ, PRₑ, P(O)Rₑ, O, S, Se, C═O, C═S, C═Se, C═NRₑ, C═CRₑR_{f}, S═O, SO₂, CRₑR_{f}, SiRₑR_{f}, and GeRₑR_{f};
Rₑ and R_{f} can be fused or joined to form a ring;
each Rₐ, R_{b}, R_{c}, and R_{d} independently represents from mono to the maximum allowed number of substitutions, or no substitution;
each of Rₐ₁, R_{b1}, R_{c1}, R_{d1}, Rₐ, R_{b}, R_{c}, R_{d}, Rₑ, and R_{f} is independently a hydrogen or a substituent selected from the group consisting of deuterium, halide, alkyl, cycloalkyl, heteroalkyl, arylalkyl, alkoxy, aryloxy, amino, silyl, germyl, boryl, alkenyl, cycloalkenyl, heteroalkenyl, alkynyl, aryl, heteroaryl, acyl, carbonyl, carboxylic acid, ester, nitrile, isonitrile, sulfanyl, selenyl, sulfinyl, sulfonyl, phosphino, and combinations thereof; and
any two substituents of Rₐ₁, R_{b1}, R_{c1}, R_{d1}, Rₐ, R_{b}, R_{c}, and R_{d} can be fused or joined to form a ring or form a multidentate ligand.

In some embodiments, the compound may be an acceptor, and the OLED may further comprise a sensitizer selected from the group consisting of a delayed fluorescence emitter, a phosphorescent emitter, and combination thereof.

In some embodiments, the compound may be a fluorescent emitter, a delayed fluorescence emitter, or a component of an exciplex that is a fluorescent emitter or a delayed fluorescence emitter.

In yet another aspect, the OLED of the present disclosure may also comprise an emissive region containing a compound as disclosed in the above compounds section of the present disclosure.

In some embodiments, the emissive region can comprise a compound of Formula I as disclosed herein.

In some embodiments, at least one of the anode, the cathode, or a new layer disposed over the organic emissive layer functions as an enhancement layer. The enhancement layer comprises a plasmonic material exhibiting surface plasmon resonance that non-radiatively couples to the emitter material and transfers excited state energy from the emitter material to non-radiative mode of surface plasmon polariton. The enhancement layer is provided no more than a threshold distance away from the organic emissive layer, wherein the emitter material has a total non-radiative decay rate constant and a total radiative decay rate constant due to the presence of the enhancement layer and the threshold distance is where the total non-radiative decay rate constant is equal to the total radiative decay rate constant. In some embodiments, the OLED further comprises an outcoupling layer. In some embodiments, the outcoupling layer is disposed over the enhancement layer on the opposite side of the organic emissive layer. In some embodiments, the outcoupling layer is disposed on opposite side of the emissive layer from the enhancement layer but still outcouples energy from the surface plasmon mode of the enhancement layer. The outcoupling layer scatters the energy from the surface plasmon polaritons. In some embodiments this energy is scattered as photons to free space. In other embodiments, the energy is scattered from the surface plasmon mode into other modes of the device such as but not limited to the organic waveguide mode, the substrate mode, or another waveguiding mode. If energy is scattered to the non-free space mode of the OLED other outcoupling schemes could be incorporated to extract that energy to free space. In some embodiments, one or more intervening layer can be disposed between the enhancement layer and the outcoupling layer. The examples for intervening layer(s) can be dielectric materials, including organic, inorganic, perovskites, oxides, and may include stacks and/or mixtures of these materials.

The enhancement layer modifies the effective properties of the medium in which the emitter material resides resulting in any or all of the following: a decreased rate of emission, a modification of emission line-shape, a change in emission intensity with angle, a change in the stability of the emitter material, a change in the efficiency of the OLED, and reduced efficiency roll-off of the OLED device. Placement of the enhancement layer on the cathode side, anode side, or on both sides results in OLED devices which take advantage of any of the above-mentioned effects. In addition to the specific functional layers mentioned herein and illustrated in the various OLED examples shown in the figures, the OLEDs according to the present disclosure may include any of the other functional layers often found in OLEDs.

The enhancement layer can be comprised of plasmonic materials, optically active metamaterials, or hyperbolic metamaterials. As used herein, a plasmonic material is a material in which the real part of the dielectric constant crosses zero in the visible or ultraviolet region of the electromagnetic spectrum. In some embodiments, the plasmonic material includes at least one metal. In such embodiments the metal may include at least one of Ag, Al, Au, Ir, Pt, Ni, Cu, W, Ta, Fe, Cr, Mg, Ga, Rh, Ti, Ru, Pd, In, Bi, Ca alloys or mixtures of these materials, and stacks of these materials. In general, a metamaterial is a medium composed of different materials where the medium as a whole acts differently than the sum of its material parts. In particular, we define optically active metamaterials as materials which have both negative permittivity and negative permeability. Hyperbolic metamaterials, on the other hand, are anisotropic media in which the permittivity or permeability are of different sign for different spatial directions. Optically active metamaterials and hyperbolic metamaterials are strictly distinguished from many other photonic structures such as Distributed Bragg Reflectors (“DBRs”) in that the medium should appear uniform in the direction of propagation on the length scale of the wavelength of light. Using terminology that one skilled in the art can understand: the dielectric constant of the metamaterials in the direction of propagation can be described with the effective medium approximation. Plasmonic materials and metamaterials provide methods for controlling the propagation of light that can enhance OLED performance in a number of ways.

In some embodiments, the enhancement layer is provided as a planar layer. In other embodiments, the enhancement layer has wavelength-sized features that are arranged periodically, quasi-periodically, or randomly, or sub-wavelength-sized features that are arranged periodically, quasi-periodically, or randomly. In some embodiments, the wavelength-sized features and the sub-wavelength-sized features have sharp edges.

In some embodiments, the outcoupling layer has wavelength-sized features that are arranged periodically, quasi-periodically, or randomly, or sub-wavelength-sized features that are arranged periodically, quasi-periodically, or randomly. In some embodiments, the outcoupling layer may be composed of a plurality of nanoparticles and in other embodiments the outcoupling layer is composed of a plurality of nanoparticles disposed over a material. In these embodiments the outcoupling may be tunable by at least one of varying a size of the plurality of nanoparticles, varying a shape of the plurality of nanoparticles, changing a material of the plurality of nanoparticles, adjusting a thickness of the material, changing the refractive index of the material or an additional layer disposed on the plurality of nanoparticles, varying a thickness of the enhancement layer, and/or varying the material of the enhancement layer. The plurality of nanoparticles of the device may be formed from at least one of metal, dielectric material, semiconductor materials, an alloy of metal, a mixture of dielectric materials, a stack or layering of one or more materials, and/or a core of one type of material and that is coated with a shell of a different type of material. In some embodiments, the outcoupling layer is composed of at least metal nanoparticles wherein the metal is selected from the group consisting of Ag, Al, Au, Ir, Pt, Ni, Cu, W, Ta, Fe, Cr, Mg, Ga, Rh, Ti, Ru, Pd, In, Bi, Ca, alloys or mixtures of these materials, and stacks of these materials. The plurality of nanoparticles may have additional layer disposed over them. In some embodiments, the polarization of the emission can be tuned using the outcoupling layer. Varying the dimensionality and periodicity of the outcoupling layer can select a type of polarization that is preferentially outcoupled to air. In some embodiments the outcoupling layer also acts as an electrode of the device.

In yet another aspect, the present disclosure also provides a consumer product comprising an organic light-emitting device (OLED) having an anode; a cathode; and an organic layer disposed between the anode and the cathode, wherein the organic layer may comprise a compound as disclosed in the above compounds section of the present disclosure.

In some embodiments, the consumer product comprises an organic light-emitting device (OLED) having an anode; a cathode; and an organic layer disposed between the anode and the cathode, wherein the organic layer may comprise a compound of Formula I as described herein.

In some embodiments, the consumer product can be one of a flat panel display, a computer monitor, a medical monitor, a television, a billboard, a light for interior or exterior illumination and/or signaling, a heads-up display, a fully or partially transparent display, a flexible display, a laser printer, a telephone, a cell phone, tablet, a phablet, a personal digital assistant (PDA), a wearable device, a laptop computer, a digital camera, a camcorder, a viewfinder, a micro-display that is less than 2 inches diagonal, a 3-D display, a virtual reality or augmented reality display, a vehicle, a video wall comprising multiple displays tiled together, a theater or stadium screen, a light therapy device, and a sign.

Generally, an OLED comprises at least one organic layer disposed between and electrically connected to an anode and a cathode. When a current is applied, the anode injects holes and the cathode injects electrons into the organic layer(s). The injected holes and electrons each migrate toward the oppositely charged electrode. When an electron and hole localize on the same molecule, an “exciton,” which is a localized electron-hole pair having an excited energy state, is formed. Light is emitted when the exciton relaxes via a photoemissive mechanism. In some cases, the exciton may be localized on an excimer or an exciplex. Non-radiative mechanisms, such as thermal relaxation, may also occur, but are generally considered undesirable.

Several OLED materials and configurations are described in U.S. Pat. Nos. 5,844,363, 6,303,238, and 5,707,745, which are incorporated herein by reference in their entirety.

The initial OLEDs used emissive molecules that emitted light from their singlet states (“fluorescence”) as disclosed, for example, in U.S. Pat. No. 4,769,292, which is incorporated by reference in its entirety. Fluorescent emission generally occurs in a time frame of less than 10 nanoseconds.

More recently, OLEDs having emissive materials that emit light from triplet states (“phosphorescence”) have been demonstrated. Baldo et al., “Highly Efficient Phosphorescent Emission from Organic Electroluminescent Devices,” Nature, vol. 395, 151-154, 1998; (“Baldo-I”) and Baldo et al., “Very high-efficiency green organic light-emitting devices based on electrophosphorescence,” Appl. Phys. Lett., vol. 75, No. 3, 4-6 (1999) (“Baldo-II”), are incorporated by reference in their entireties. Phosphorescence is described in more detail in U.S. Pat. No. 7,279,704 at cols. 5-6, which are incorporated by reference.

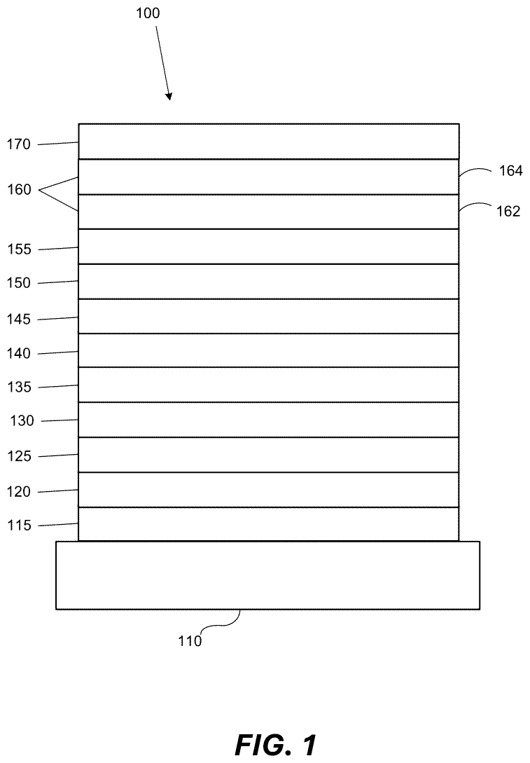

FIG. 1 shows an organic light emitting device 100. The figures are not necessarily drawn to scale. Device 100 may include a substrate 110, an anode 115, a hole injection layer 120, a hole transport layer 125, an electron blocking layer 130, an emissive layer 135, a hole blocking layer 140, an electron transport layer 145, an electron injection layer 150, a protective layer 155, a cathode 160, and a barrier layer 170. Cathode 160 is a compound cathode having a first conductive layer 162 and a second conductive layer 164. Device 100 may be fabricated by depositing the layers described, in order. The properties and functions of these various layers, as well as example materials, are described in more detail in U.S. Pat. No. 7,279,704 at cols. 6-10, which are incorporated by reference.

More examples for each of these layers are available. For example, a flexible and transparent substrate-anode combination is disclosed in U.S. Pat. No. 5,844,363, which is incorporated by reference in its entirety. An example of a p-doped hole transport layer is m-MTDATA doped with F₄-TCNQ at a molar ratio of 50:1, as disclosed in U.S. Patent Application Publication No. 2003/0230980, which is incorporated by reference in its entirety. Examples of emissive and host materials are disclosed in U.S. Pat. No. 6,303,238 to Thompson et al., which is incorporated by reference in its entirety. An example of an n-doped electron transport layer is BPhen doped with Li at a molar ratio of 1:1, as disclosed in U.S. Patent Application Publication No. 2003/0230980, which is incorporated by reference in its entirety. U.S. Pat. Nos. 5,703,436 and 5,707,745, which are incorporated by reference in their entireties, disclose examples of cathodes including compound cathodes having a thin layer of metal such as Mg:Ag with an overlying transparent, electrically-conductive, sputter-deposited ITO layer. The theory and use of blocking layers is described in more detail in U.S. Pat. No. 6,097,147 and U.S. Patent Application Publication No. 2003/0230980, which are incorporated by reference in their entireties. Examples of injection layers are provided in U.S. Patent Application Publication No. 2004/0174116, which is incorporated by reference in its entirety. A description of protective layers may be found in U.S. Patent Application Publication No. 2004/0174116, which is incorporated by reference in its entirety.

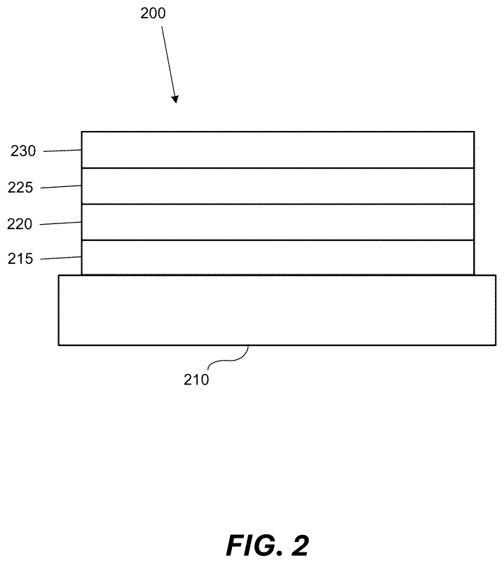

FIG. 2 shows an inverted OLED 200. The device includes a substrate 210, a cathode 215, an emissive layer 220, a hole transport layer 225, and an anode 230. Device 200 may be fabricated by depositing the layers described, in order. Because the most common OLED configuration has a cathode disposed over the anode, and device 200 has cathode 215 disposed under anode 230, device 200 may be referred to as an “inverted” OLED. Materials similar to those described with respect to device 100 may be used in the corresponding layers of device 200. FIG. 2 provides one example of how some layers may be omitted from the structure of device 100.

The simple layered structure illustrated in FIGS. 1 and 2 is provided by way of non-limiting example, and it is understood that embodiments of the present disclosure may be used in connection with a wide variety of other structures. The specific materials and structures described are exemplary in nature, and other materials and structures may be used. Functional OLEDs may be achieved by combining the various layers described in different ways, or layers may be omitted entirely, based on design, performance, and cost factors. Other layers not specifically described may also be included. Materials other than those specifically described may be used.

Although many of the examples provided herein describe various layers as comprising a single material, it is understood that combinations of materials, such as a mixture of host and dopant, or more generally a mixture, may be used. Also, the layers may have various sublayers. The names given to the various layers herein are not intended to be strictly limiting. For example, in device 200, hole transport layer 225 transports holes and injects holes into emissive layer 220, and may be described as a hole transport layer or a hole injection layer. In one embodiment, an OLED may be described as having an “organic layer” disposed between a cathode and an anode. This organic layer may comprise a single layer, or may further comprise multiple layers of different organic materials as described, for example, with respect to FIGS. 1 and 2.

Structures and materials not specifically described may also be used, such as OLEDs comprised of polymeric materials (PLEDs) such as disclosed in U.S. Pat. No. 5,247,190 to Friend et al., which is incorporated by reference in its entirety. By way of further example, OLEDs having a single organic layer may be used. OLEDs may be stacked, for example as described in U.S. Pat. No. 5,707,745 to Forrest et al, which is incorporated by reference in its entirety. The OLED structure may deviate from the simple layered structure illustrated in FIGS. 1 and 2. For example, the substrate may include an angled reflective surface to improve out-coupling, such as a mesa structure as described in U.S. Pat. No. 6,091,195 to Forrest et al., and/or a pit structure as described in U.S. Pat. No. 5,834,893 to Bulovic et al., which are incorporated by reference in their entireties.

Unless otherwise specified, any of the layers of the various embodiments may be deposited by any suitable method. For the organic layers, preferred methods include thermal evaporation, ink-jet, such as described in U.S. Pat. Nos. 6,013,982 and 6,087,196, which are incorporated by reference in their entireties, organic vapor phase deposition (OVPD), such as described in U.S. Pat. No. 6,337,102 to Forrest et al., which is incorporated by reference in its entirety, and deposition by organic vapor jet printing (OVJP, also referred to as organic vapor jet deposition (OVJD)), such as described in U.S. Pat. No. 7,431,968, which is incorporated by reference in its entirety. Other suitable deposition methods include spin coating and other solution based processes. Solution based processes are preferably carried out in nitrogen or an inert atmosphere. For the other layers, preferred methods include thermal evaporation. Preferred patterning methods include deposition through a mask, cold welding such as described in U.S. Pat. Nos. 6,294,398 and 6,468,819, which are incorporated by reference in their entireties, and patterning associated with some of the deposition methods such as ink-jet and organic vapor jet printing (OVJP). Other methods may also be used. The materials to be deposited may be modified to make them compatible with a particular deposition method. For example, substituents such as alkyl and aryl groups, branched or unbranched, and preferably containing at least 3 carbons, may be used in small molecules to enhance their ability to undergo solution processing. Substituents having 20 carbons or more may be used, and 3-20 carbons are a preferred range. Materials with asymmetric structures may have better solution processability than those having symmetric structures, because asymmetric materials may have a lower tendency to recrystallize. Dendrimer substituents may be used to enhance the ability of small molecules to undergo solution processing.

Devices fabricated in accordance with embodiments of the present disclosure may further optionally comprise a barrier layer. One purpose of the barrier layer is to protect the electrodes and organic layers from damaging exposure to harmful species in the environment including moisture, vapor and/or gases, etc. The barrier layer may be deposited over, under or next to a substrate, an electrode, or over any other parts of a device including an edge. The barrier layer may comprise a single layer, or multiple layers. The barrier layer may be formed by various known chemical vapor deposition techniques and may include compositions having a single phase as well as compositions having multiple phases. Any suitable material or combination of materials may be used for the barrier layer. The barrier layer may incorporate an inorganic or an organic compound or both. The preferred barrier layer comprises a mixture of a polymeric material and a non-polymeric material as described in U.S. Pat. No. 7,968,146, PCT Pat. Application Nos. PCT/US2007/023098 and PCT/US2009/042829, which are herein incorporated by reference in their entireties. To be considered a “mixture”, the aforesaid polymeric and non-polymeric materials comprising the barrier layer should be deposited under the same reaction conditions and/or at the same time. The weight ratio of polymeric to non-polymeric material may be in the range of 95:5 to 5:95. The polymeric material and the non-polymeric material may be created from the same precursor material. In one example, the mixture of a polymeric material and a non-polymeric material consists essentially of polymeric silicon and inorganic silicon.

Devices fabricated in accordance with embodiments of the present disclosure can be incorporated into a wide variety of electronic component modules (or units) that can be incorporated into a variety of electronic products or intermediate components. Examples of such electronic products or intermediate components include display screens, lighting devices such as discrete light source devices or lighting panels, etc. that can be utilized by the end-user product manufacturers. Such electronic component modules can optionally include the driving electronics and/or power source(s). Devices fabricated in accordance with embodiments of the present disclosure can be incorporated into a wide variety of consumer products that have one or more of the electronic component modules (or units) incorporated therein. A consumer product comprising an OLED that includes the compound of the present disclosure in the organic layer in the OLED is disclosed. Such consumer products would include any kind of products that include one or more light source(s) and/or one or more of some type of visual displays. Some examples of such consumer products include flat panel displays, curved displays, computer monitors, medical monitors, televisions, billboards, lights for interior or exterior illumination and/or signaling, heads-up displays, fully or partially transparent displays, flexible displays, rollable displays, foldable displays, stretchable displays, laser printers, telephones, mobile phones, tablets, phablets, personal digital assistants (PDAs), wearable devices, laptop computers, digital cameras, camcorders, viewfinders, micro-displays (displays that are less than 2 inches diagonal), 3-D displays, virtual reality or augmented reality displays, vehicles, video walls comprising multiple displays tiled together, theater or stadium screen, a light therapy device, and a sign. Various control mechanisms may be used to control devices fabricated in accordance with the present disclosure, including passive matrix and active matrix. Many of the devices are intended for use in a temperature range comfortable to humans, such as 18° C. to 30° C., and more preferably at room temperature (20-25° C.), but could be used outside this temperature range, for example, from −40° C. to +80° C.

More details on OLEDs, and the definitions described above, can be found in U.S. Pat. No. 7,279,704, which is incorporated herein by reference in its entirety.

The materials and structures described herein may have applications in devices other than OLEDs. For example, other optoelectronic devices such as organic solar cells and organic photodetectors may employ the materials and structures. More generally, organic devices, such as organic transistors, may employ the materials and structures.

In some embodiments, the OLED has one or more characteristics selected from the group consisting of being flexible, being rollable, being foldable, being stretchable, and being curved. In some embodiments, the OLED is transparent or semi-transparent. In some embodiments, the OLED further comprises a layer comprising carbon nanotubes.

In some embodiments, the OLED further comprises a layer comprising a delayed fluorescent emitter. In some embodiments, the OLED comprises a RGB pixel arrangement or white plus color filter pixel arrangement. In some embodiments, the OLED is a mobile device, a hand held device, or a wearable device. In some embodiments, the OLED is a display panel having less than 10 inch diagonal or 50 square inch area. In some embodiments, the OLED is a display panel having at least 10 inch diagonal or 50 square inch area. In some embodiments, the OLED is a lighting panel.

In some embodiments, the compound can be an emissive dopant. In some embodiments, the compound can produce emissions via phosphorescence, fluorescence, thermally activated delayed fluorescence, i.e., TADF (also referred to as E-type delayed fluorescence; see, e.g., U.S. application Ser. No. 15/700,352, which is hereby incorporated by reference in its entirety), triplet-triplet annihilation, or combinations of these processes. In some embodiments, the emissive dopant can be a racemic mixture, or can be enriched in one enantiomer. In some embodiments, the compound can be homoleptic (each ligand is the same). In some embodiments, the compound can be heteroleptic (at least one ligand is different from others). When there are more than one ligand coordinated to a metal, the ligands can all be the same in some embodiments. In some other embodiments, at least one ligand is different from the other ligands. In some embodiments, every ligand can be different from each other. This is also true in embodiments where a ligand being coordinated to a metal can be linked with other ligands being coordinated to that metal to form a tridentate, tetradentate, pentadentate, or hexadentate ligands. Thus, where the coordinating ligands are being linked together, all of the ligands can be the same in some embodiments, and at least one of the ligands being linked can be different from the other ligand(s) in some other embodiments.

In some embodiments, the compound can be used as one component of an exciplex to be used as a sensitizer.

In some embodiments, the sensitizer is a single component, or one of the components to form an exciplex.

According to another aspect, a formulation comprising the compound described herein is also disclosed.

The OLED disclosed herein can be incorporated into one or more of a consumer product, an electronic component module, and a lighting panel. The organic layer can be an emissive layer and the compound can be an emissive dopant in some embodiments, while the compound can be a non-emissive dopant in other embodiments.

In some embodiments, the emissive layer comprises one or more quantum dots.

In yet another aspect of the present disclosure, a formulation that comprises the novel compound disclosed herein is described. The formulation can include one or more components selected from the group consisting of a solvent, a host, a hole injection material, hole transport material, electron blocking material, hole blocking material, and an electron transport material, disclosed herein.

The present disclosure encompasses any chemical structure comprising the novel compound of the present disclosure, or a monovalent or polyvalent variant thereof. In other words, the inventive compound, or a monovalent or polyvalent variant thereof, can be a part of a larger chemical structure. Such chemical structure can be selected from the group consisting of a monomer, a polymer, a macromolecule, and a supramolecule (also known as supermolecule). As used herein, a “monovalent variant of a compound” refers to a moiety that is identical to the compound except that one hydrogen has been removed and replaced with a bond to the rest of the chemical structure. As used herein, a “polyvalent variant of a compound” refers to a moiety that is identical to the compound except that more than one hydrogen has been removed and replaced with a bond or bonds to the rest of the chemical structure. In the instance of a supramolecule, the inventive compound can also be incorporated into the supramolecule complex without covalent bonds.

### D. Combination of the Compounds of the Present Disclosure with Other Materials

The materials described herein as useful for a particular layer in an organic light emitting device may be used in combination with a wide variety of other materials present in the device. For example, emissive dopants disclosed herein may be used in conjunction with a wide variety of hosts, transport layers, blocking layers, injection layers, electrodes and other layers that may be present. The materials described or referred to below are non-limiting examples of materials that may be useful in combination with the compounds disclosed herein, and one of skill in the art can readily consult the literature to identify other materials that may be useful in combination.

### a) Conductivity Dopants:

A charge transport layer can be doped with conductivity dopants to substantially alter its density of charge carriers, which will in turn alter its conductivity. The conductivity is increased by generating charge carriers in the matrix material, and depending on the type of dopant, a change in the Fermi level of the semiconductor may also be achieved. Hole-transporting layer can be doped by p-type conductivity dopants and n-type conductivity dopants are used in the electron-transporting layer.

Non-limiting examples of the conductivity dopants that may be used in an OLED in combination with materials disclosed herein are exemplified below together with references that disclose those materials: EP01617493, EP01968131, EP2020694, EP2684932, US20050139810, US20070160905, US20090167167, US2010288362, WO06081780, WO2009003455, WO2009008277, WO2009011327, WO2014009310, US2007252140, US2015060804, US20150123047, and US2012146012.

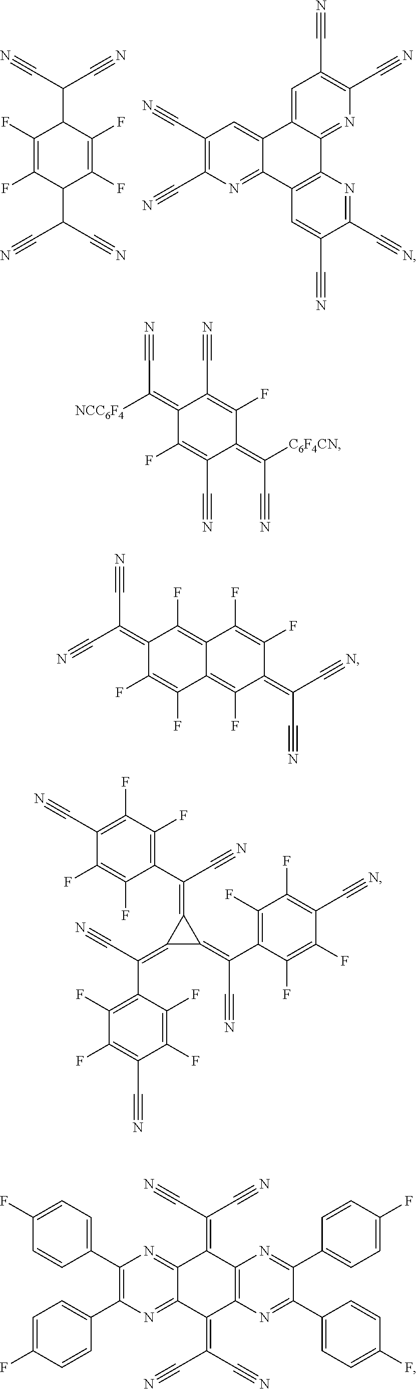

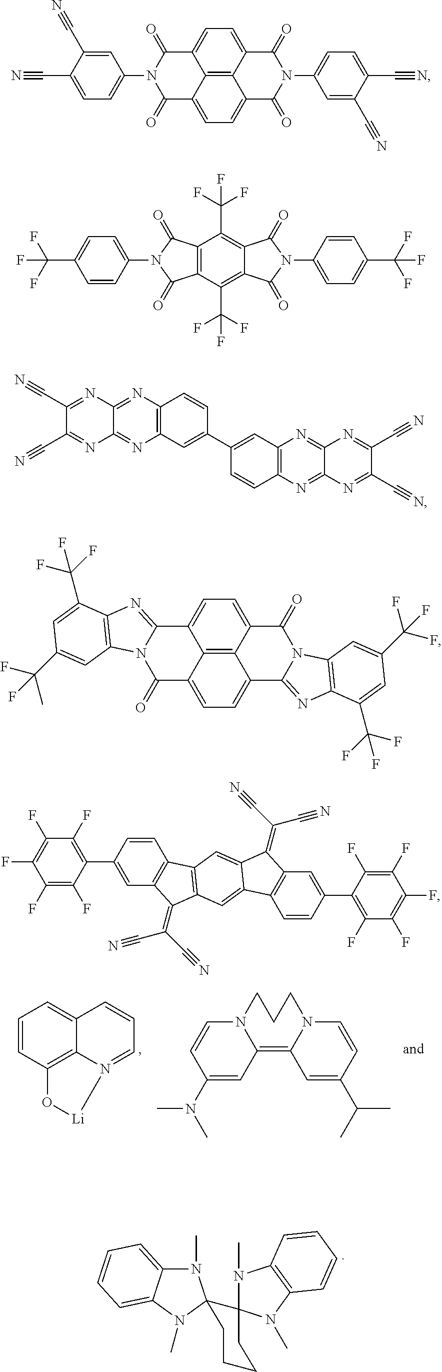

### b) HIL/HTL:

A hole injecting/transporting material to be used in the present disclosure is not particularly limited, and any compound may be used as long as the compound is typically used as a hole injecting/transporting material. Examples of the material include, but are not limited to: a phthalocyanine or porphyrin derivative; an aromatic amine derivative; an indolocarbazole derivative; a polymer containing fluorohydrocarbon; a polymer with conductivity dopants; a conducting polymer, such as PEDOT/PSS; a self-assembly monomer derived from compounds such as phosphonic acid and silane derivatives; a metal oxide derivative, such as MoOₓ; a p-type semiconducting organic compound, such as 1,4,5,8,9,12-Hexaazatriphenylenehexacarbonitrile; a metal complex, and a cross-linkable compounds.

Examples of aromatic amine derivatives used in HIL or HTL include, but not limit to the following general structures:

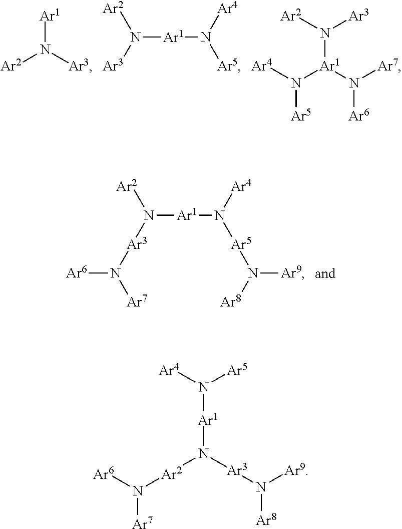

Each of Ar¹ to Ar⁹ is selected from the group consisting of aromatic hydrocarbon cyclic compounds such as benzene, biphenyl, triphenyl, triphenylene, naphthalene, anthracene, phenalene, phenanthrene, fluorene, pyrene, chrysene, perylene, and azulene; the group consisting of aromatic heterocyclic compounds such as dibenzothiophene, dibenzofuran, dibenzoselenophene, furan, thiophene, benzofuran, benzothiophene, benzoselenophene, carbazole, indolocarbazole, pyridylindole, pyrrolodipyridine, pyrazole, imidazole, triazole, oxazole, thiazole, oxadiazole, oxatriazole, dioxazole, thiadiazole, pyridine, pyridazine, pyrimidine, pyrazine, triazine, oxazine, oxathiazine, oxadiazine, indole, benzimidazole, indazole, indoxazine, benzoxazole, benzisoxazole, benzothiazole, quinoline, isoquinoline, cinnoline, quinazoline, quinoxaline, naphthyridine, phthalazine, pteridine, xanthene, acridine, phenazine, phenothiazine, phenoxazine, benzofuropyridine, furodipyridine, benzothienopyridine, thienodipyridine, benzoselenophenopyridine, and selenophenodipyridine; and the group consisting of 2 to 10 cyclic structural units which are groups of the same type or different types selected from the aromatic hydrocarbon cyclic group and the aromatic heterocyclic group and are bonded to each other directly or via at least one of oxygen atom, nitrogen atom, sulfur atom, silicon atom, phosphorus atom, boron atom, chain structural unit and the aliphatic cyclic group. Each Ar may be unsubstituted or may be substituted by a substituent selected from the group consisting of deuterium, halogen, alkyl, cycloalkyl, heteroalkyl, heterocycloalkyl, arylalkyl, alkoxy, aryloxy, amino, silyl, alkenyl, cycloalkenyl, heteroalkenyl, alkynyl, aryl, heteroaryl, acyl, carboxylic acids, ether, ester, nitrile, isonitrile, sulfanyl, sulfinyl, sulfonyl, phosphino, and combinations thereof.

In one aspect, Ar¹ to Ar⁹ is independently selected from the group consisting of:

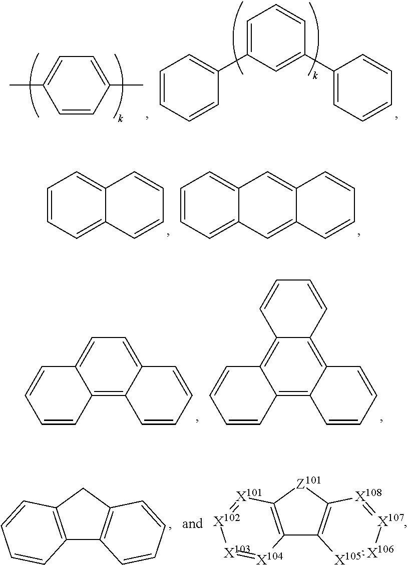

wherein k is an integer from 1 to 20; X¹⁰¹ to X¹⁰⁸ is C (including CH) or N; Z¹⁰¹ is NAr¹, O, or S; Ar¹ has the same group defined above.

Examples of metal complexes used in HIL or HTL include, but are not limited to the following general formula:

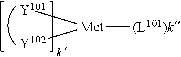

wherein Met is a metal, which can have an atomic weight greater than 40; (Y¹⁰¹-Y¹⁰²) is a bidentate ligand, Y¹⁰¹ and Y¹⁰² are independently selected from C, N, O, P, and S; L¹⁰¹ is an ancillary ligand; k′ is an integer value from 1 to the maximum number of ligands that may be attached to the metal; and k′+k″ is the maximum number of ligands that may be attached to the metal.

In one aspect, (Y¹⁰¹-Y¹⁰²) is a 2-phenylpyridine derivative. In another aspect, (Y¹⁰¹-Y¹⁰²) is a carbene ligand. In another aspect, Met is selected from Ir, Pt, Os, and Zn. In a further aspect, the metal complex has a smallest oxidation potential in solution vs. Fc⁺/Fc couple less than about 0.6 V.

Non-limiting examples of the HIL and HTL materials that may be used in an OLED in combination with materials disclosed herein are exemplified below together with references that disclose those materials: CN102702075, DE102012005215, EP01624500, EP01698613, EP01806334, EP01930964, EP01972613, EP01997799, EP02011790, EP02055700, EP02055701, EP1725079, EP2085382, EP2660300, EP650955, JP07-073529, JP2005112765, JP2007091719, JP2008021687, JP2014-009196, KR20110088898, KR20130077473, TW201139402, U.S. Ser. No. 06/517,957, US20020158242, US20030162053, US20050123751, US20060182993, US20060240279, US20070145888, US20070181874, US20070278938, US20080014464, US20080091025, US20080106190, US20080124572, US20080145707, US20080220265, US20080233434, US20080303417, US2008107919, US20090115320, US20090167161, US2009066235, US2011007385, US20110163302, US2011240968, US2011278551, US2012205642, US2013241401, US20140117329, US2014183517, U.S. Pat. Nos. 5,061,569, 5,639,914, WO05075451, WO07125714, WO08023550, WO08023759, WO2009145016, WO2010061824, WO2011075644, WO2012177006, WO2013018530, WO2013039073, WO2013087142, WO2013118812, WO2013120577, WO2013157367, WO2013175747, WO2014002873, WO2014015935, WO2014015937, WO2014030872, WO2014030921, WO2014034791, WO2014104514, WO2014157018.

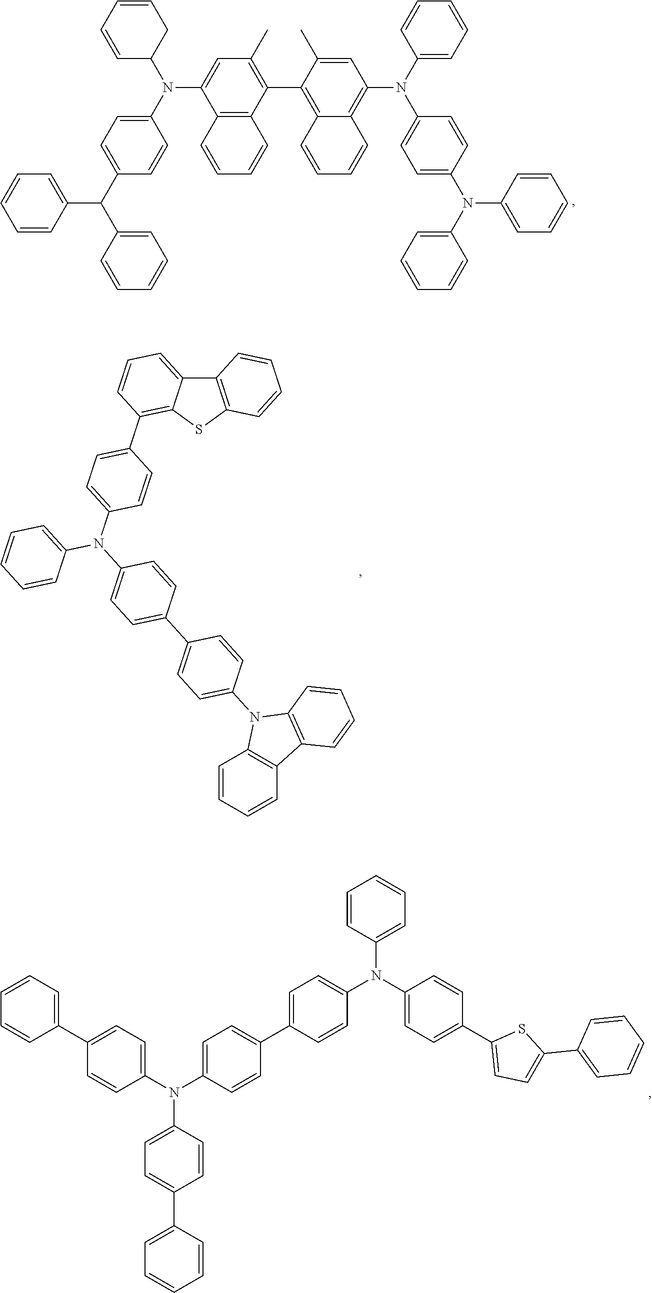 [SMILES: Cc1cc(N(c2ccccc2)c2ccc(N(c3ccccc3)c3ccccc3)cc2)c2ccccc2c1-c1c(C)cc(N(c2ccc(C(c3ccccc3)c3ccccc3)cc2)C2C=CC=CC2)c2ccccc12 ; c1ccc(N(c2ccc(-c3ccc(-n4c5ccccc5c5ccccc54)cc3)cc2)c2ccc(-c3cccc4c3sc3ccccc34)cc2)cc1 ; c1ccc(-c2ccc(N(c3ccc(-c4ccccc4)cc3)c3ccc(-c4ccc(N(c5ccccc5)c5ccc(-c6ccc(-c7ccccc7)s6)cc5)cc4)cc3)cc2)cc1]

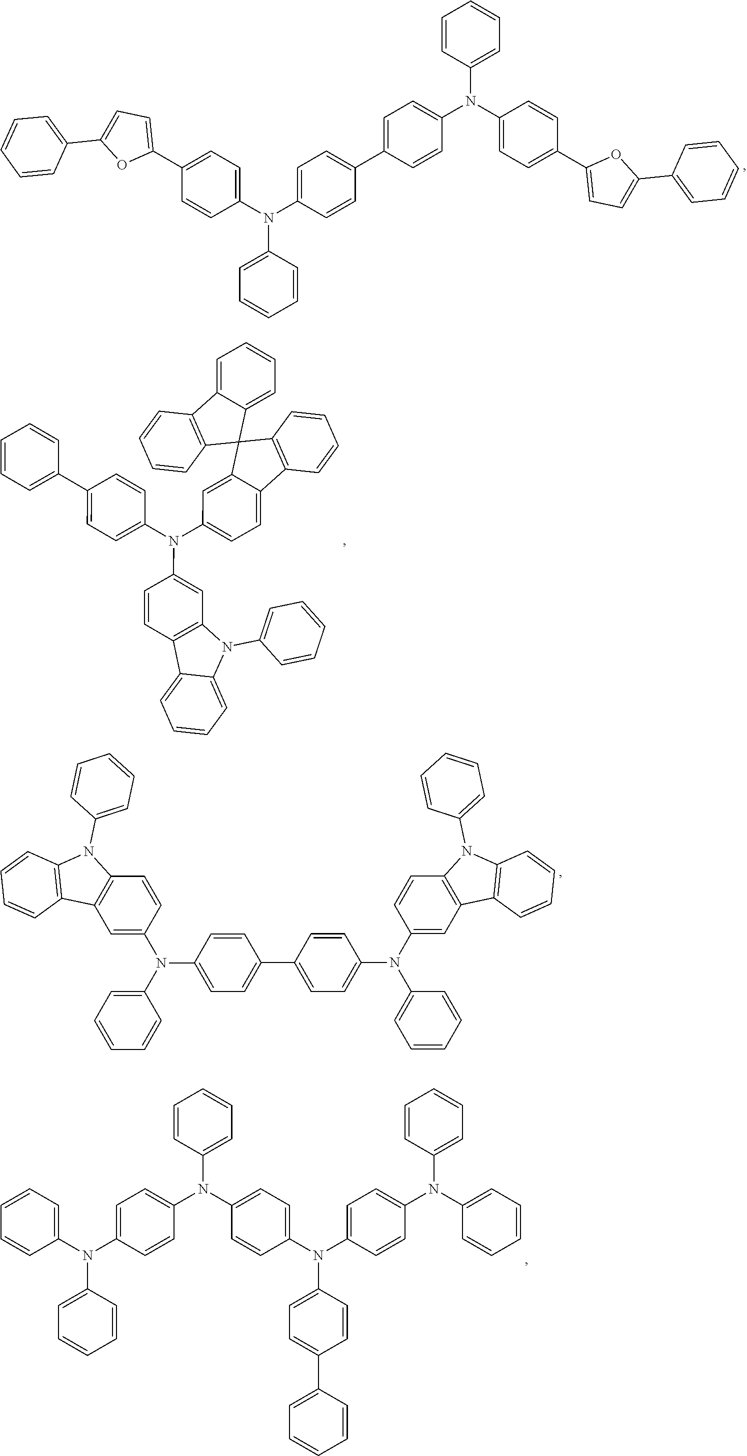

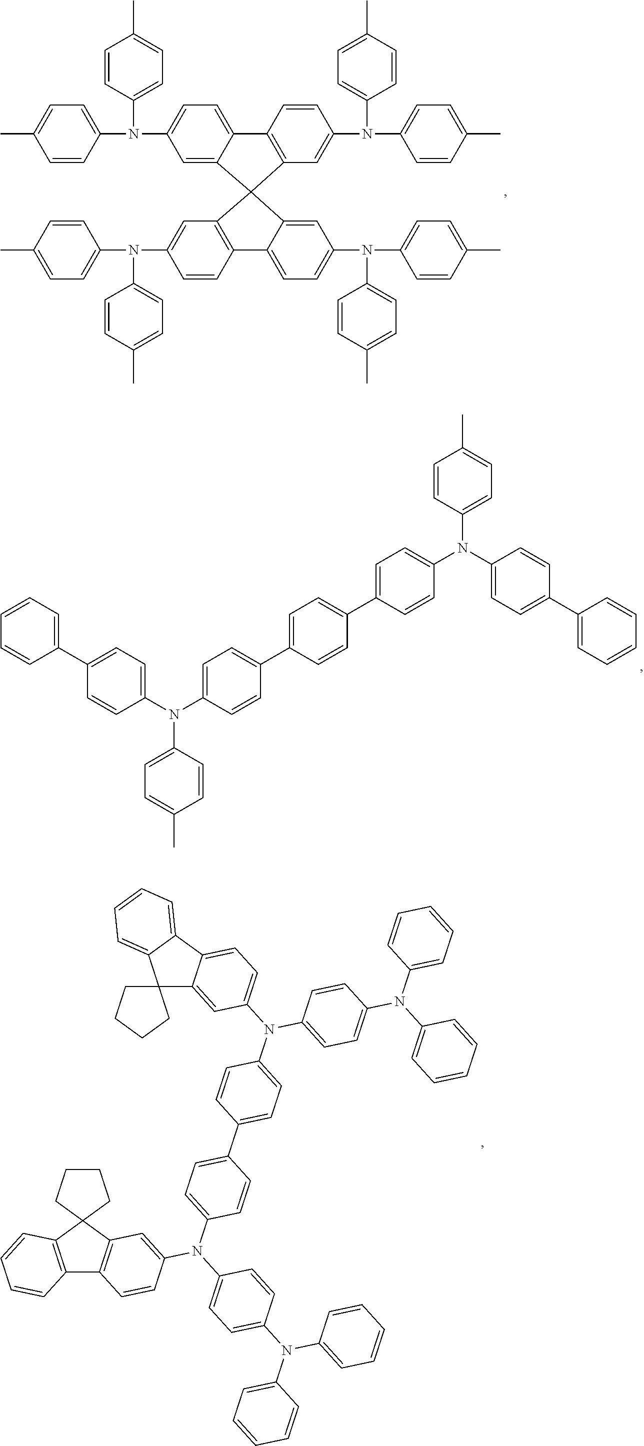

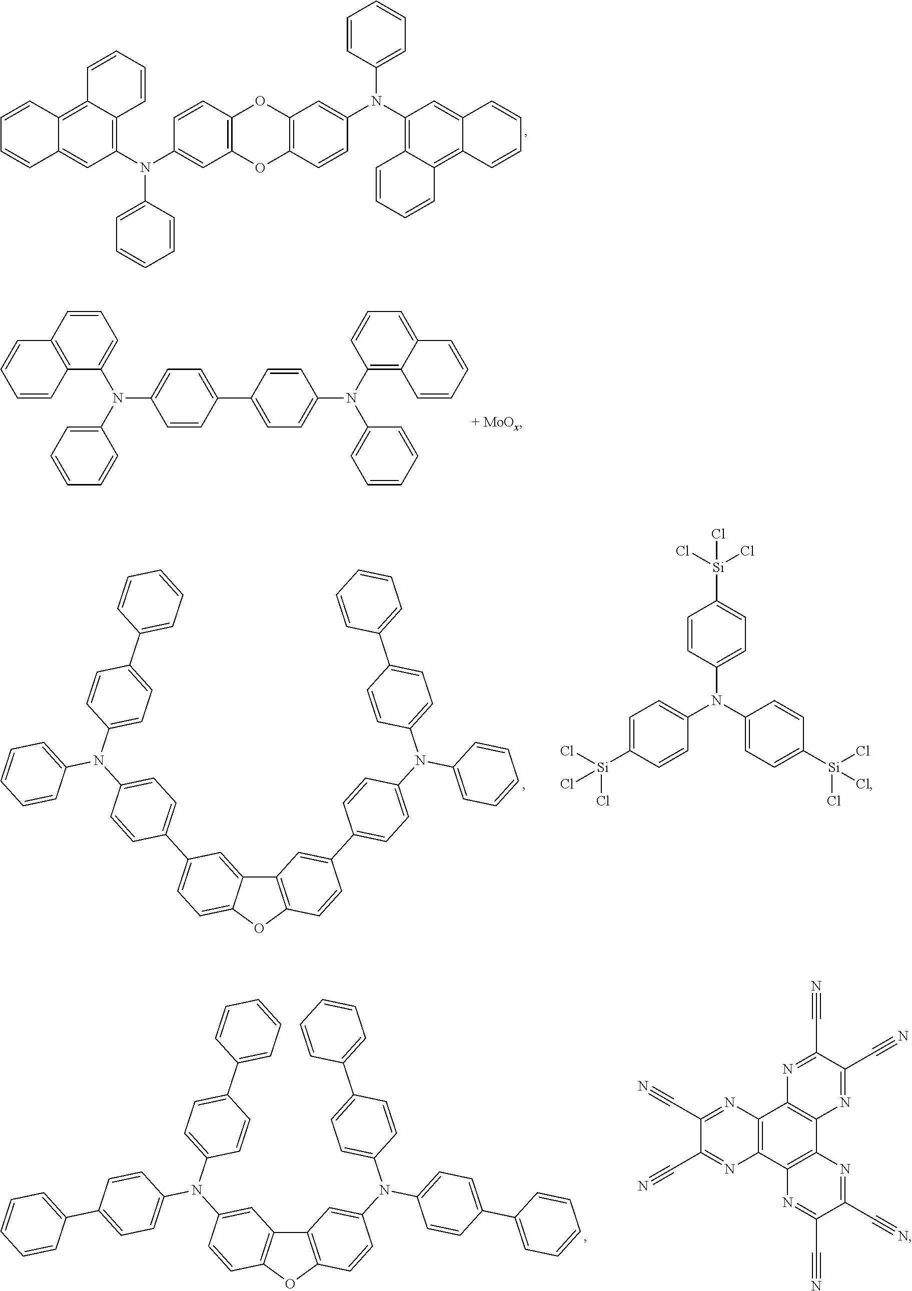

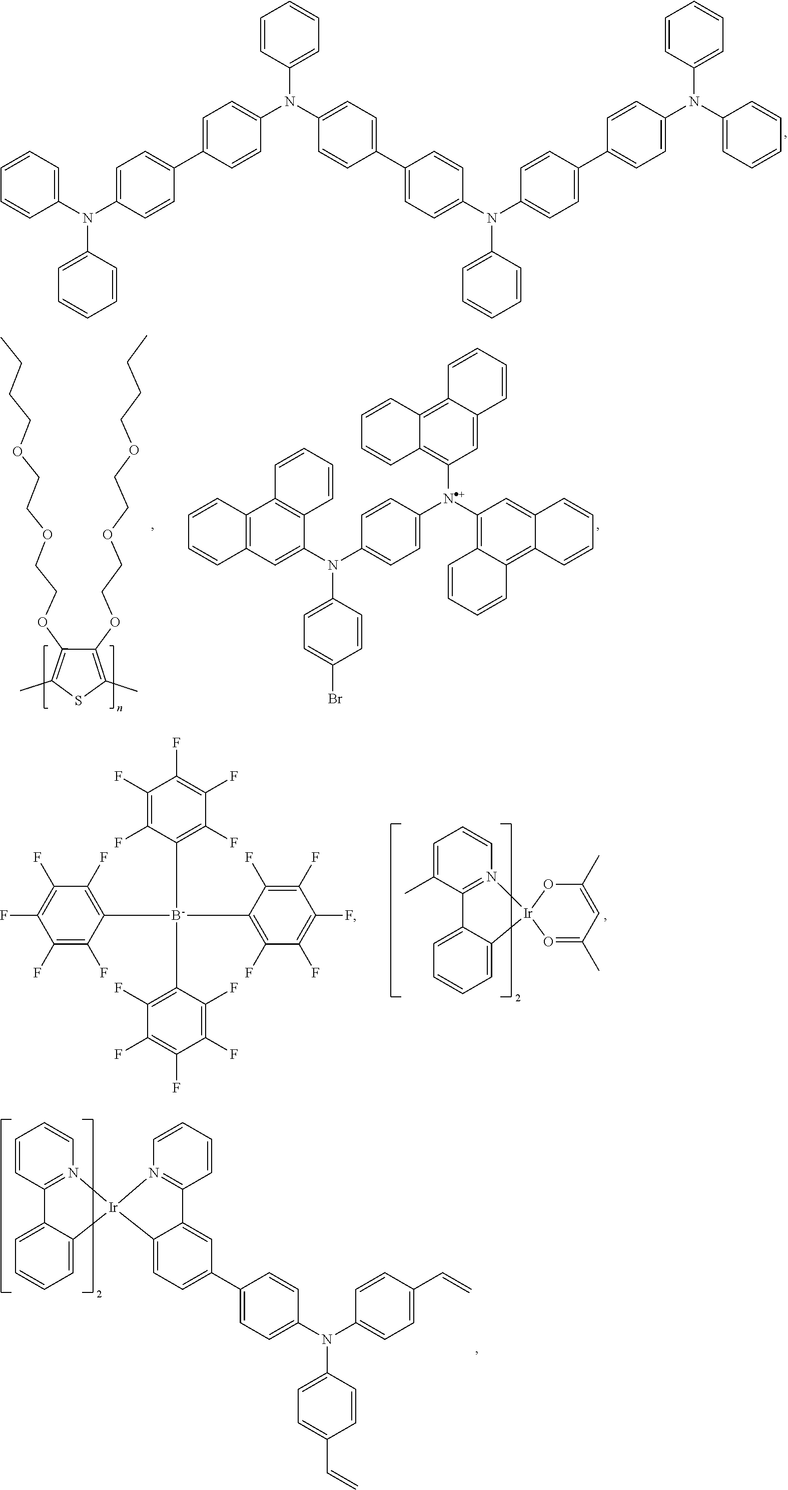

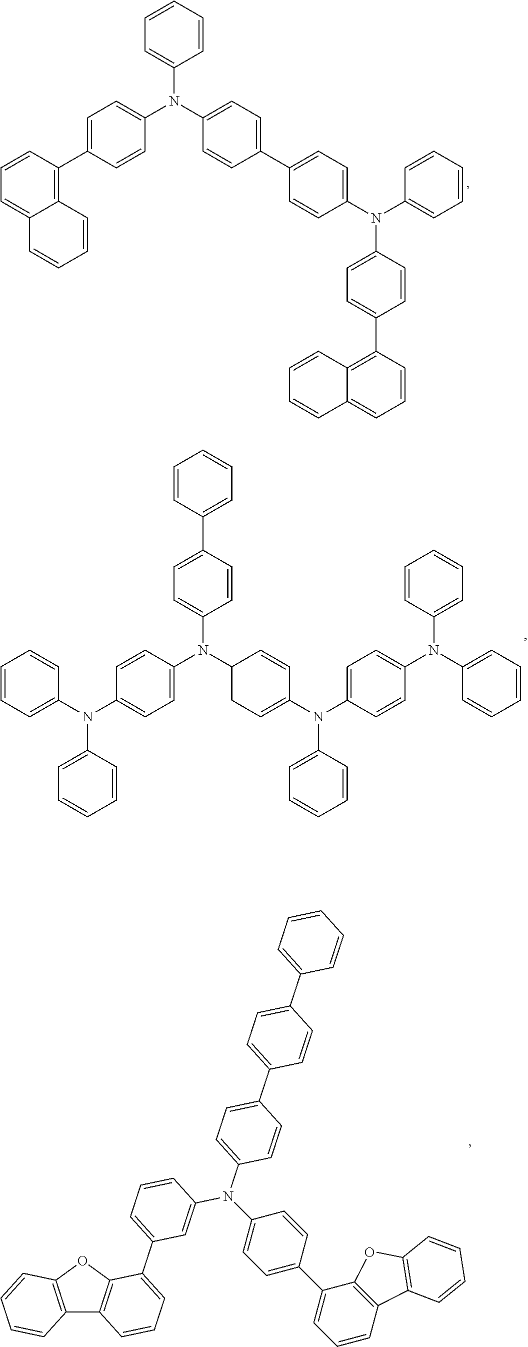 [SMILES: c1ccc(N(c2ccc(-c3ccc(N(c4ccccc4)c4ccc(-c5cccc6ccccc56)cc4)cc3)cc2)c2ccc(-c3cccc4ccccc34)cc2)cc1 ; C1=CC(N(c2ccc(-c3ccccc3)cc2)c2ccc(N(c3ccccc3)c3ccccc3)cc2)CC=C1N(c1ccccc1)c1ccc(N(c2ccccc2)c2ccccc2)cc1 ; c1ccc(-c2ccc(-c3ccc(N(c4ccc(-c5cccc6c5oc5ccccc56)cc4)c4cccc(-c5cccc6c5oc5ccccc56)c4)cc3)cc2)cc1]

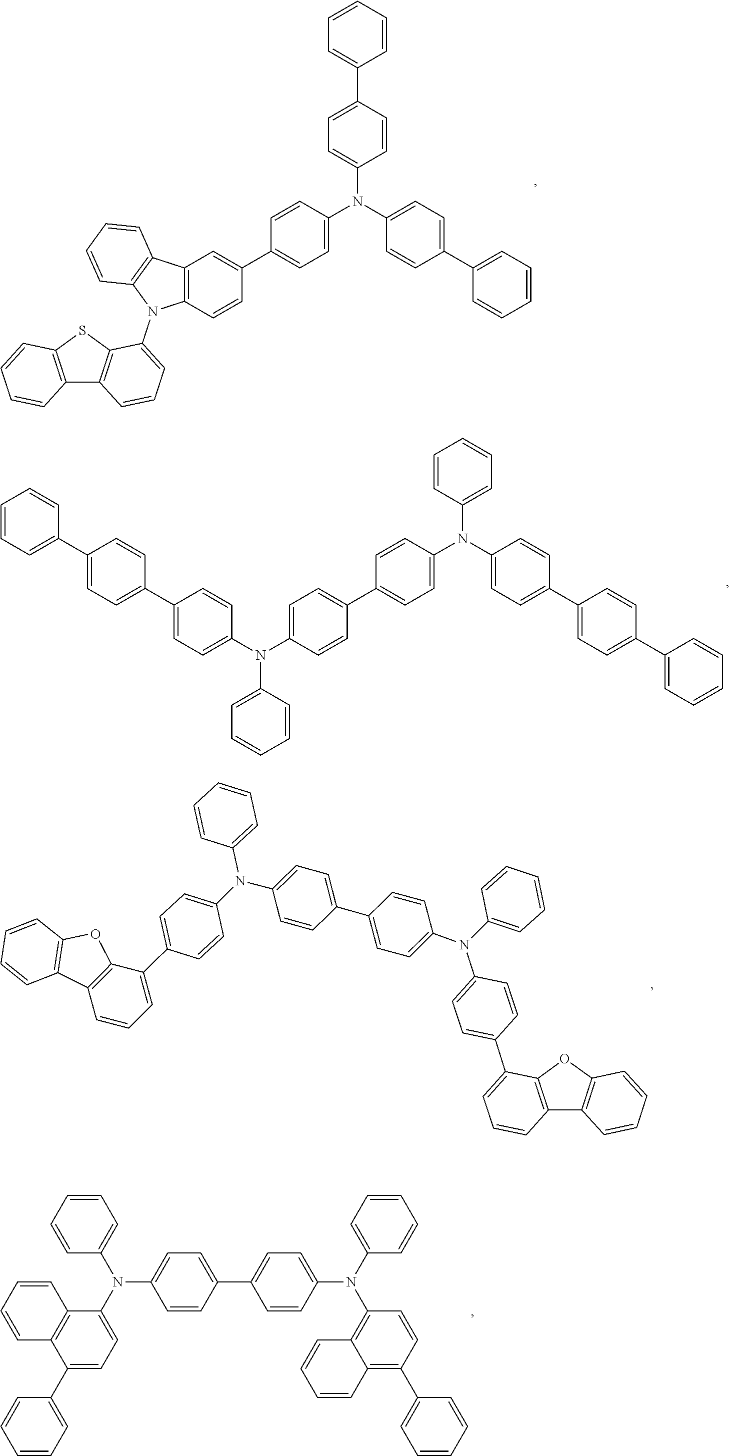

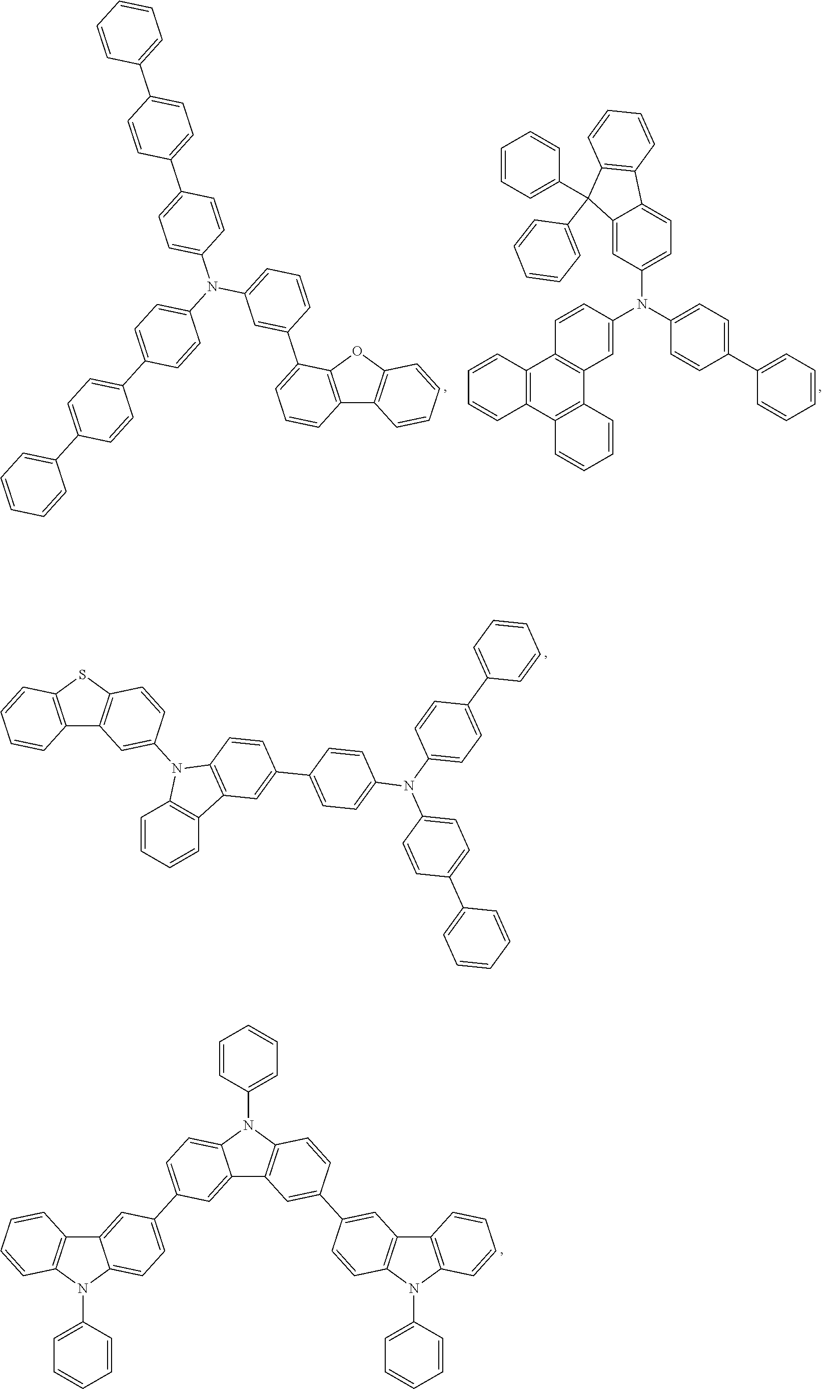

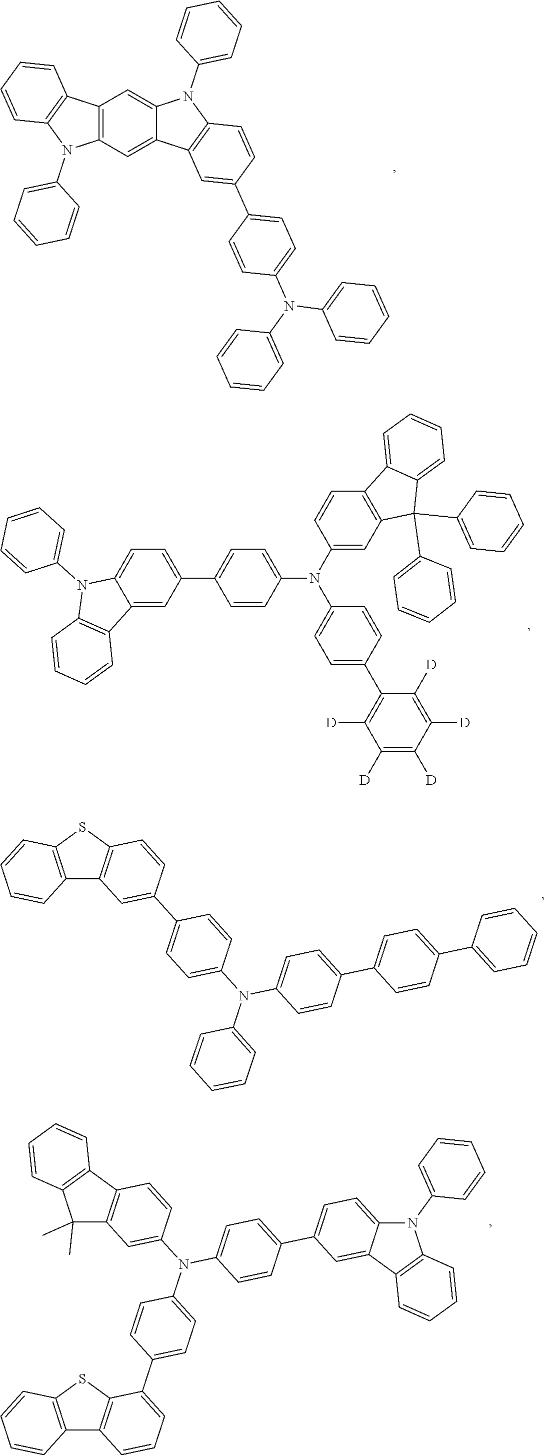 [SMILES: c1ccc(N(c2ccccc2)c2ccc(-c3ccc4c(c3)c3cc5c(cc3n4-c3ccccc3)c3ccccc3n5-c3ccccc3)cc2)cc1 ; [2H]c1c([2H])c([2H])c(-c2ccc(N(c3ccc(-c4ccc5c(c4)c4ccccc4n5-c4ccccc4)cc3)c3ccc4c(c3)C(c3ccccc3)(c3ccccc3)c3ccccc3-4)cc2)c([2H])c1[2H] ; c1ccc(-c2ccc(-c3ccc(N(c4ccccc4)c4ccc(-c5ccc6sc7ccccc7c6c5)cc4)cc3)cc2)cc1 ; CC1(C)c2ccccc2-c2ccc(N(c3ccc(-c4ccc5c(c4)c4ccccc4n5-c4ccccc4)cc3)c3ccc(-c4cccc5c4sc4ccccc45)cc3)cc21]

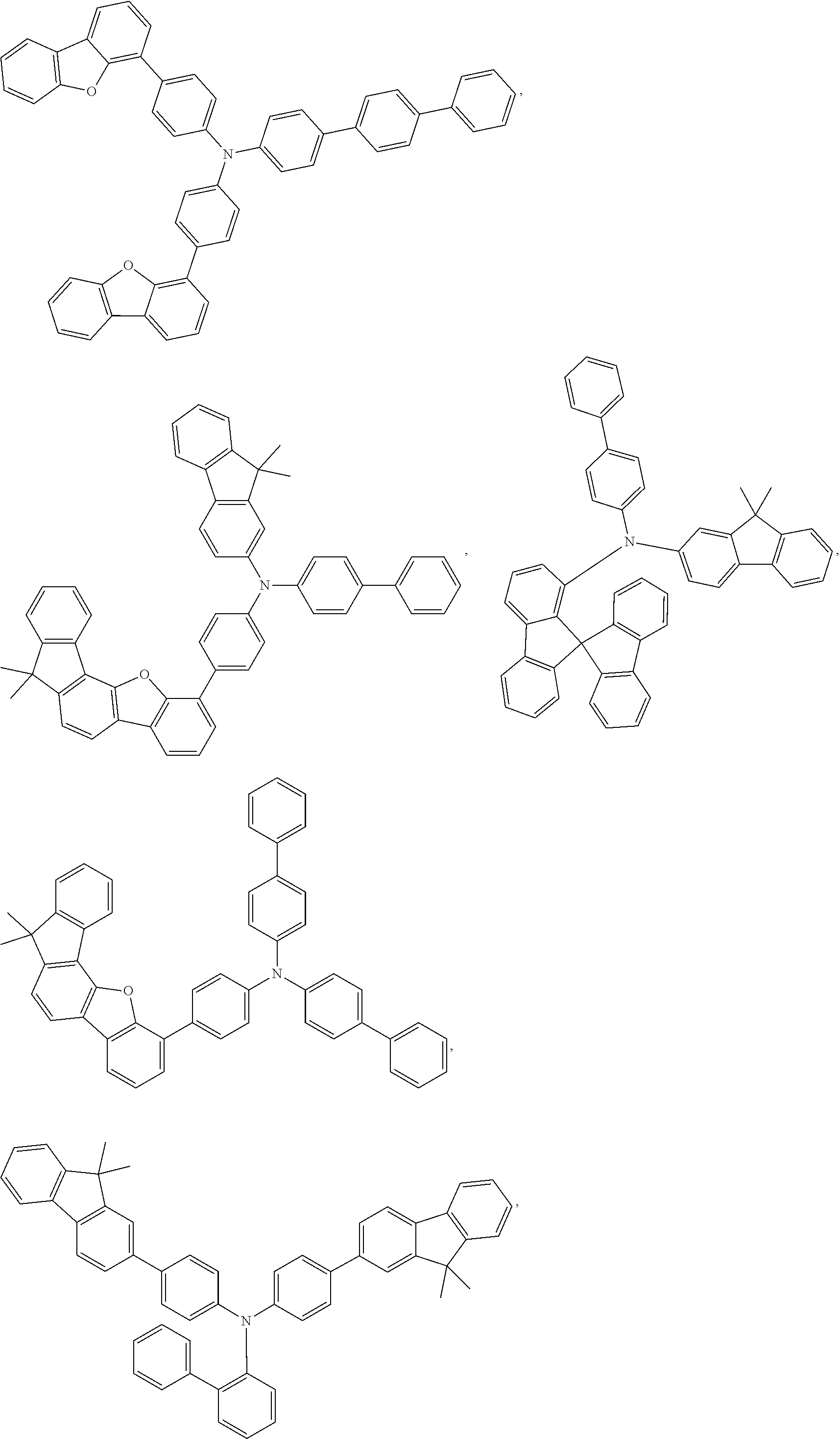 [SMILES: c1ccc(-c2ccc(-c3ccc(N(c4ccc(-c5cccc6c5oc5ccccc56)cc4)c4ccc(-c5cccc6c5oc5ccccc56)cc4)cc3)cc2)cc1 ; CC1(C)c2ccccc2-c2ccc(N(c3ccc(-c4ccccc4)cc3)c3ccc(-c4cccc5c4oc4c6c(ccc45)C(C)(C)c4ccccc4-6)cc3)cc21 ; CC1(C)c2ccccc2-c2ccc(N(c3ccc(-c4ccccc4)cc3)c3cccc4c3C3(c5ccccc5-c5ccccc53)c3ccccc3-4)cc21 ; CC1(C)c2ccccc2-c2c1ccc1c2oc2c(-c3ccc(N(c4ccc(-c5ccccc5)cc4)c4ccc(-c5ccccc5)cc4)cc3)cccc21 ; CC1(C)c2ccccc2-c2ccc(-c3ccc(N(c4ccc(-c5ccc6c(c5)C(C)(C)c5ccccc5-6)cc4)c4ccccc4-c4ccccc4)cc3)cc21]

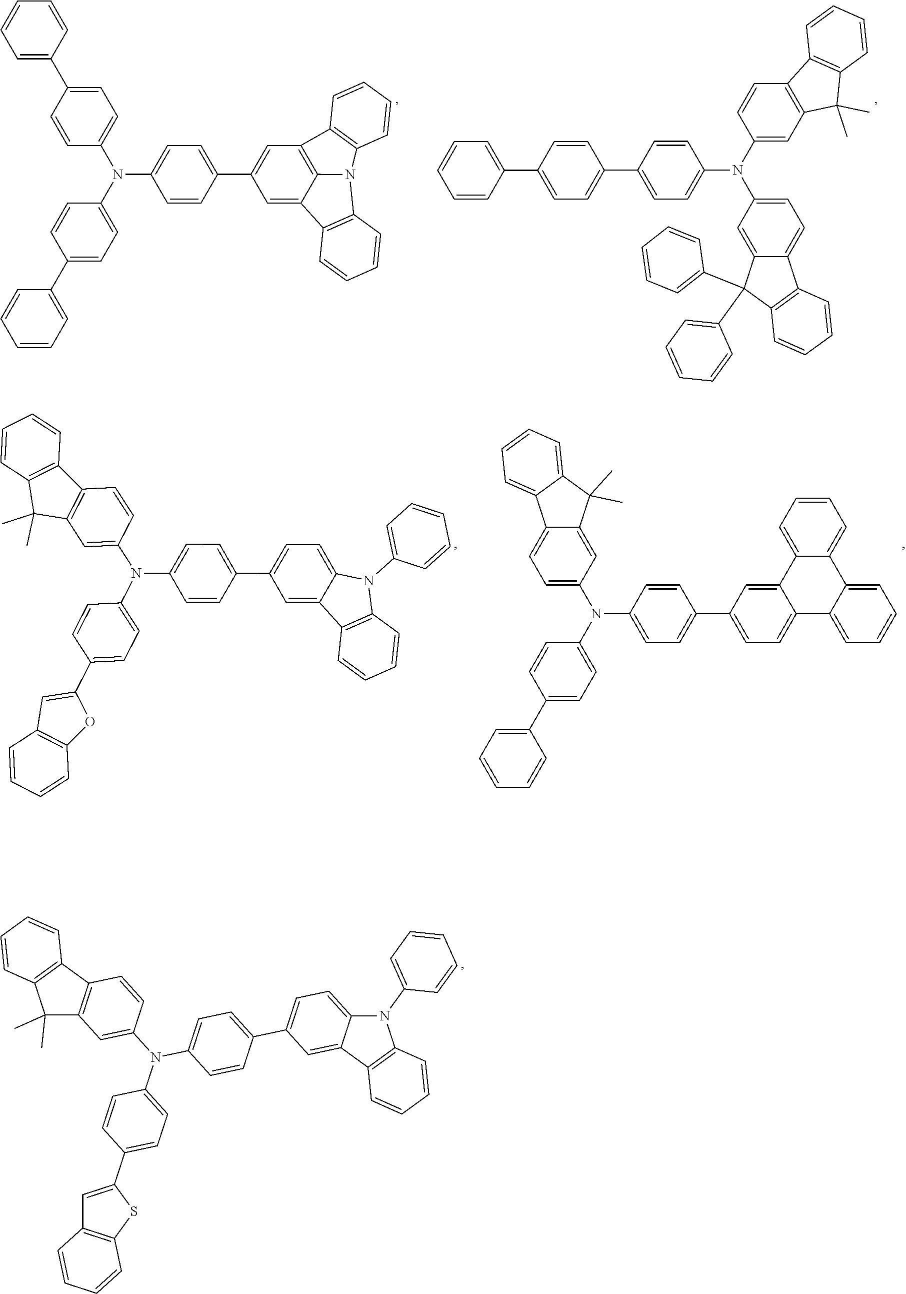 [SMILES: c1ccc(-c2ccc(N(c3ccc(-c4ccccc4)cc3)c3ccc(-c4cc5c6ccccc6n6c7ccccc7c(c4)c56)cc3)cc2)cc1 ; CC1(C)c2ccccc2-c2ccc(N(c3ccc(-c4ccc(-c5ccccc5)cc4)cc3)c3ccc4c(c3)C(c3ccccc3)(c3ccccc3)c3ccccc3-4)cc21 ; CC1(C)c2ccccc2-c2ccc(N(c3ccc(-c4ccc5c(c4)c4ccccc4n5-c4ccccc4)cc3)c3ccc(-c4cc5ccccc5o4)cc3)cc21 ; CC1(C)c2ccccc2-c2ccc(N(c3ccc(-c4ccccc4)cc3)c3ccc(-c4ccc5c6ccccc6c6ccccc6c5c4)cc3)cc21 ; CC1(C)c2ccccc2-c2ccc(N(c3ccc(-c4ccc5c(c4)c4ccccc4n5-c4ccccc4)cc3)c3ccc(-c4cc5ccccc5s4)cc3)cc21]

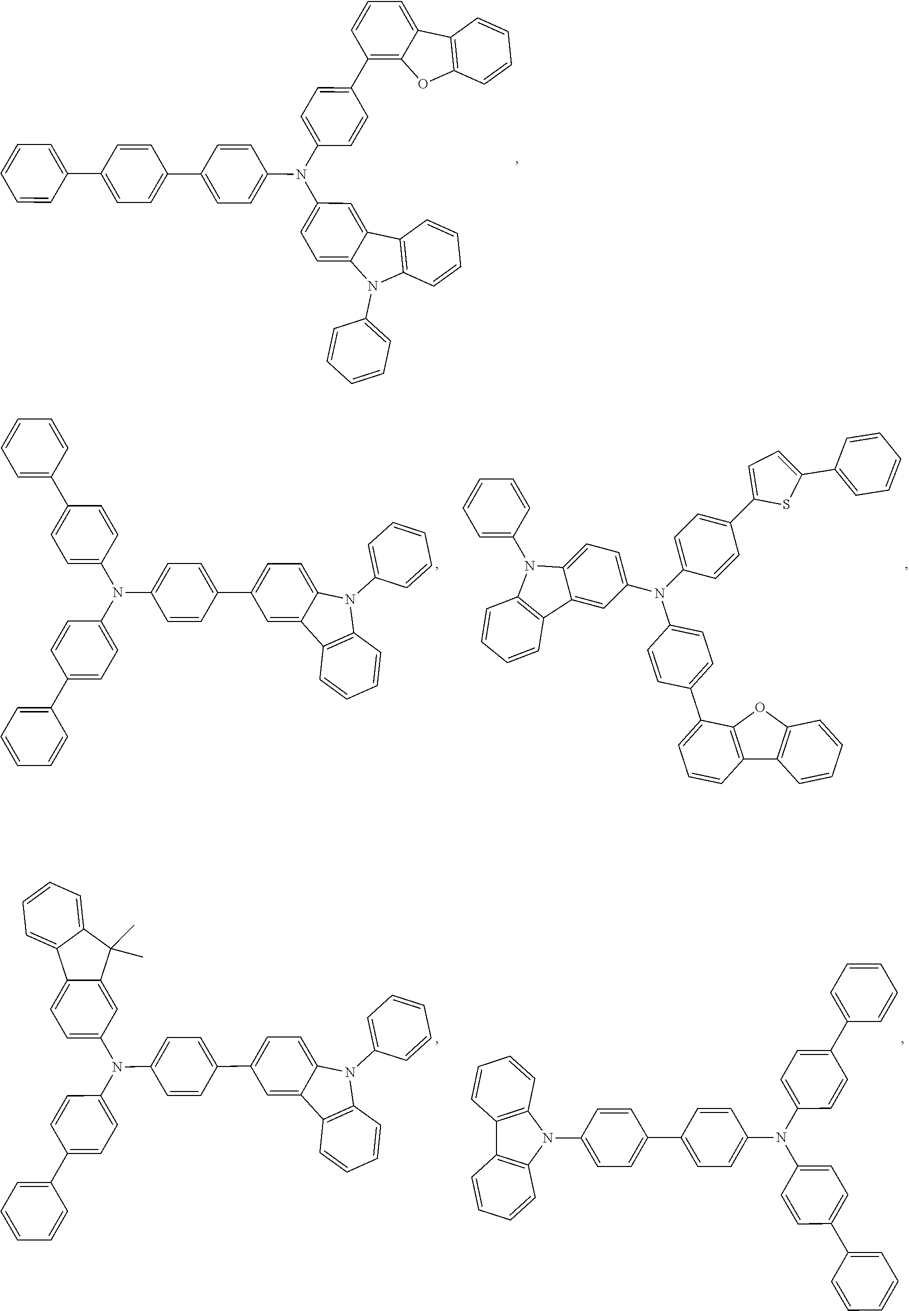

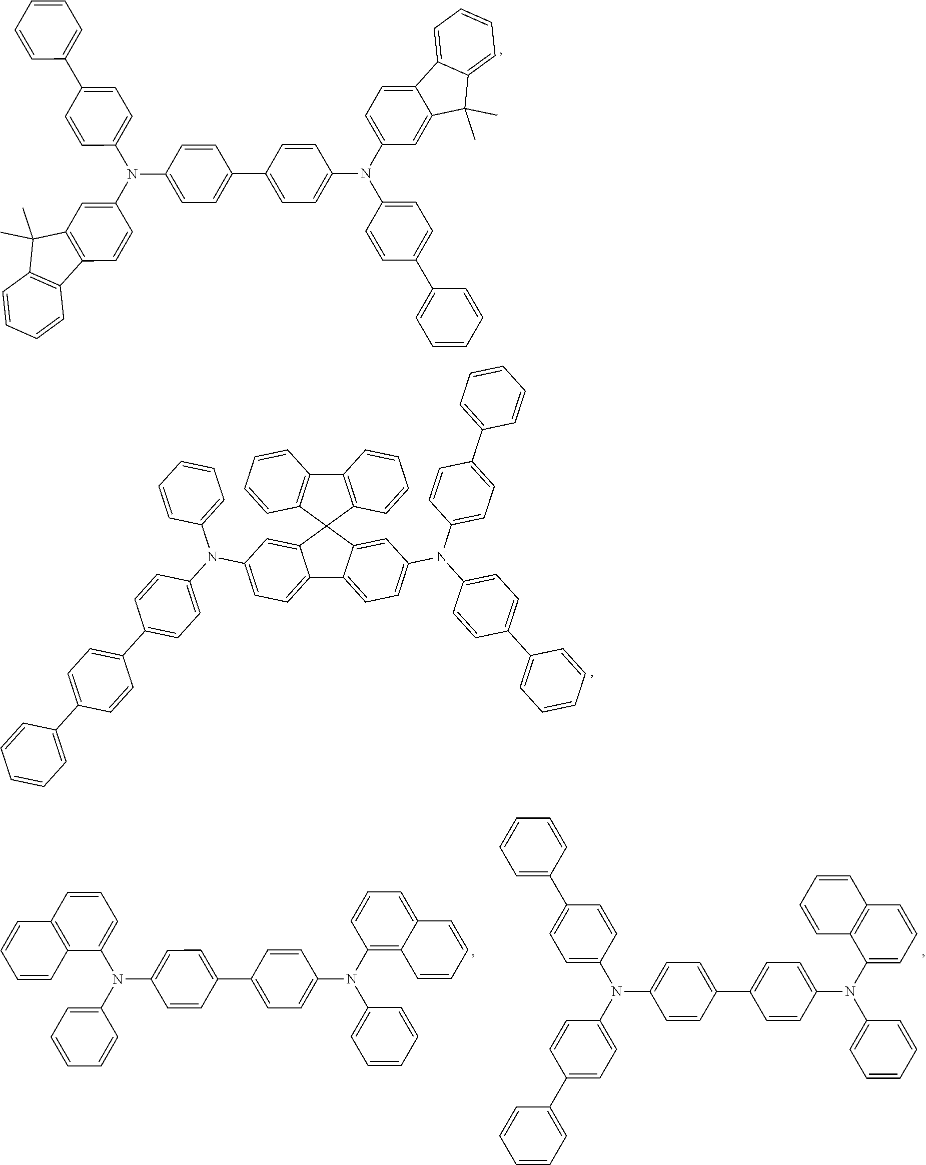

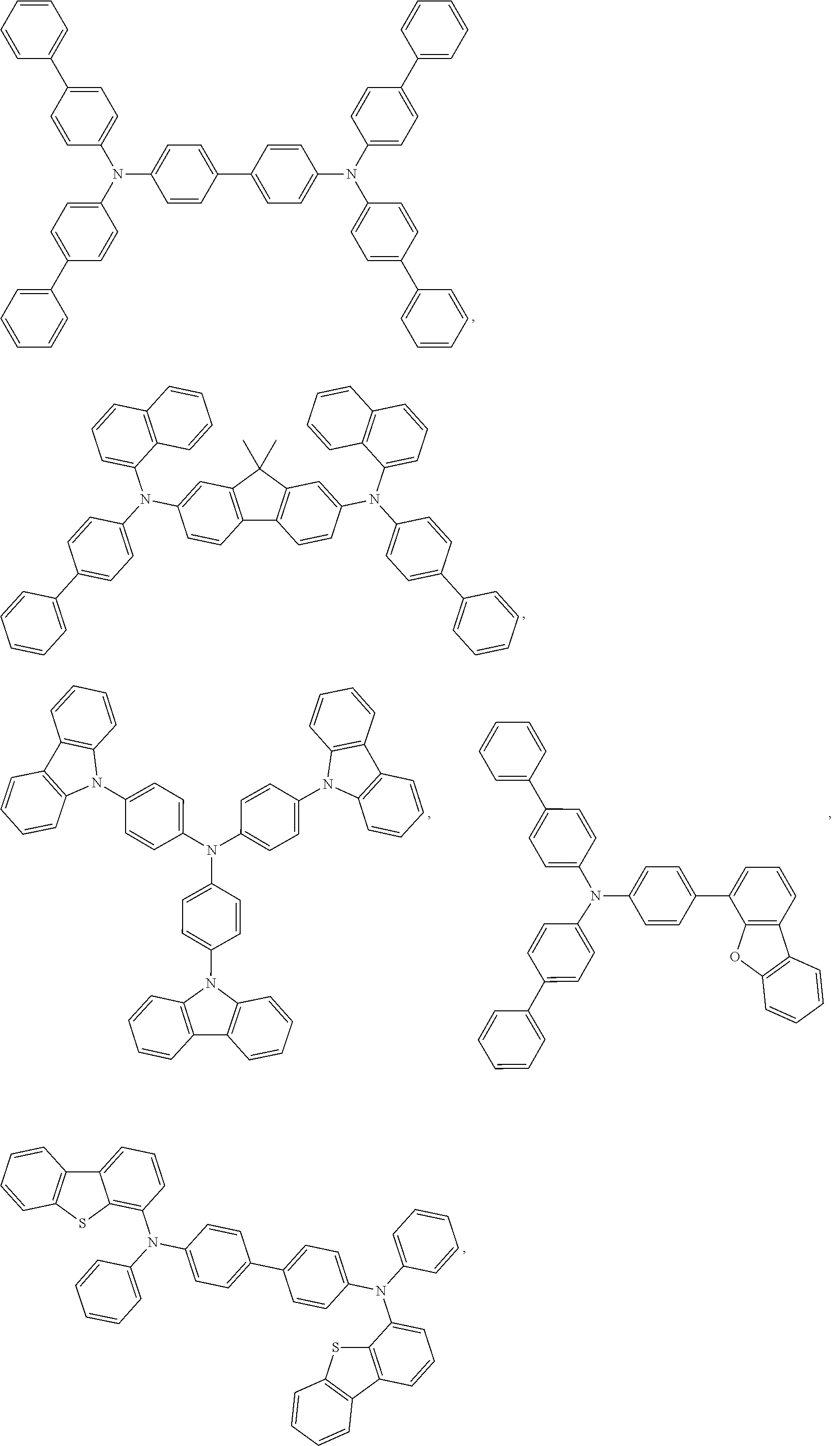

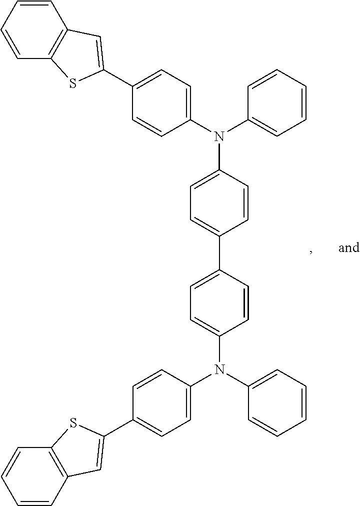 [SMILES: c1ccc(N(c2ccc(-c3ccc(N(c4ccccc4)c4ccc(-c5cc6ccccc6s5)cc4)cc3)cc2)c2ccc(-c3cc4ccccc4s3)cc2)cc1]

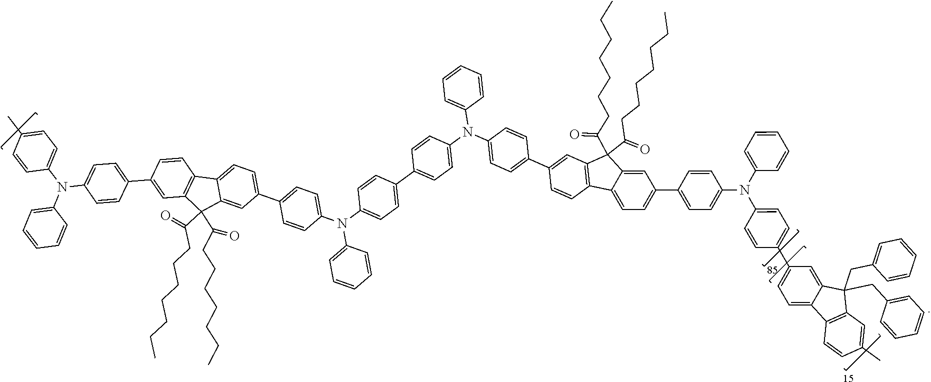

### c) EBL:

An electron blocking layer (EBL) may be used to reduce the number of electrons and/or excitons that leave the emissive layer. The presence of such a blocking layer in a device may result in substantially higher efficiencies, and/or longer lifetime, as compared to a similar device lacking a blocking layer. Also, a blocking layer may be used to confine emission to a desired region of an OLED. In some embodiments, the EBL material has a higher LUMO (closer to the vacuum level) and/or higher triplet energy than the emitter closest to the EBL interface. In some embodiments, the EBL material has a higher LUMO (closer to the vacuum level) and/or higher triplet energy than one or more of the hosts closest to the EBL interface. In one aspect, the compound used in EBL contains the same molecule or the same functional groups used as one of the hosts described below.
d) Hosts:

The light emitting layer of the organic EL device of the present disclosure preferably contains at least a metal complex as light emitting material, and may contain a host material using the metal complex as a dopant material. Examples of the host material are not particularly limited, and any metal complexes or organic compounds may be used as long as the triplet energy of the host is larger than that of the dopant. Any host material may be used with any dopant so long as the triplet criteria is satisfied.

Examples of metal complexes used as host are preferred to have the following general formula:

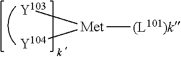

wherein Met is a metal; (Y¹⁰³-Y¹⁰⁴) is a bidentate ligand, Y¹⁰³ and Y¹⁰⁴ are independently selected from C, N, O, P, and S; L¹⁰¹ is an another ligand; k′ is an integer value from 1 to the maximum number of ligands that may be attached to the metal; and k′+k″ is the maximum number of ligands that may be attached to the metal.

In one aspect, the metal complexes are:

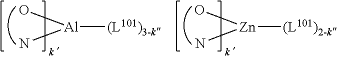

wherein (O—N) is a bidentate ligand, having metal coordinated to atoms O and N.

In another aspect, Met is selected from Ir and Pt. In a further aspect, (Y¹⁰³-Y¹⁰⁴) is a carbene ligand.

In one aspect, the host compound contains at least one of the following groups selected from the group consisting of aromatic hydrocarbon cyclic compounds such as benzene, biphenyl, triphenyl, triphenylene, tetraphenylene, naphthalene, anthracene, phenalene, phenanthrene, fluorene, pyrene, chrysene, perylene, and azulene; the group consisting of aromatic heterocyclic compounds such as dibenzothiophene, dibenzofuran, dibenzoselenophene, furan, thiophene, benzofuran, benzothiophene, benzoselenophene, carbazole, indolocarbazole, pyridylindole, pyrrolodipyridine, pyrazole, imidazole, triazole, oxazole, thiazole, oxadiazole, oxatriazole, dioxazole, thiadiazole, pyridine, pyridazine, pyrimidine, pyrazine, triazine, oxazine, oxathiazine, oxadiazine, indole, benzimidazole, indazole, indoxazine, benzoxazole, benzisoxazole, benzothiazole, quinoline, isoquinoline, cinnoline, quinazoline, quinoxaline, naphthyridine, phthalazine, pteridine, xanthene, acridine, phenazine, phenothiazine, phenoxazine, benzofuropyridine, furodipyridine, benzothienopyridine, thienodipyridine, benzoselenophenopyridine, and selenophenodipyridine; and the group consisting of 2 to 10 cyclic structural units which are groups of the same type or different types selected from the aromatic hydrocarbon cyclic group and the aromatic heterocyclic group and are bonded to each other directly or via at least one of oxygen atom, nitrogen atom, sulfur atom, silicon atom, phosphorus atom, boron atom, chain structural unit and the aliphatic cyclic group. Each option within each group may be unsubstituted or may be substituted by a substituent selected from the group consisting of deuterium, halogen, alkyl, cycloalkyl, heteroalkyl, heterocycloalkyl, arylalkyl, alkoxy, aryloxy, amino, silyl, alkenyl, cycloalkenyl, heteroalkenyl, alkynyl, aryl, heteroaryl, acyl, carboxylic acids, ether, ester, nitrile, isonitrile, sulfanyl, sulfinyl, sulfonyl, phosphino, and combinations thereof.

In one aspect, the host compound contains at least one of the following groups in the molecule:

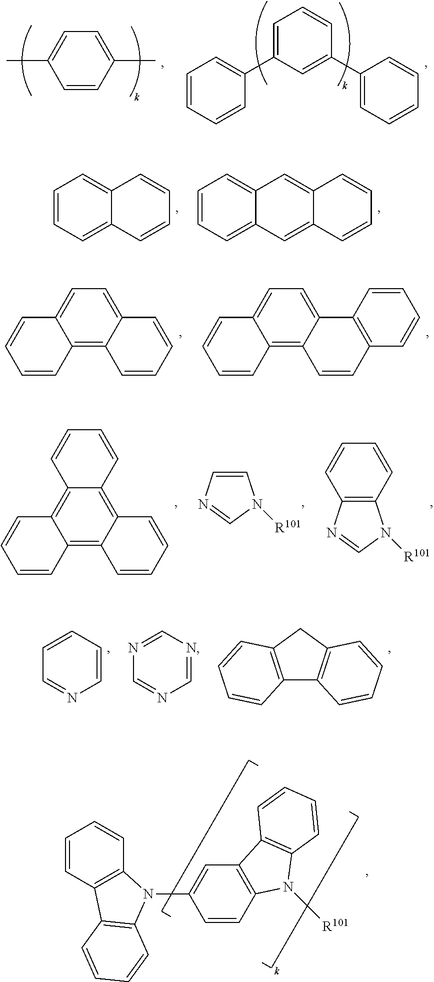

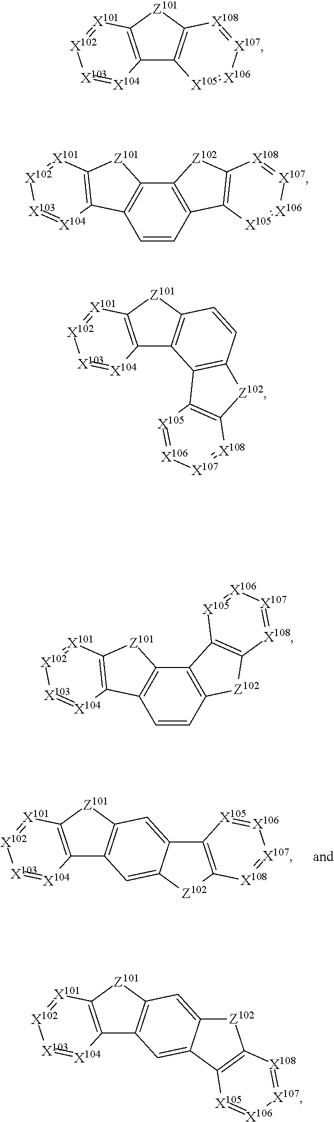

wherein R¹⁰¹ is selected from the group consisting of hydrogen, deuterium, halogen, alkyl, cycloalkyl, heteroalkyl, heterocycloalkyl, arylalkyl, alkoxy, aryloxy, amino, silyl, alkenyl, cycloalkenyl, heteroalkenyl, alkynyl, aryl, heteroaryl, acyl, carboxylic acids, ether, ester, nitrile, isonitrile, sulfanyl, sulfinyl, sulfonyl, phosphino, and combinations thereof, and when it is aryl or heteroaryl, it has the similar definition as Ar's mentioned above. k is an integer from 0 to 20 or 1 to 20. X¹⁰¹ to X¹⁰⁸ are independently selected from C (including CH) or N. Z¹⁰¹ and Z¹⁰² are independently selected from NR¹⁰¹, O, or S.

Non-limiting examples of the host materials that may be used in an OLED in combination with materials disclosed herein are exemplified below together with references that disclose those materials: EP2034538, EP2034538A, EP2757608, JP2007254297, KR20100079458, KR20120088644, KR20120129733, KR20130115564, TW201329200, US20030175553, US20050238919, US20060280965, US20090017330, US20090030202, US20090167162, US20090302743, US20090309488, US20100012931, US20100084966, US20100187984, US2010187984, US2012075273, US2012126221, US2013009543, US2013105787, US2013175519, US2014001446, US20140183503, US20140225088, US2014034914, U.S. Pat. No. 7,154,114, WO2001039234, WO2004093207, WO2005014551, WO2005089025, WO2006072002, WO2006114966, WO2007063754, WO2008056746, WO2009003898, WO2009021126, WO2009063833, WO2009066778, WO2009066779, WO2009086028, WO2010056066, WO2010107244, WO2011081423, WO2011081431, WO2011086863, WO2012128298, WO2012133644, WO2012133649, WO2013024872, WO2013035275, WO2013081315, WO2013191404, WO2014142472, US20170263869, US20160163995, U.S. Pat. No. 9,466,803,

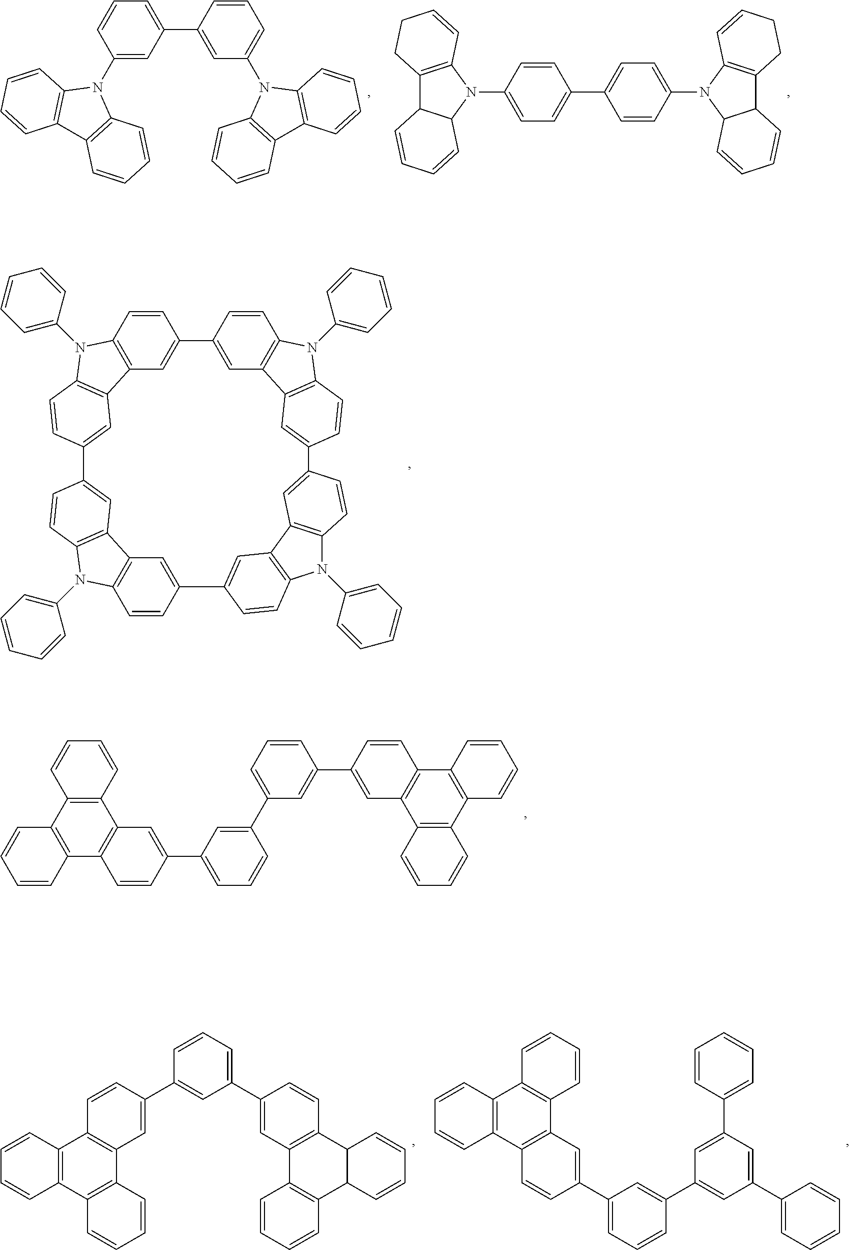

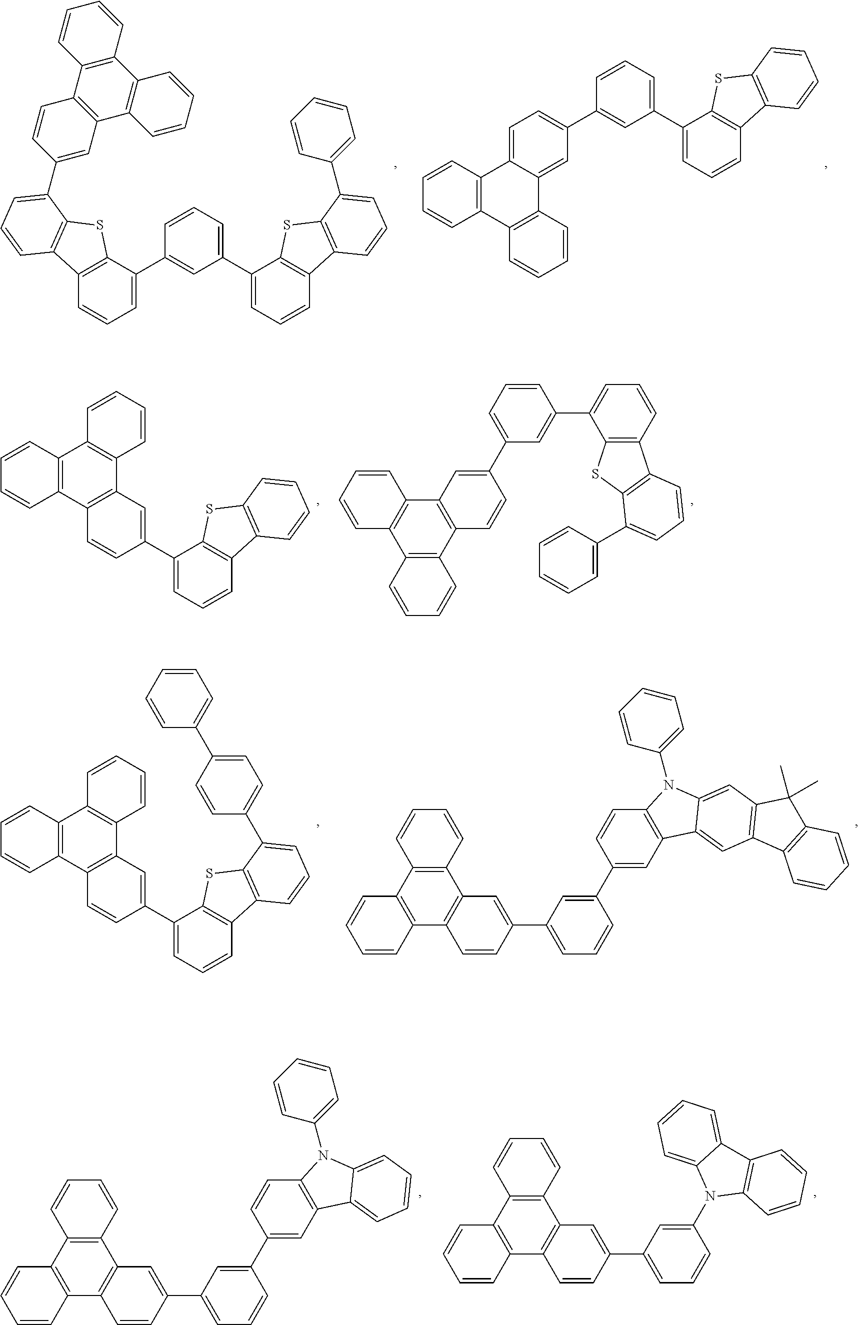

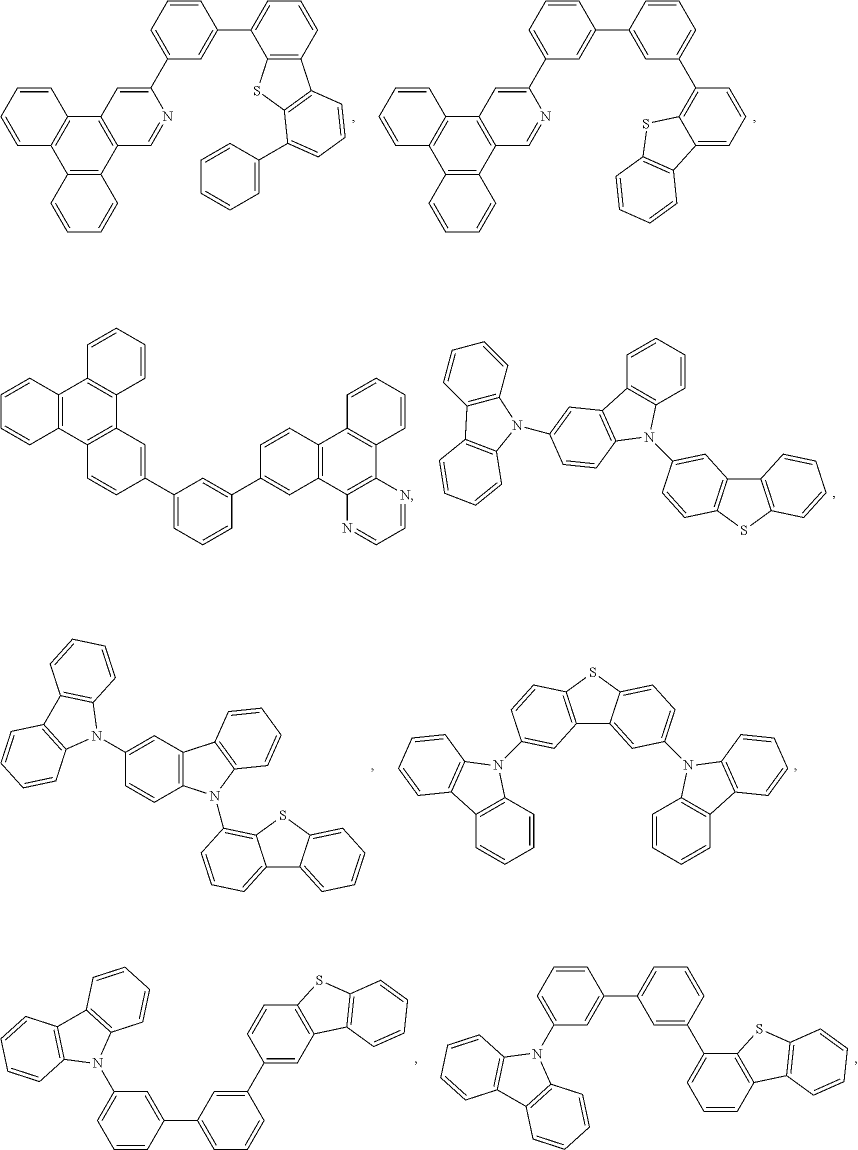

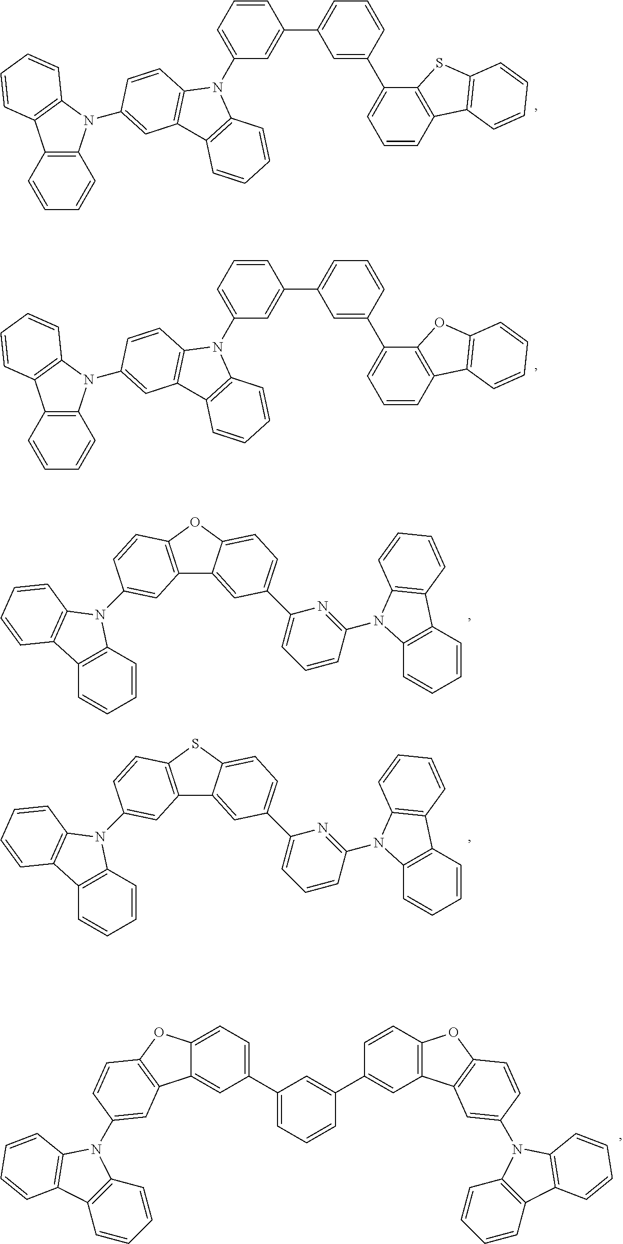 [SMILES: c1cc(-c2cccc(-n3c4ccccc4c4cc(-n5c6ccccc6c6ccccc65)ccc43)c2)cc(-c2cccc3c2sc2ccccc23)c1 ; c1cc(-c2cccc(-n3c4ccccc4c4cc(-n5c6ccccc6c6ccccc65)ccc43)c2)cc(-c2cccc3c2oc2ccccc23)c1 ; c1cc(-c2ccc3oc4ccc(-n5c6ccccc6c6ccccc65)cc4c3c2)nc(-n2c3ccccc3c3ccccc32)c1 ; c1cc(-c2ccc3sc4ccc(-n5c6ccccc6c6ccccc65)cc4c3c2)nc(-n2c3ccccc3c3ccccc32)c1 ; c1cc(-c2ccc3oc4ccc(-n5c6ccccc6c6ccccc65)cc4c3c2)cc(-c2ccc3oc4ccc(-n5c6ccccc6c6ccccc65)cc4c3c2)c1]

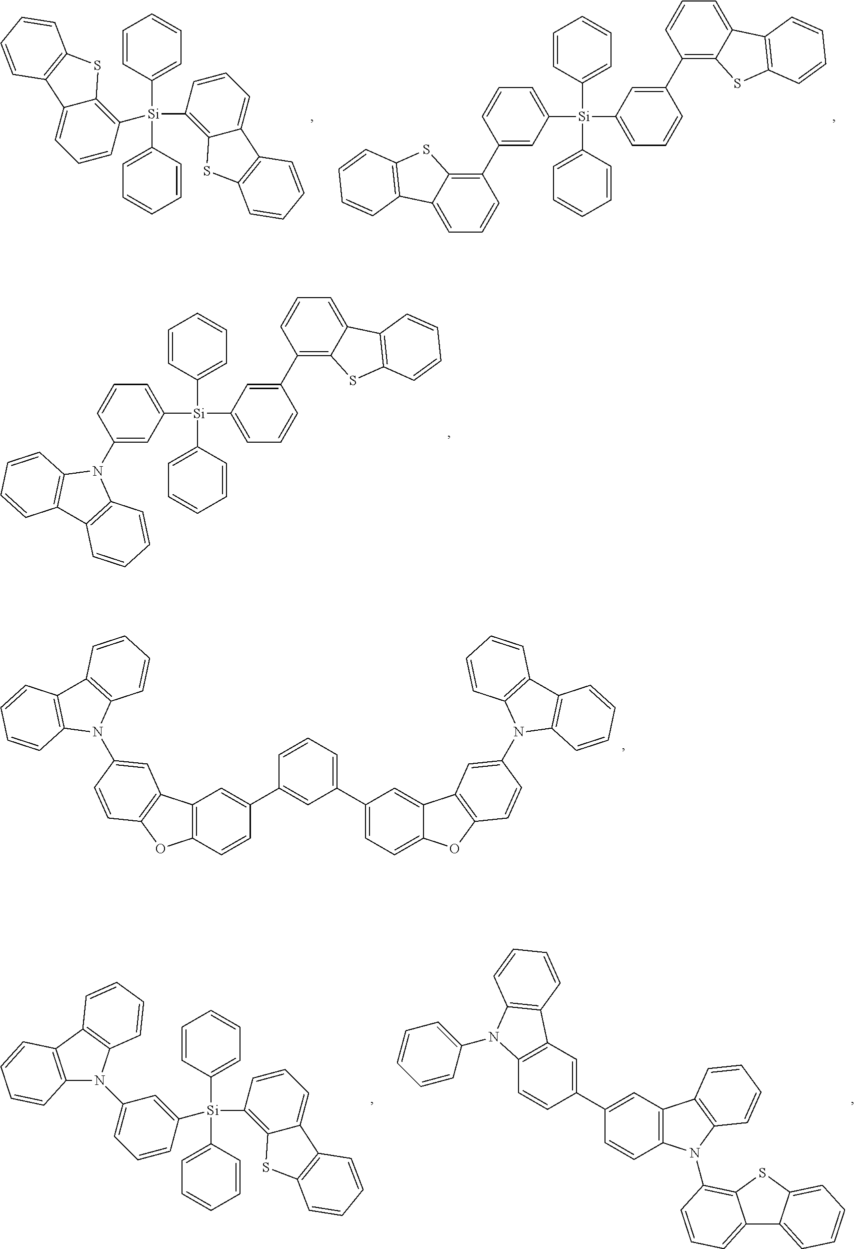

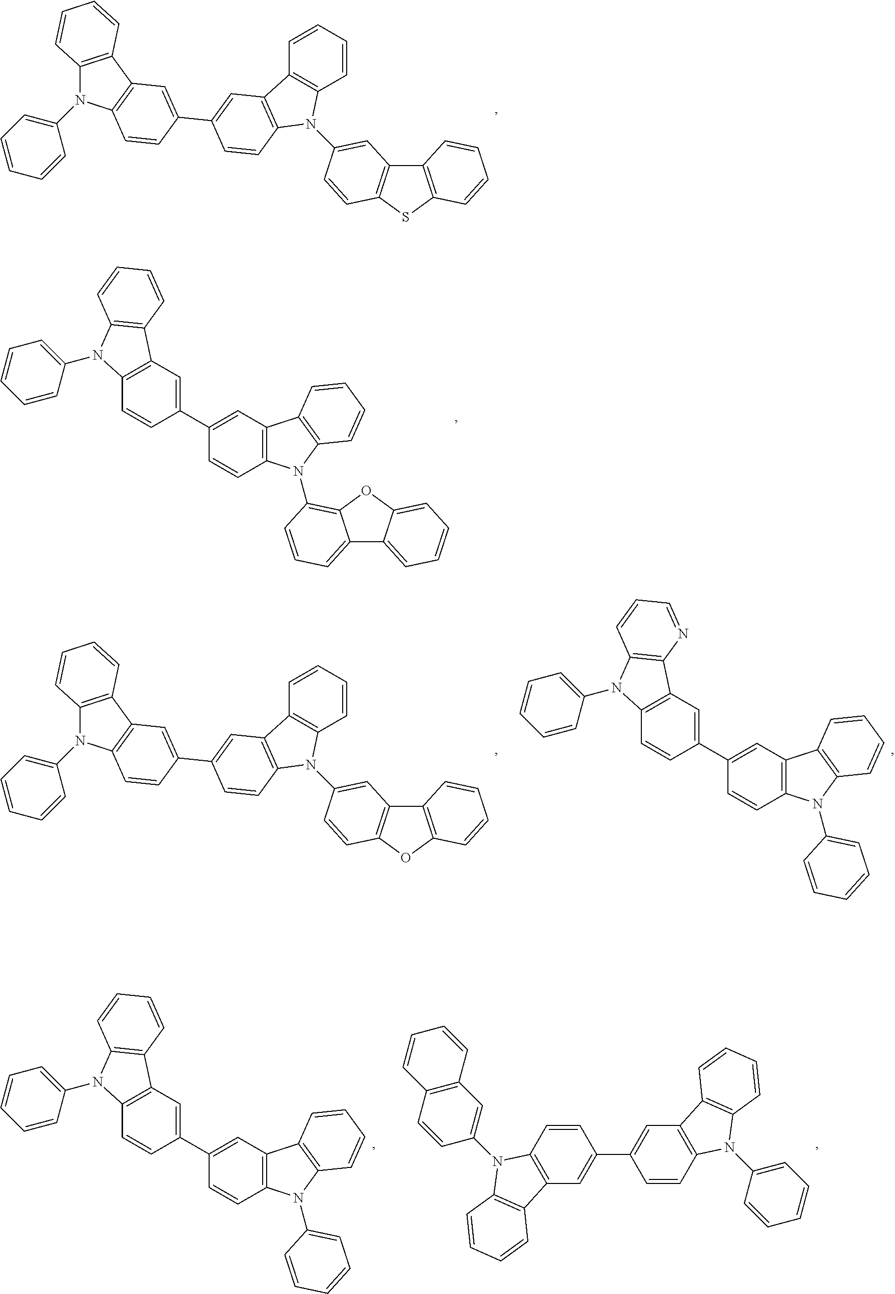 [SMILES: c1ccc(-n2c3ccccc3c3cc(-c4ccc5c(c4)c4ccccc4n5-c4ccc5sc6ccccc6c5c4)ccc32)cc1 ; c1ccc(-n2c3ccccc3c3cc(-c4ccc5c(c4)c4ccccc4n5-c4cccc5c4oc4ccccc45)ccc32)cc1 ; c1ccc(-n2c3ccccc3c3cc(-c4ccc5c(c4)c4ccccc4n5-c4ccc5oc6ccccc6c5c4)ccc32)cc1 ; c1ccc(-n2c3ccccc3c3cc(-c4ccc5c(c4)c4ncccc4n5-c4ccccc4)ccc32)cc1 ; c1ccc(-n2c3ccccc3c3cc(-c4ccc5c(c4)c4ccccc4n5-c4ccccc4)ccc32)cc1 ; c1ccc(-n2c3ccccc3c3cc(-c4ccc5c(c4)c4ccccc4n5-c4ccc5ccccc5c4)ccc32)cc1]

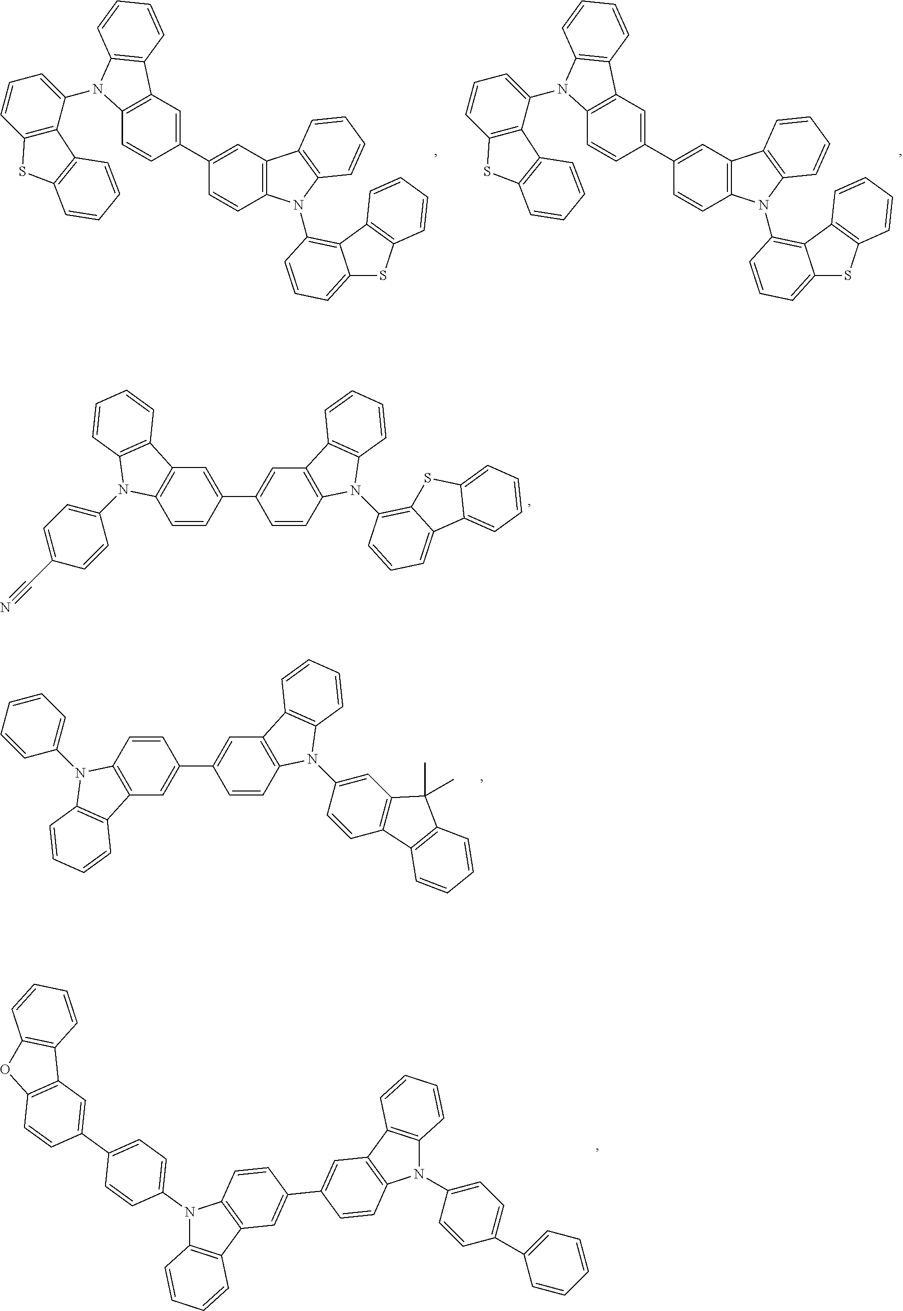 [SMILES: c1ccc2c(c1)sc1cccc(-n3c4ccccc4c4cc(-c5ccc6c(c5)c5ccccc5n6-c5cccc6sc7ccccc7c56)ccc43)c12 ; c1ccc2c(c1)sc1cccc(-n3c4ccccc4c4cc(-c5ccc6c(c5)c5ccccc5n6-c5cccc6sc7ccccc7c56)ccc43)c12 ; N#Cc1ccc(-n2c3ccccc3c3cc(-c4ccc5c(c4)c4ccccc4n5-c4cccc5c4sc4ccccc45)ccc32)cc1 ; CC1(C)c2ccccc2-c2ccc(-n3c4ccccc4c4cc(-c5ccc6c(c5)c5ccccc5n6-c5ccccc5)ccc43)cc21 ; c1ccc(-c2ccc(-n3c4ccccc4c4cc(-c5ccc6c(c5)c5ccccc5n6-c5ccc(-c6ccc7oc8ccccc8c7c6)cc5)ccc43)cc2)cc1]

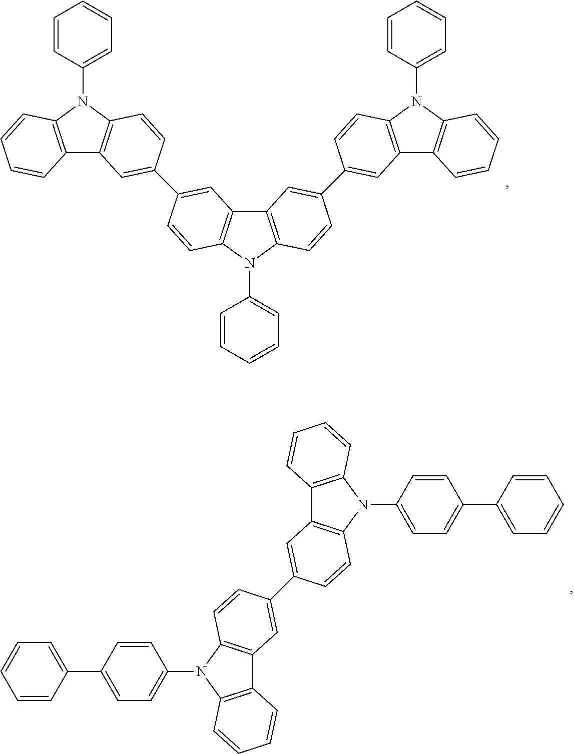 [SMILES: c1ccc(-n2c3ccccc3c3cc(-c4ccc5c(c4)c4cc(-c6ccc7c(c6)c6ccccc6n7-c6ccccc6)ccc4n5-c4ccccc4)ccc32)cc1 ; c1ccc(-c2ccc(-n3c4ccccc4c4cc(-c5ccc6c(c5)c5ccccc5n6-c5ccc(-c6ccccc6)cc5)ccc43)cc2)cc1]

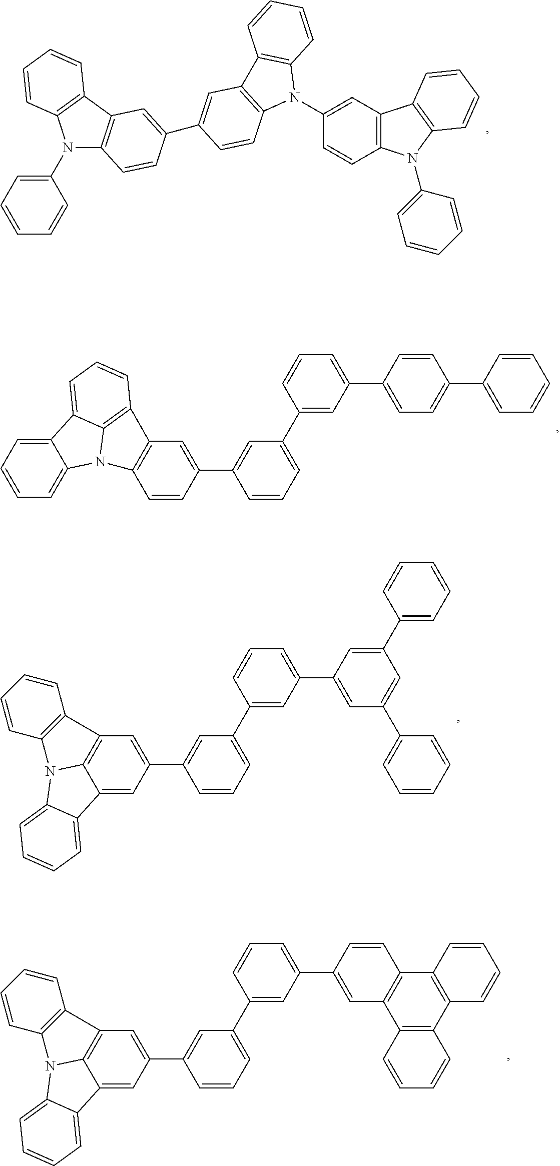 [SMILES: c1ccc(-n2c3ccccc3c3cc(-c4ccc5c(c4)c4ccccc4n5-c4ccc5c(c4)c4ccccc4n5-c4ccccc4)ccc32)cc1 ; c1ccc(-c2ccc(-c3cccc(-c4cccc(-c5ccc6c(c5)c5cccc7c8ccccc8n6c75)c4)c3)cc2)cc1 ; c1ccc(-c2cc(-c3ccccc3)cc(-c3cccc(-c4cccc(-c5cc6c7ccccc7n7c8ccccc8c(c5)c67)c4)c3)c2)cc1 ; c1cc(-c2cccc(-c3cc4c5ccccc5n5c6ccccc6c(c3)c45)c2)cc(-c2ccc3c4ccccc4c4ccccc4c3c2)c1]

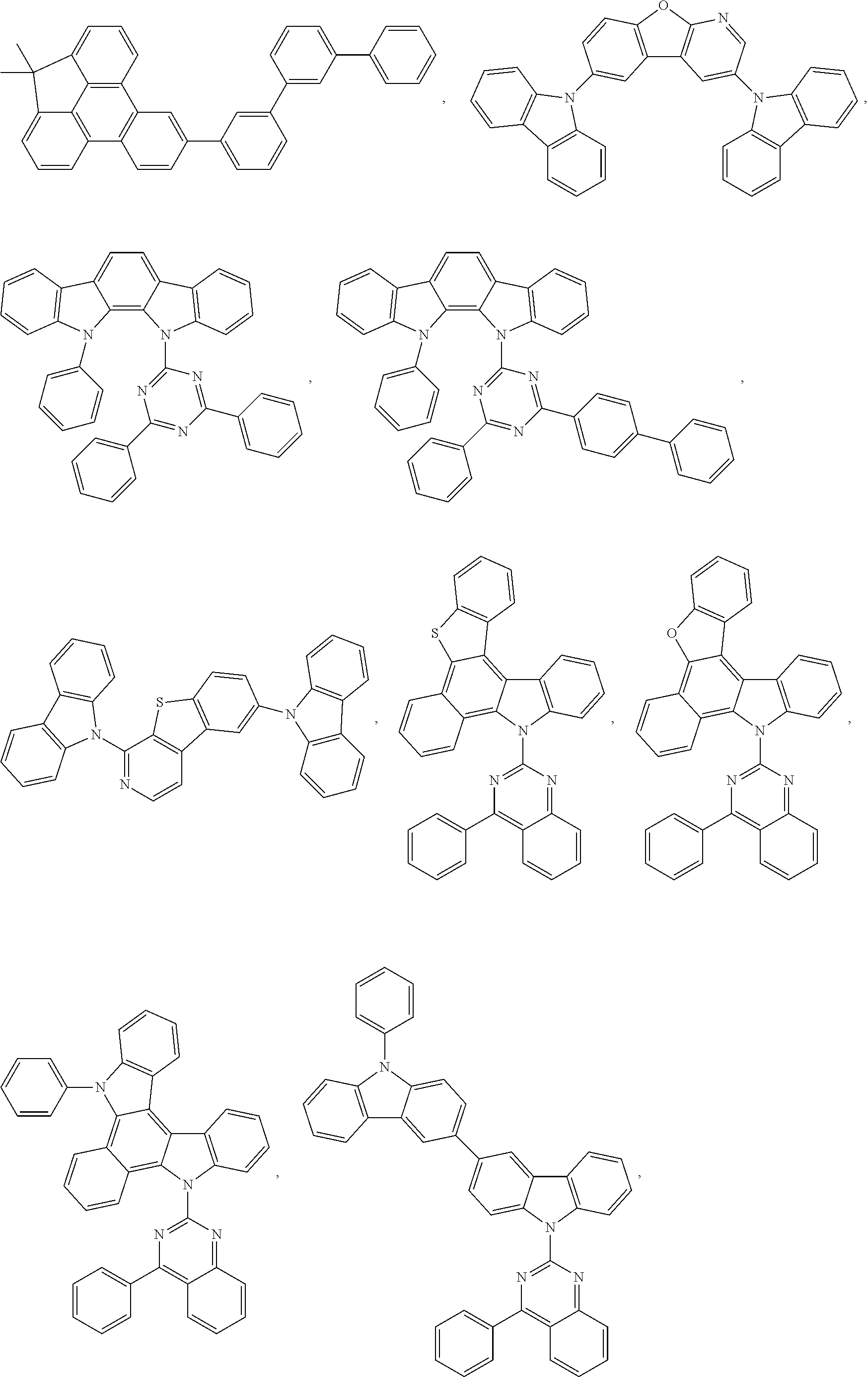

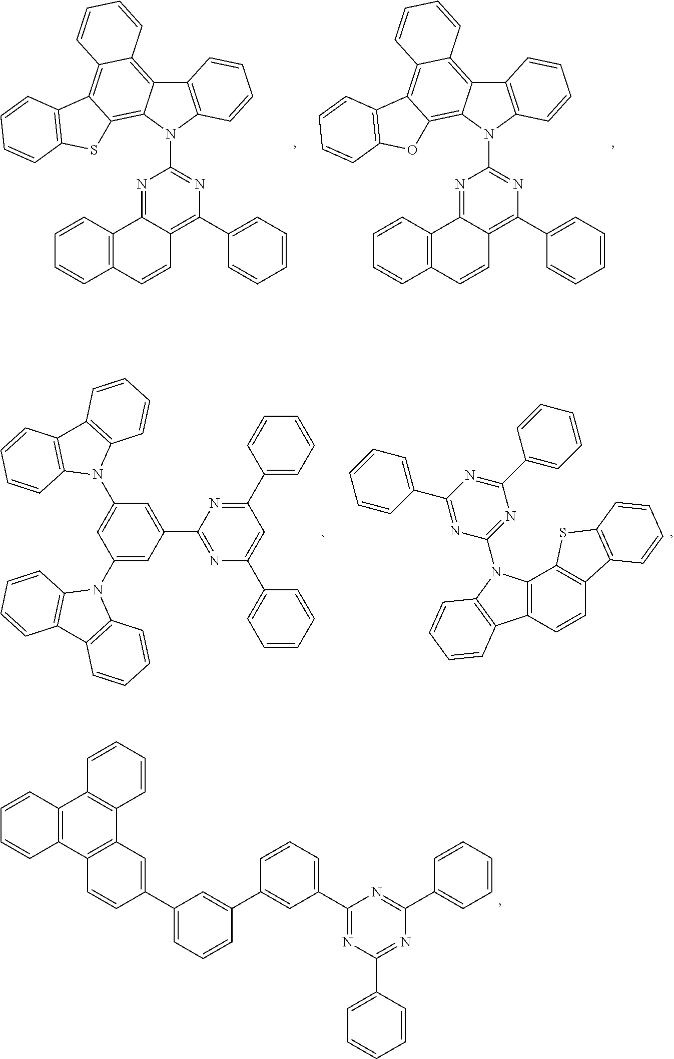

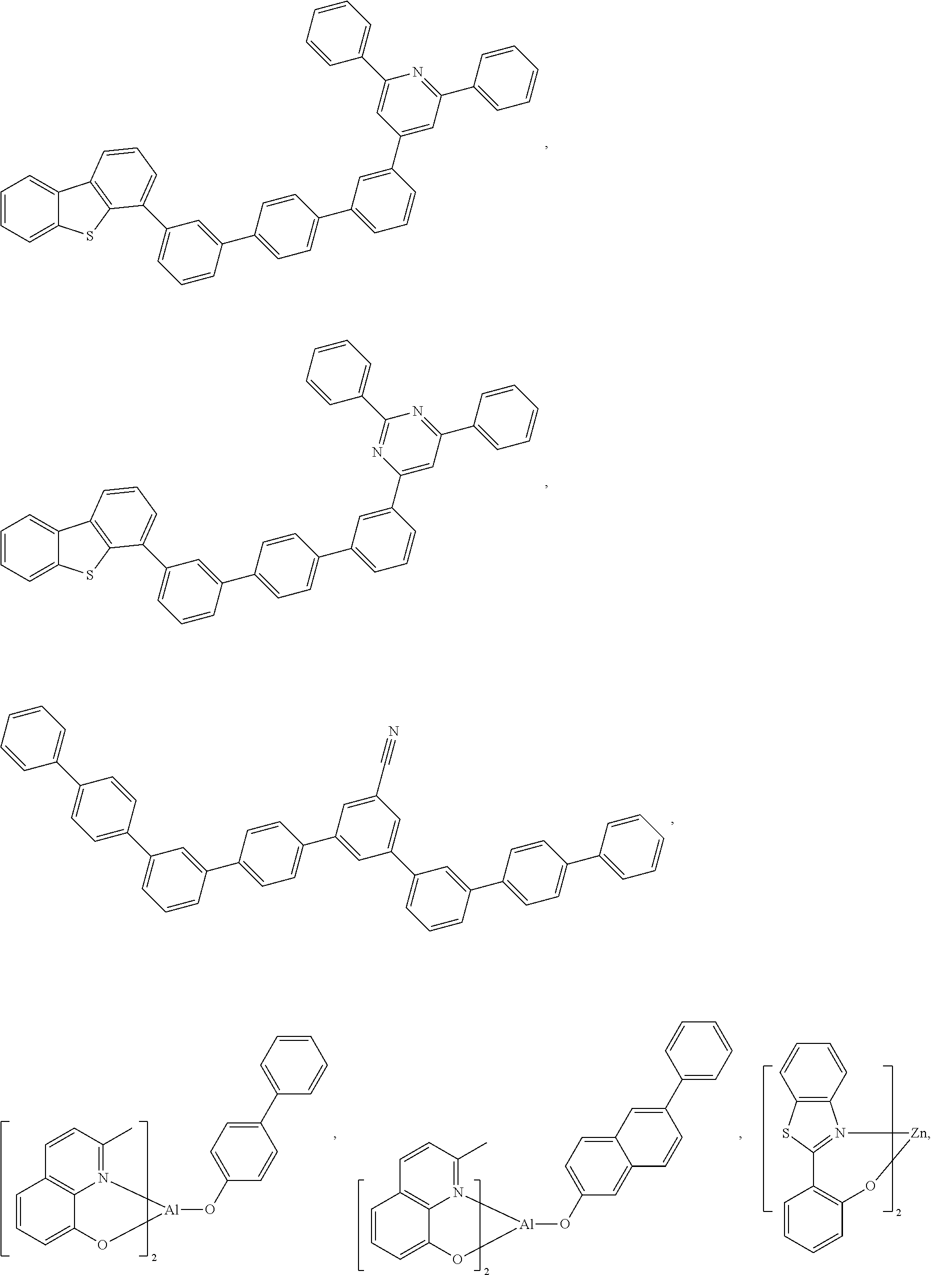

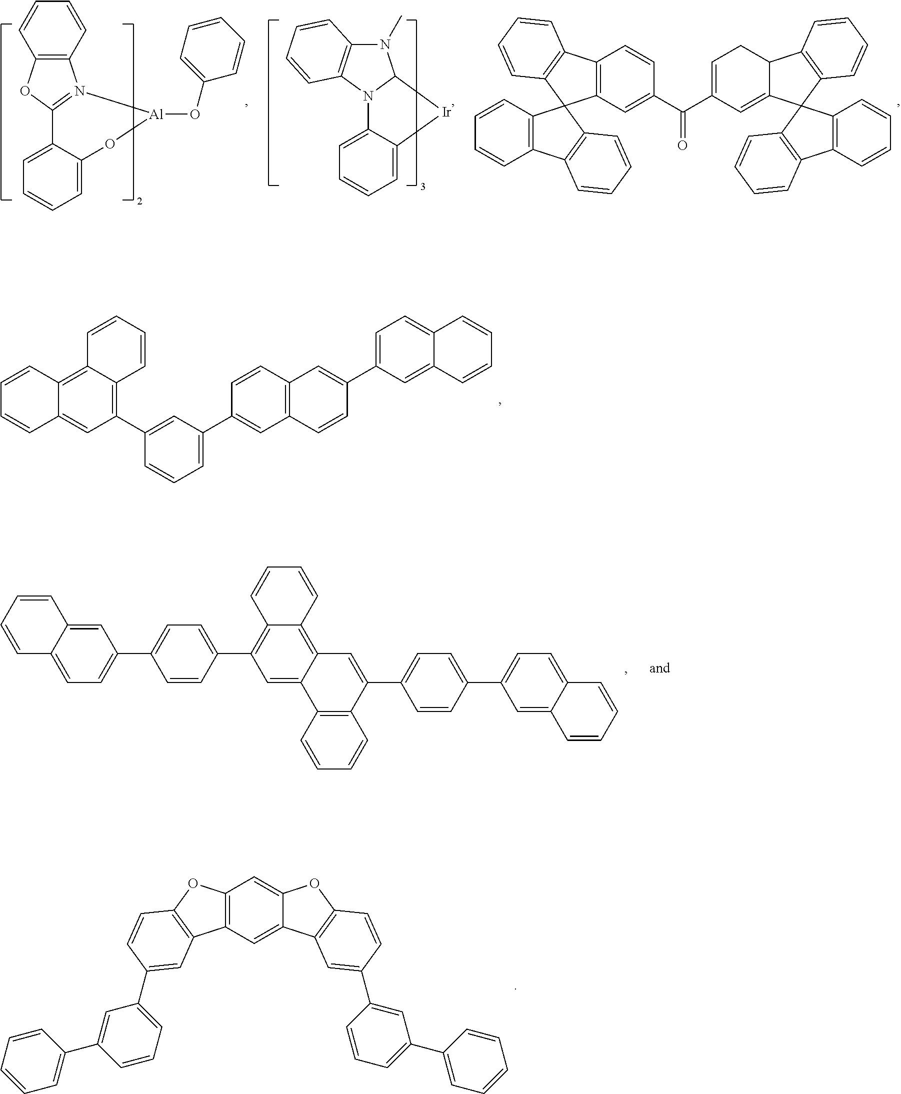

### e) Additional Emitters:

One or more additional emitter dopants may be used in conjunction with the compound of the present disclosure. Examples of the additional emitter dopants are not particularly limited, and any compounds may be used as long as the compounds are typically used as emitter materials. Examples of suitable emitter materials include, but are not limited to, compounds which can produce emissions via phosphorescence, fluorescence, thermally activated delayed fluorescence, i.e., TADF (also referred to as E-type delayed fluorescence), triplet-triplet annihilation, or combinations of these processes.

Non-limiting examples of the emitter materials that may be used in an OLED in combination with materials disclosed herein are exemplified below together with references that disclose those materials: CN103694277, CN1696137, EB01238981, EP01239526, EP01961743, EP1239526, EP1244155, EP1642951, EP1647554, EP1841834, EP1841834B, EP2062907, EP2730583, JP2012074444, JP2013110263, JP4478555, KR1020090133652, KR20120032054, KR20130043460, TW201332980, U.S. Ser. No. 06/699,599, U.S. Ser. No. 06/916,554, US20010019782, US20020034656, US20030068526, US20030072964, US20030138657, US20050123788, US20050244673, US2005123791, US2005260449, US20060008670, US20060065890, US20060127696, US20060134459, US20060134462, US20060202194, US20060251923, US20070034863, US20070087321, US20070103060, US20070111026, US20070190359, US20070231600, US2007034863, US2007104979, US2007104980, US2007138437, US2007224450, US2007278936, US20080020237, US20080233410, US20080261076, US20080297033, US200805851, US2008161567, US2008210930, US20090039776, US20090108737, US20090115322, US20090179555, US2009085476, US2009104472, US20100090591, US20100148663, US20100244004, US20100295032, US2010102716, US2010105902, US2010244004, US2010270916, US20110057559, US20110108822, US20110204333, US2011215710, US2011227049, US2011285275, US2012292601, US20130146848, US2013033172, US2013165653, US2013181190, US2013334521, US20140246656, US2014103305, U.S. Pat. Nos. 6,303,238, 6,413,656, 6,653,654, 6,670,645, 6,687,266, 6,835,469, 6,921,915, 7,279,704, 7,332,232, 7,378,162, 7,534,505, 7,675,228, 7,728,137, 7,740,957, 7,759,489, 7,951,947, 8,067,099, 8,592,586, 8,871,361, WO06081973, WO06121811, WO07018067, WO07108362, WO07115970, WO07115981, WO08035571, WO2002015645, WO2003040257, WO2005019373, WO2006056418, WO2008054584, WO2008078800, WO2008096609, WO2008101842, WO2009000673, WO2009050281, WO2009100991, WO2010028151, WO2010054731, WO2010086089, WO2010118029, WO2011044988, WO2011051404, WO2011107491, WO2012020327, WO2012163471, WO2013094620, WO2013107487, WO2013174471, WO2014007565, WO2014008982, WO2014023377, WO2014024131, WO2014031977, WO2014038456, WO2014112450.

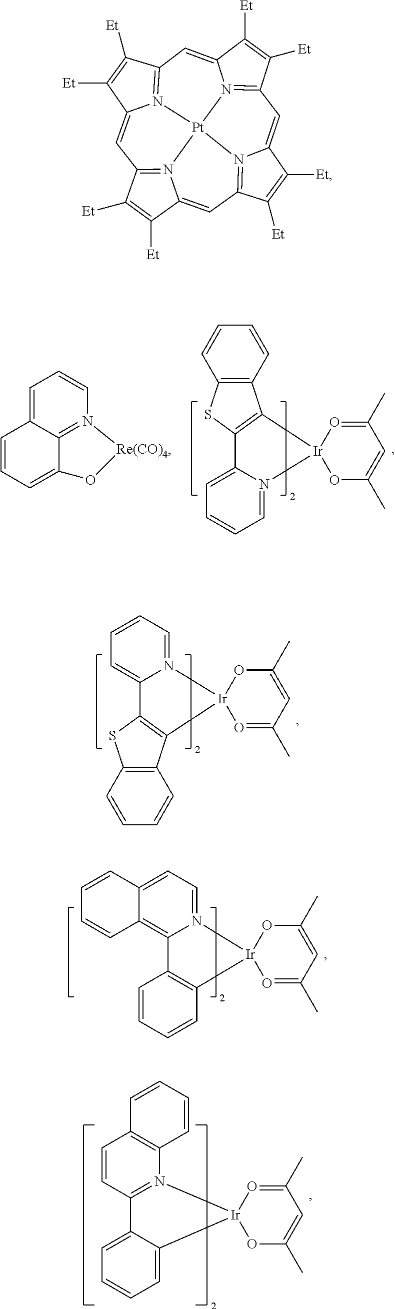

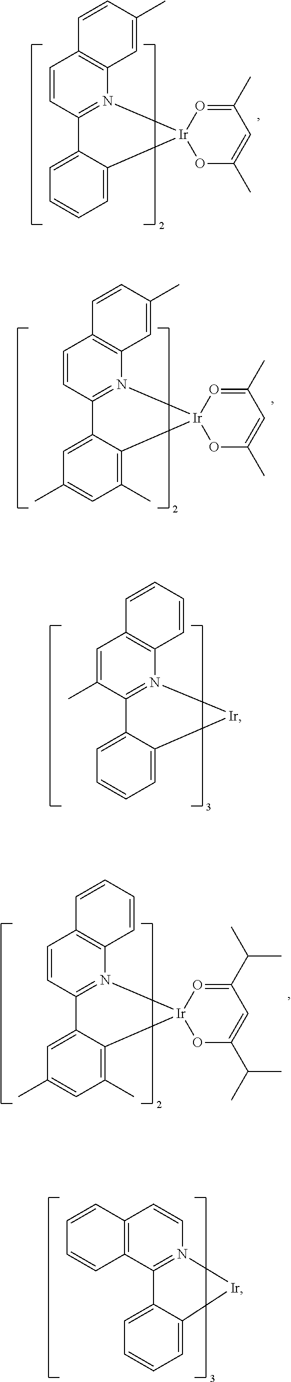

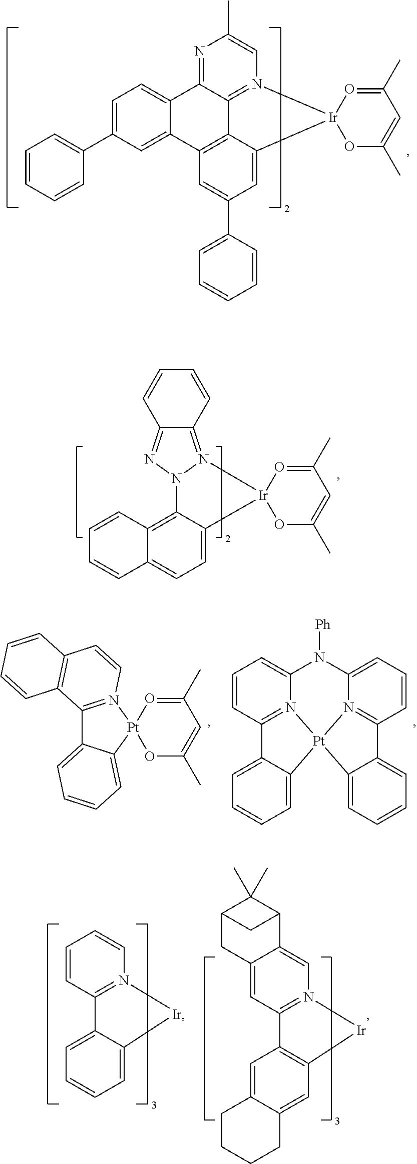

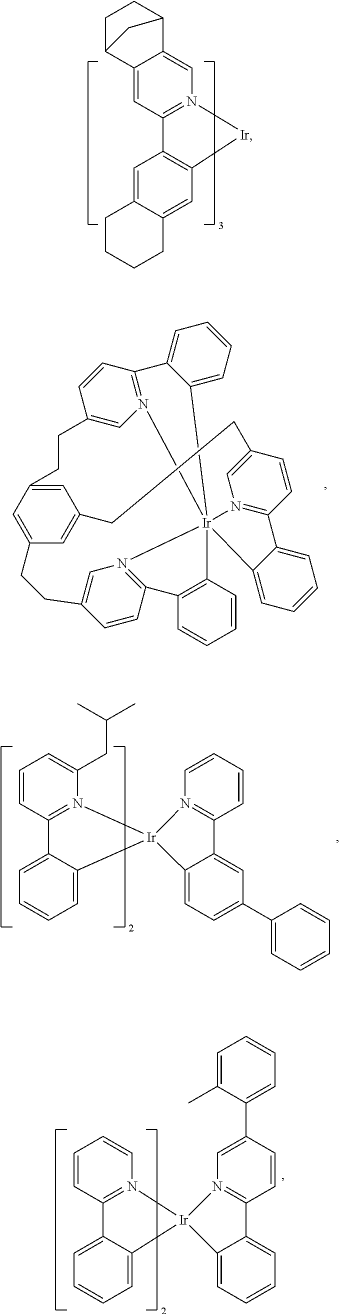

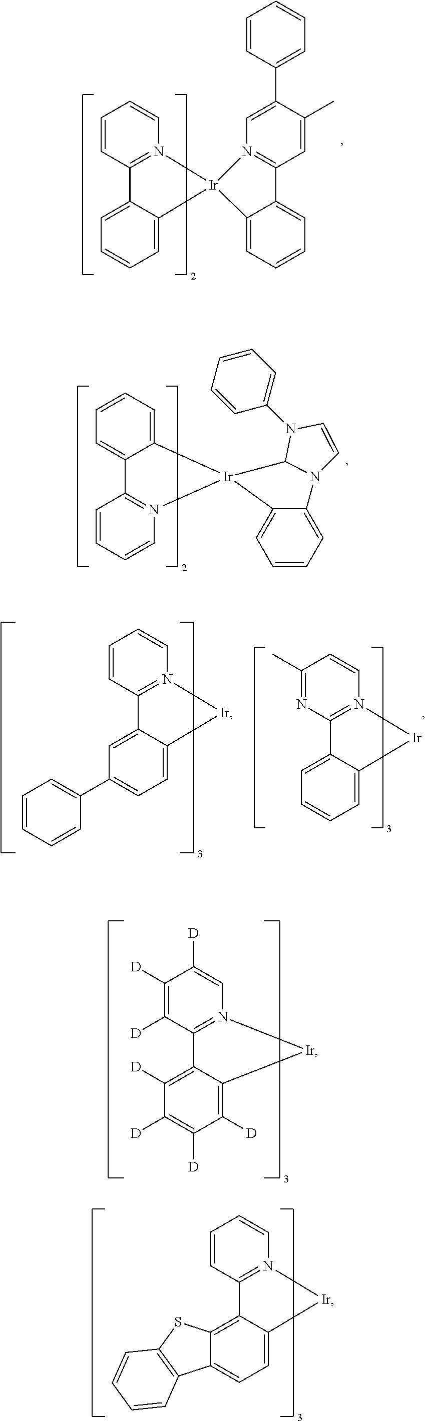

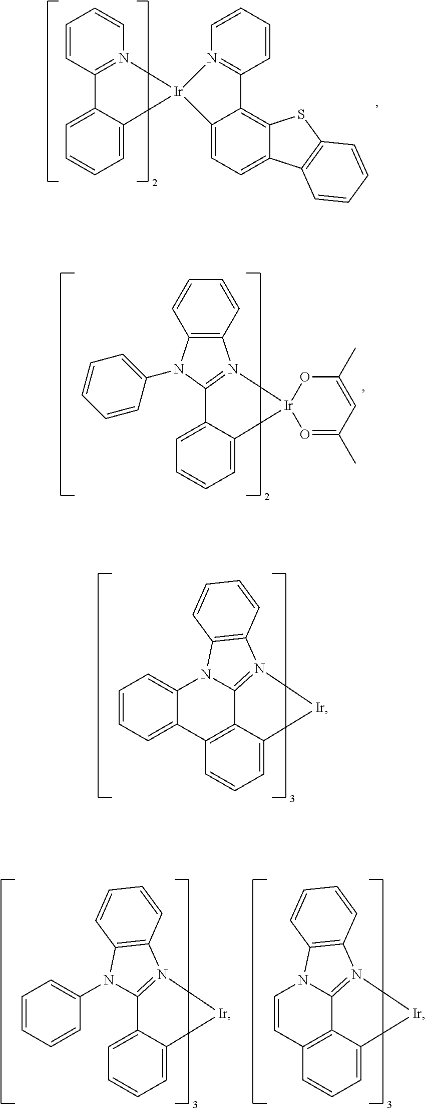

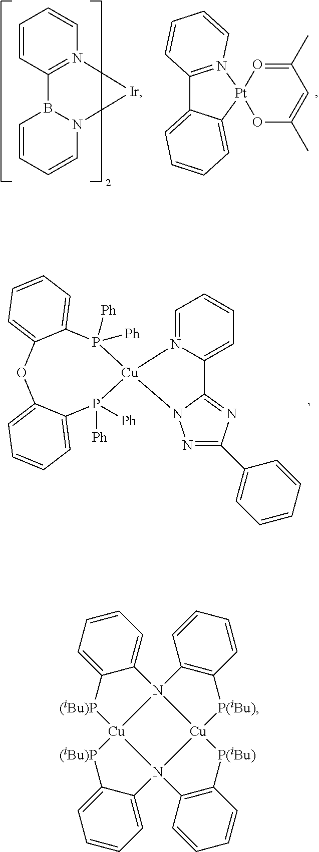

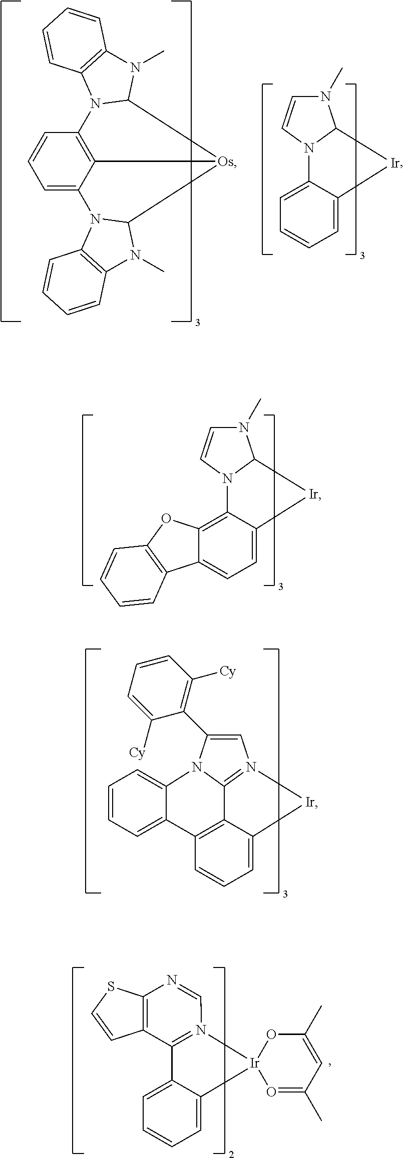

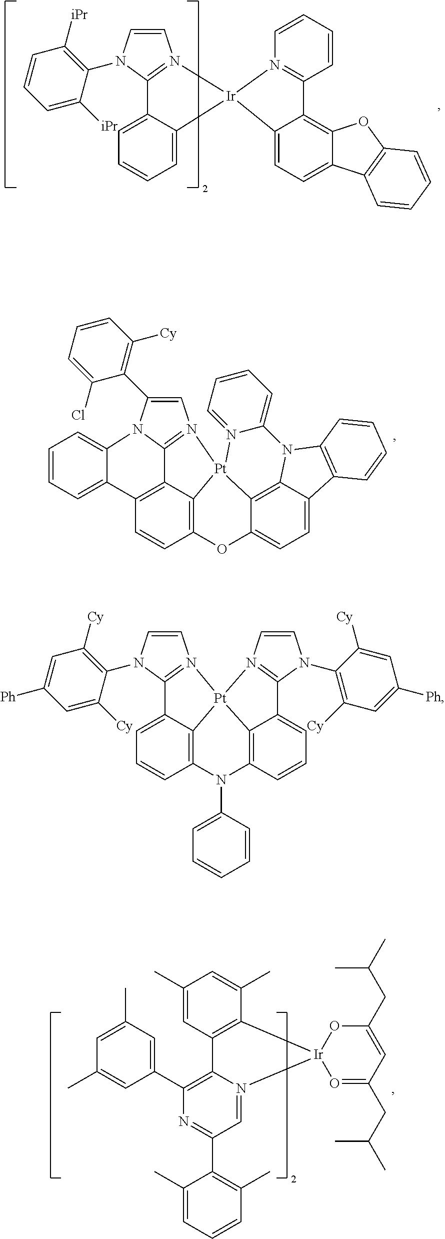

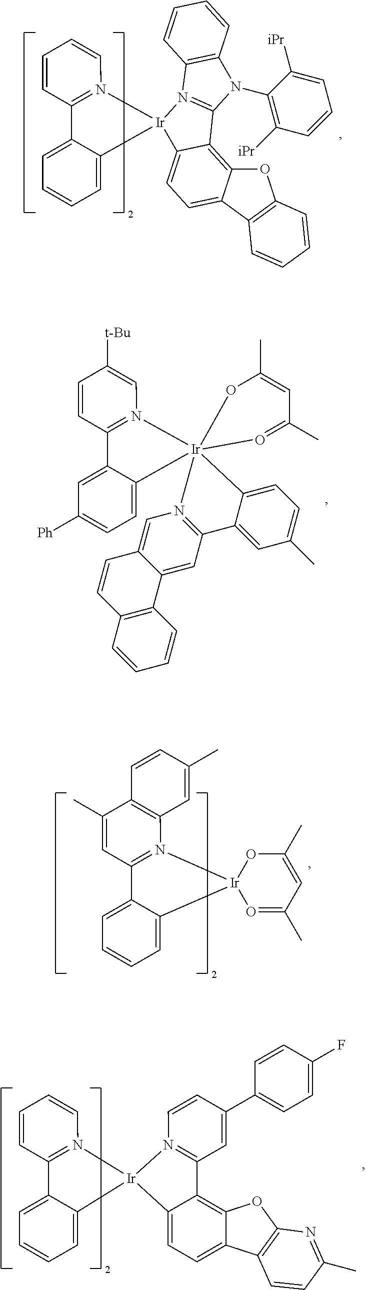

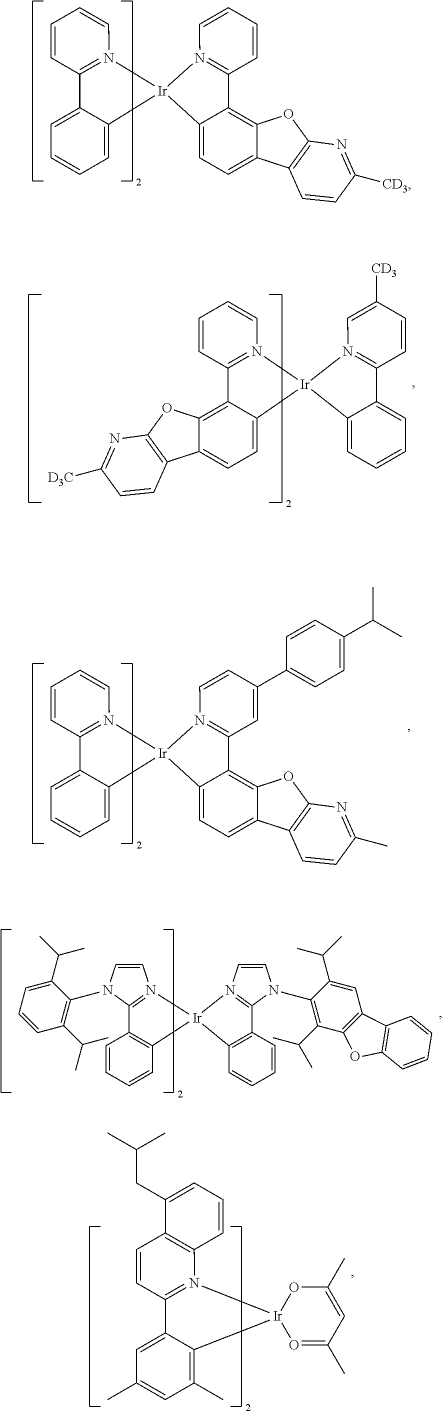

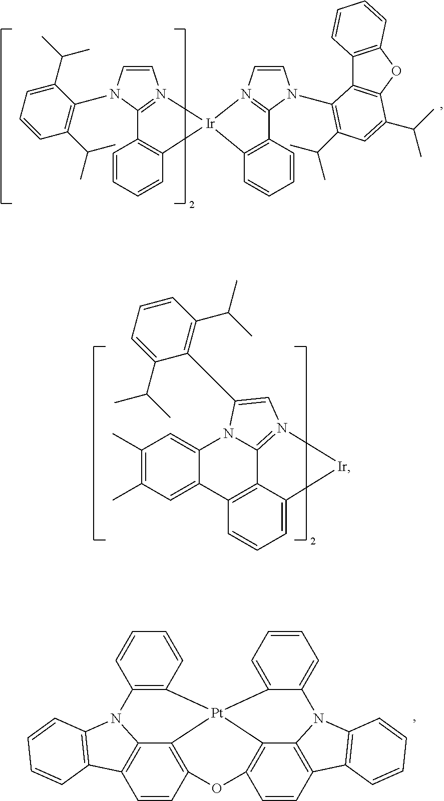

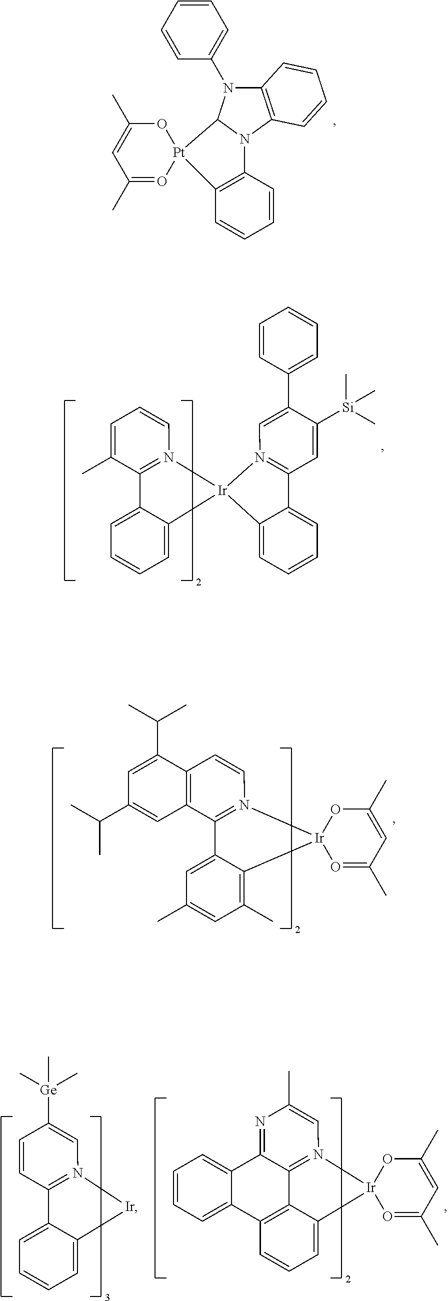

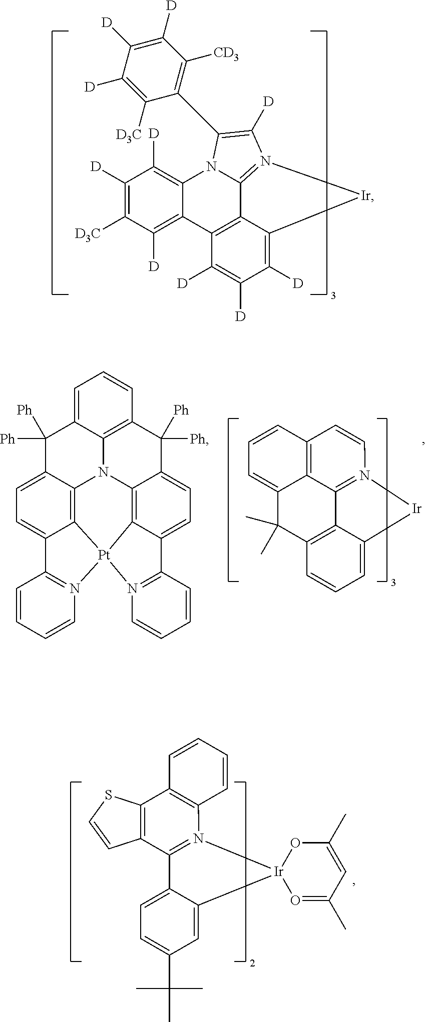

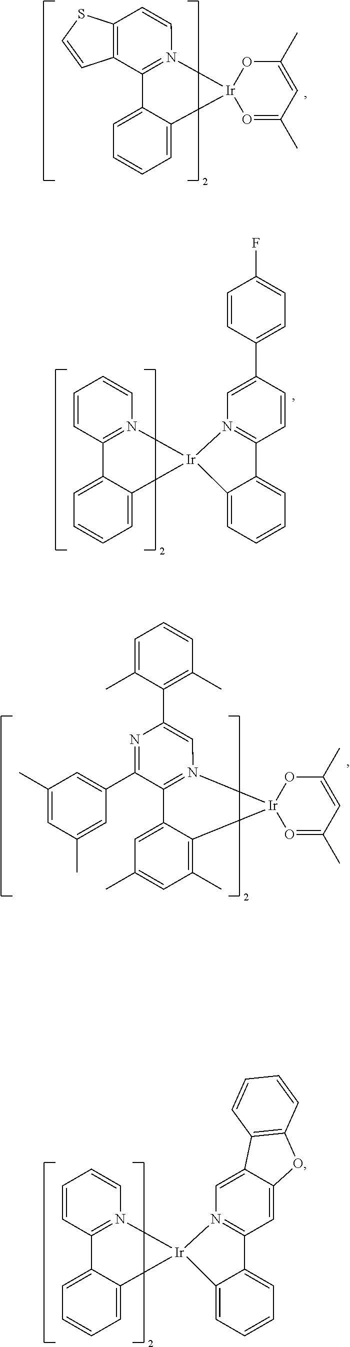

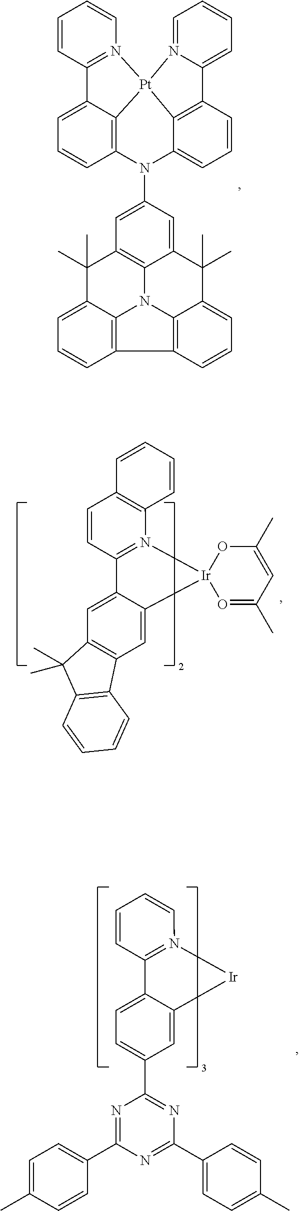

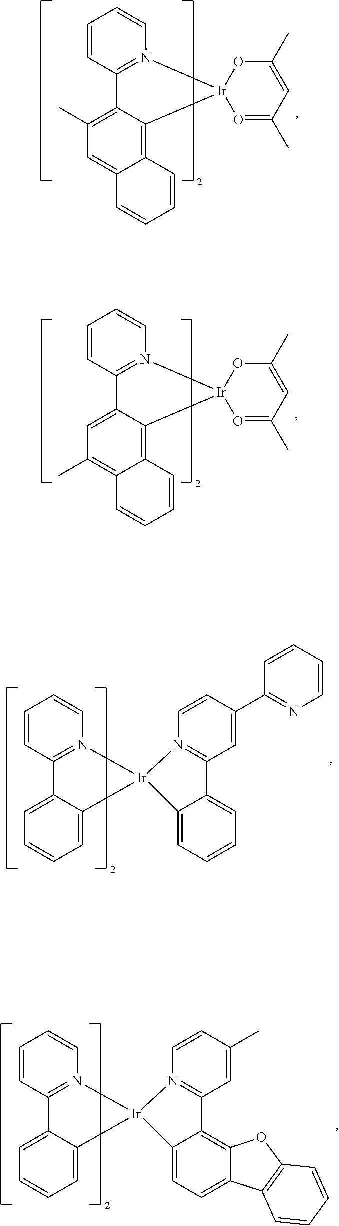

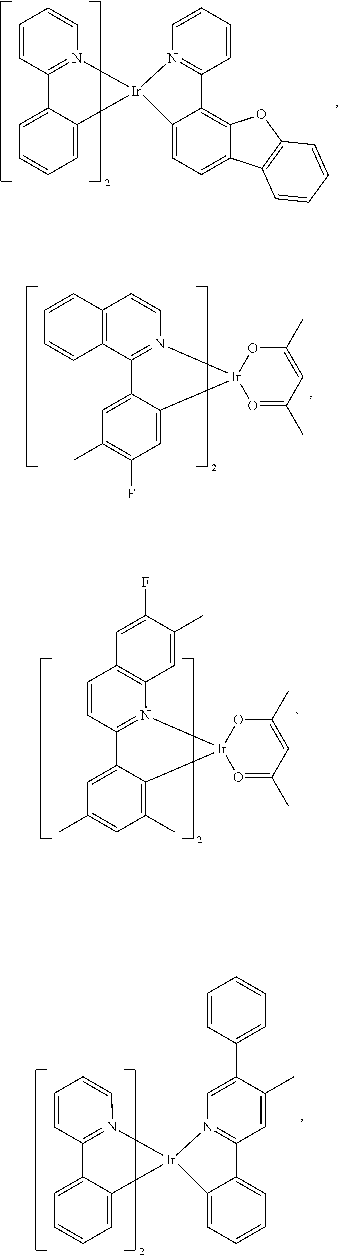

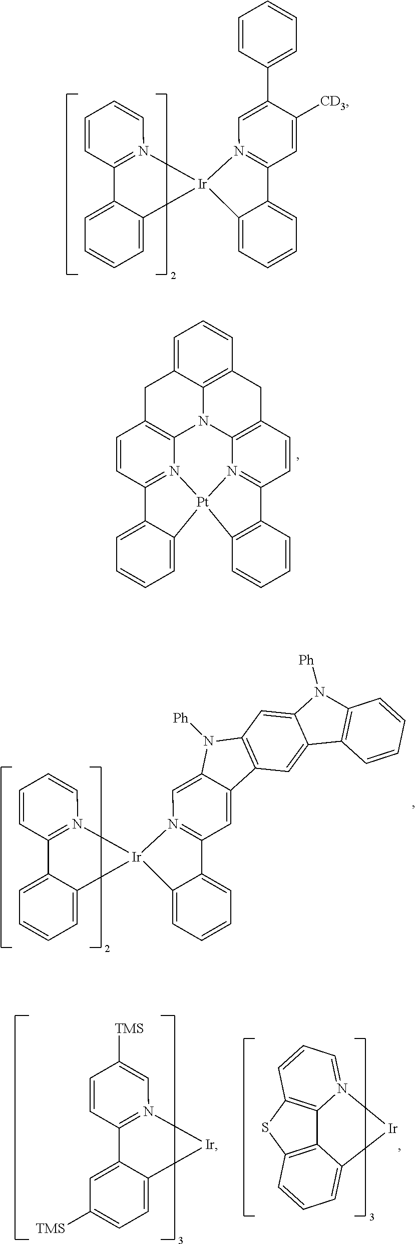

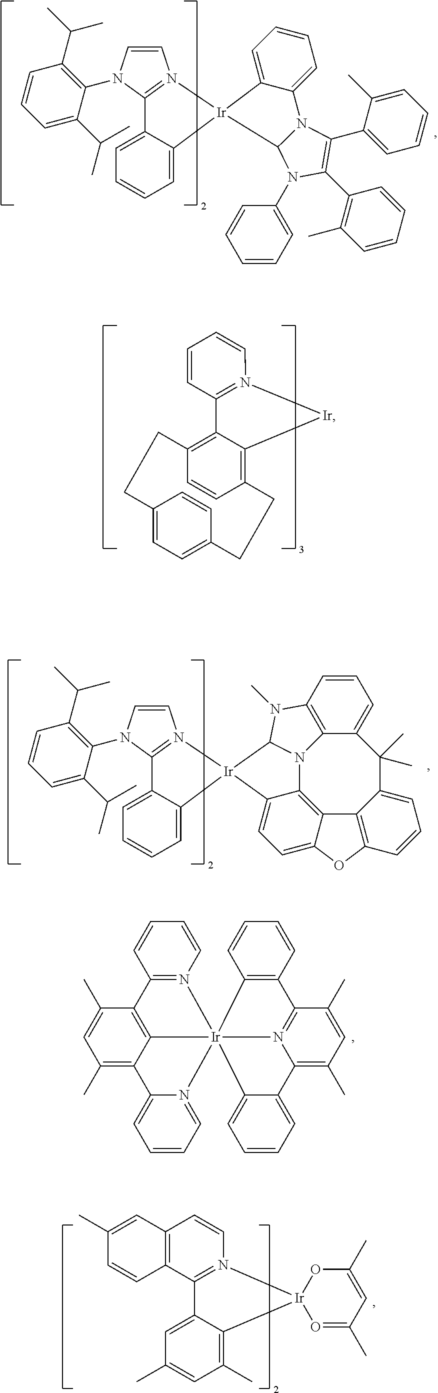

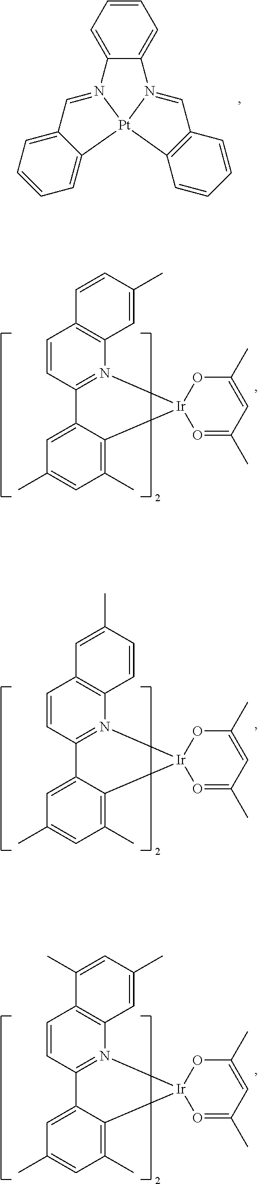

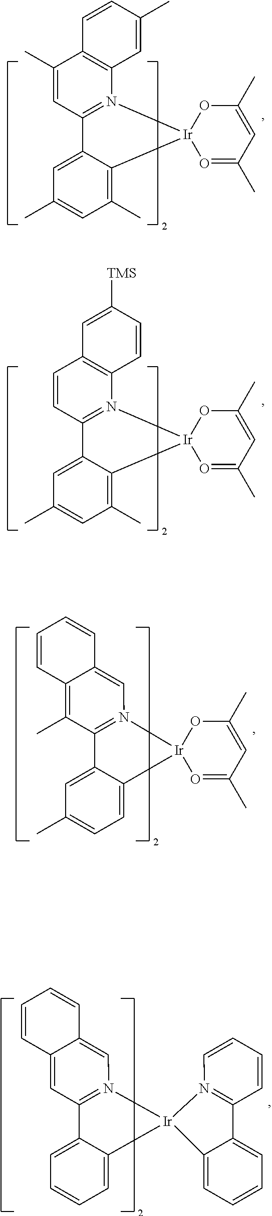

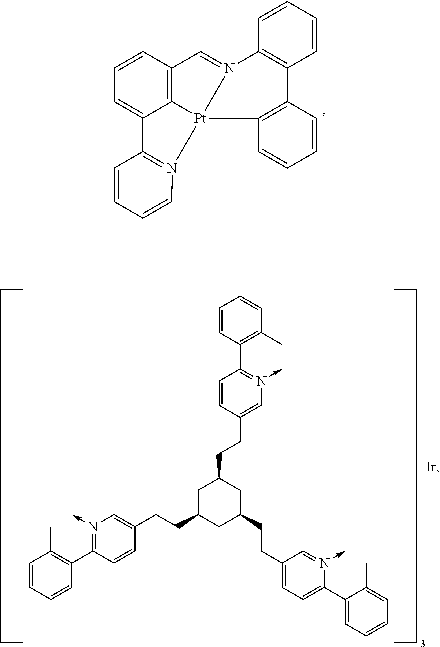

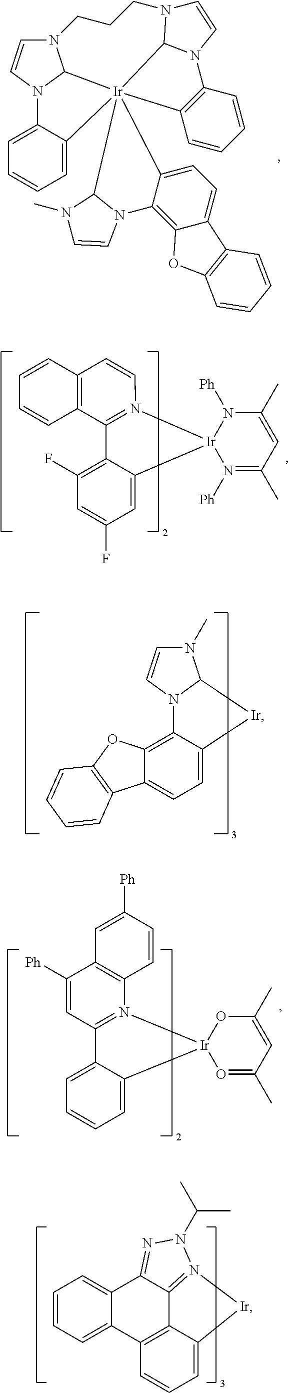

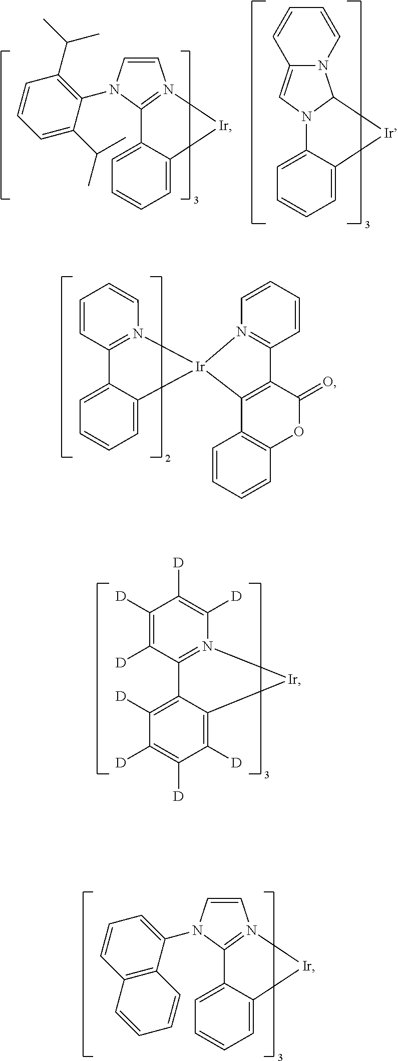

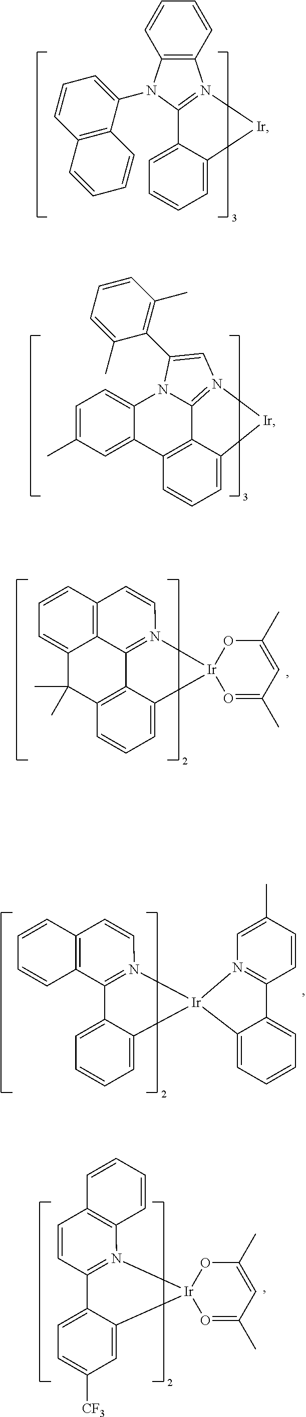

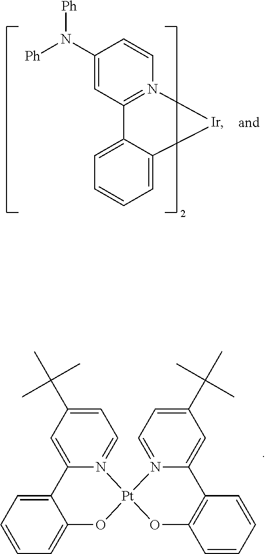

### f) HBL:

A hole blocking layer (HBL) may be used to reduce the number of holes and/or excitons that leave the emissive layer. The presence of such a blocking layer in a device may result in substantially higher efficiencies and/or longer lifetime as compared to a similar device lacking a blocking layer. Also, a blocking layer may be used to confine emission to a desired region of an OLED. In some embodiments, the HBL material has a lower HOMO (further from the vacuum level) and/or higher triplet energy than the emitter closest to the HBL interface. In some embodiments, the HBL material has a lower HOMO (further from the vacuum level) and/or higher triplet energy than one or more of the hosts closest to the HBL interface.

In one aspect, compound used in HBL contains the same molecule or the same functional groups used as host described above.

In another aspect, compound used in HBL contains at least one of the following groups in the molecule:

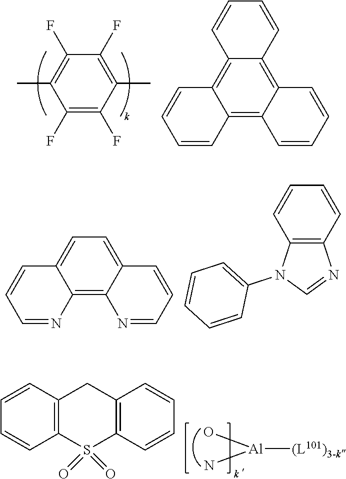

wherein is an integer from 1 to 20; L¹⁰¹ is another ligand, k′ is an integer from 1 to 3.

### g) ETL:

Electron transport layer (ETL) may include a material capable of transporting electrons. Electron transport layer may be intrinsic (undoped), or doped. Doping may be used to enhance conductivity. Examples of the ETL material are not particularly limited, and any metal complexes or organic compounds may be used as long as they are typically used to transport electrons.

In one aspect, compound used in ETL contains at least one of the following groups in the molecule:

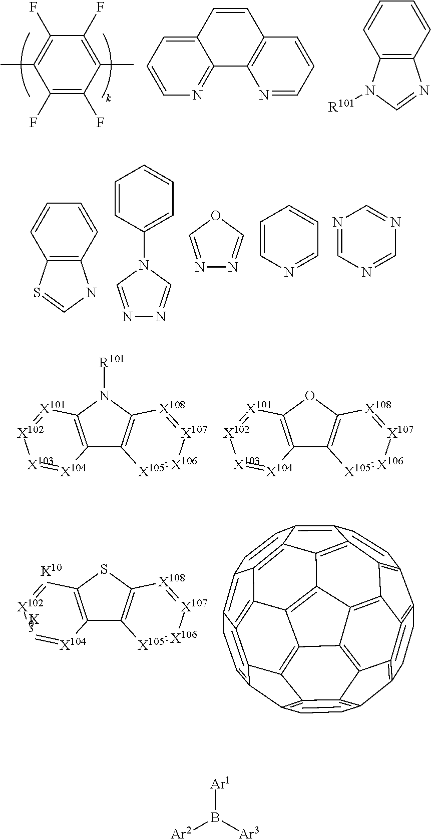

wherein R¹⁰¹ is selected from the group consisting of hydrogen, deuterium, halogen, alkyl, cycloalkyl, heteroalkyl, heterocycloalkyl, arylalkyl, alkoxy, aryloxy, amino, silyl, alkenyl, cycloalkenyl, heteroalkenyl, alkynyl, aryl, heteroaryl, acyl, carboxylic acids, ether, ester, nitrile, isonitrile, sulfanyl, sulfinyl, sulfonyl, phosphino, and combinations thereof, when it is aryl or heteroaryl, it has the similar definition as Ar's mentioned above. Ar¹ to Ar³ has the similar definition as Ar's mentioned above. k is an integer from 1 to 20. X¹⁰¹ to X¹⁰⁸ is selected from C (including CH) or N.

In another aspect, the metal complexes used in ETL contains, but not limit to the following general formula:

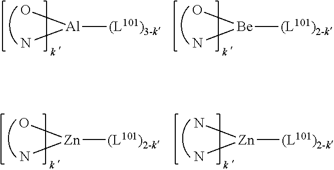

wherein (O—N) or (N—N) is a bidentate ligand, having metal coordinated to atoms O, N or N, N; L¹⁰¹ is another ligand; k′ is an integer value from 1 to the maximum number of ligands that may be attached to the metal.

Non-limiting examples of the ETL materials that may be used in an OLED in combination with materials disclosed herein are exemplified below together with references that disclose those materials: CN103508940, EP01602648, EP01734038, EP01956007, JP2004-022334, JP2005149918, JP2005-268199, KR0117693, KR20130108183, US20040036077, US20070104977, US2007018155, US20090101870, US20090115316, US20090140637, US20090179554, US2009218940, US2010108990, US2011156017, US2011210320, US2012193612, US2012214993, US2014014925, US2014014927, US20140284580, U.S. Pat. Nos. 6,656,612, 8,415,031, WO2003060956, WO2007111263, WO2009148269, WO2010067894, WO2010072300, WO2011074770, WO2011105373, WO2013079217, WO2013145667, WO2013180376, WO2014104499, WO2014104535,

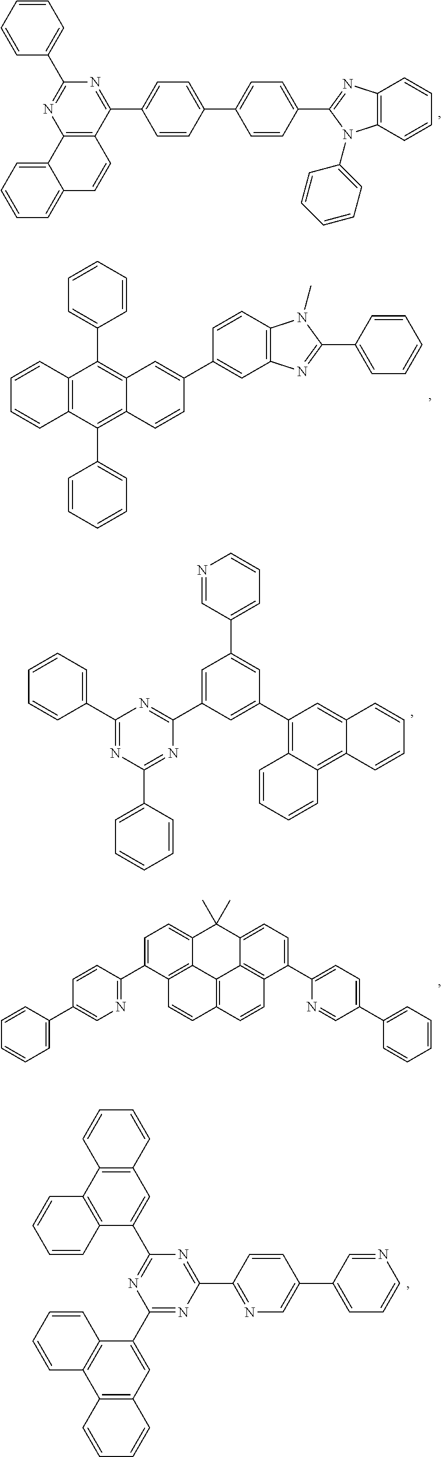 [SMILES: c1ccc(-c2nc(-c3ccc(-c4ccc(-c5nc6ccccc6n5-c5ccccc5)cc4)cc3)c3ccc4ccccc4c3n2)cc1 ; Cn1c(-c2ccccc2)nc2cc(-c3ccc4c(-c5ccccc5)c5ccccc5c(-c5ccccc5)c4c3)ccc21 ; c1ccc(-c2nc(-c3ccccc3)nc(-c3cc(-c4cccnc4)cc(-c4cc5ccccc5c5ccccc45)c3)n2)cc1 ; CC1(C)c2ccc(-c3ccc(-c4ccccc4)cn3)c3ccc4ccc5c(-c6ccc(-c7ccccc7)cn6)ccc1c5c4c23 ; c1cncc(-c2ccc(-c3nc(-c4cc5ccccc5c5ccccc45)nc(-c4cc5ccccc5c5ccccc45)n3)nc2)c1]

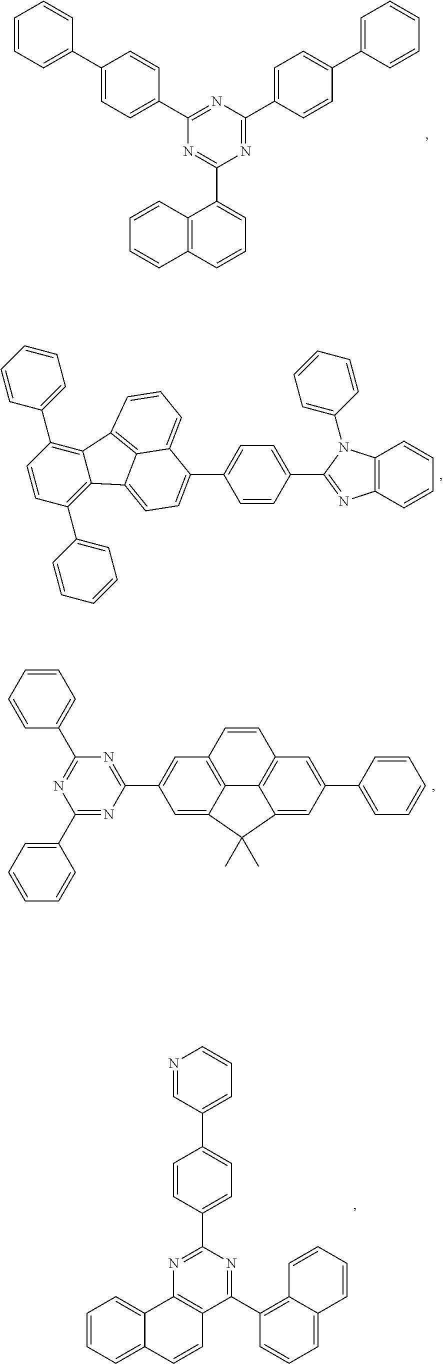 [SMILES: c1ccc(-c2ccc(-c3nc(-c4ccc(-c5ccccc5)cc4)nc(-c4cccc5ccccc45)n3)cc2)cc1 ; c1ccc(-c2ccc(-c3ccccc3)c3c2-c2cccc4c(-c5ccc(-c6nc7ccccc7n6-c6ccccc6)cc5)ccc-3c24)cc1 ; CC1(C)c2cc(-c3ccccc3)cc3ccc4cc(-c5nc(-c6ccccc6)nc(-c6ccccc6)n5)cc1c4c23 ; c1cncc(-c2ccc(-c3nc(-c4cccc5ccccc45)c4ccc5ccccc5c4n3)cc2)c1]

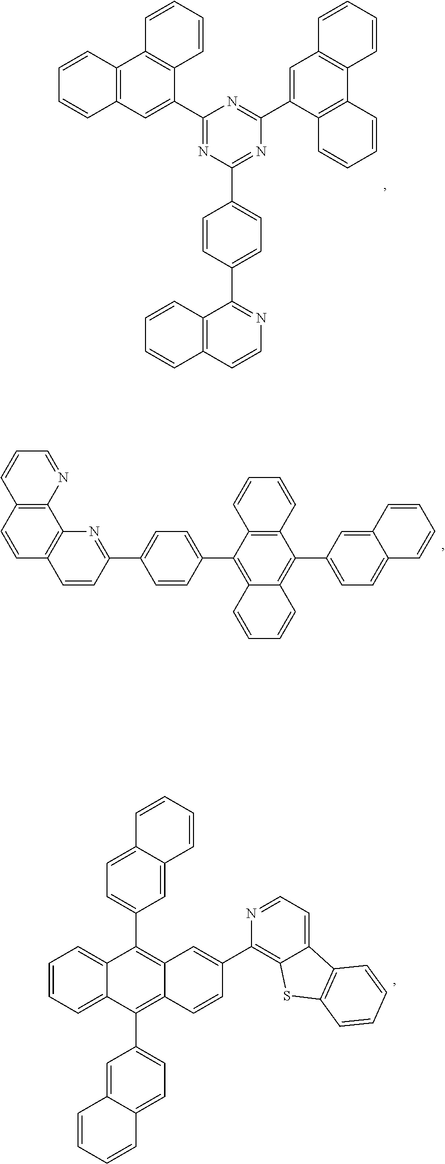 [SMILES: c1ccc2c(-c3ccc(-c4nc(-c5cc6ccccc6c6ccccc56)nc(-c5cc6ccccc6c6ccccc56)n4)cc3)nccc2c1 ; c1ccc2cc(-c3c4ccccc4c(-c4ccc(-c5ccc6ccc7cccnc7c6n5)cc4)c4ccccc34)ccc2c1 ; c1ccc2cc(-c3c4ccccc4c(-c4ccc5ccccc5c4)c4cc(-c5nccc6c5sc5ccccc56)ccc34)ccc2c1]

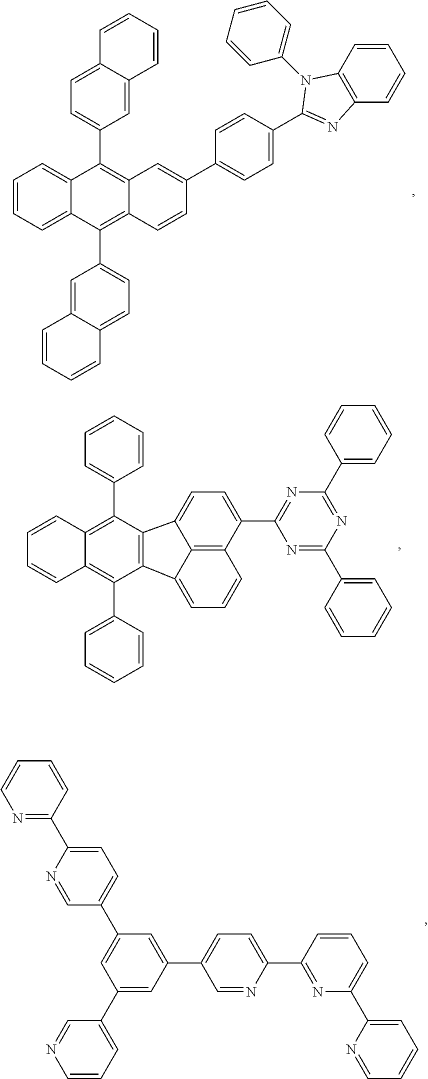 [SMILES: c1ccc(-n2c(-c3ccc(-c4ccc5c(-c6ccc7ccccc7c6)c6ccccc6c(-c6ccc7ccccc7c6)c5c4)cc3)nc3ccccc32)cc1 ; c1ccc(-c2nc(-c3ccccc3)nc(-c3ccc4c5c(cccc35)-c3c-4c(-c4ccccc4)c4ccccc4c3-c3ccccc3)n2)cc1 ; c1ccc(-c2ccc(-c3cc(-c4cccnc4)cc(-c4ccc(-c5cccc(-c6ccccn6)n5)nc4)c3)cn2)nc1]

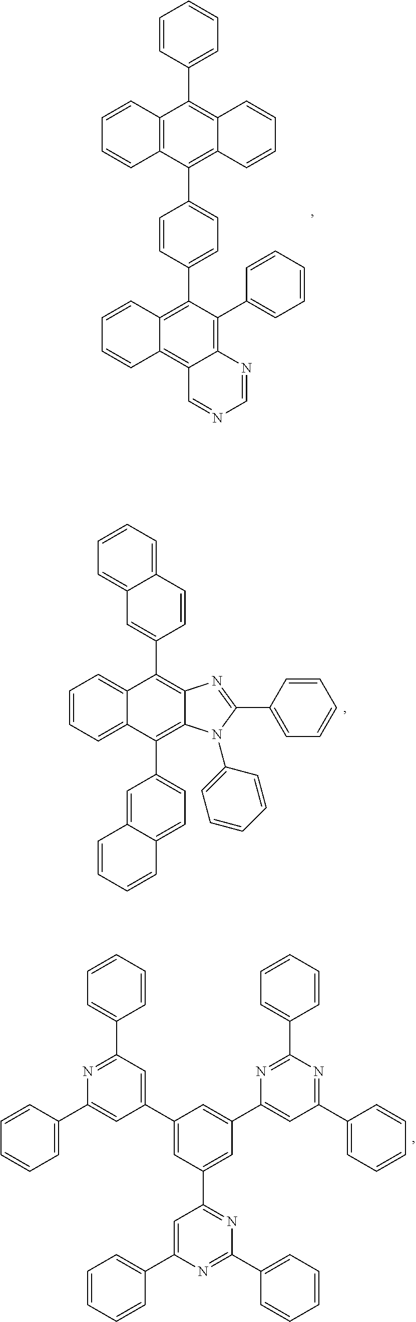 [SMILES: c1ccc(-c2c3ccccc3c(-c3ccc(-c4c(-c5ccccc5)c5ncncc5c5ccccc45)cc3)c3ccccc23)cc1 ; c1ccc(-c2nc3c(-c4ccc5ccccc5c4)c4ccccc4c(-c4ccc5ccccc5c4)c3n2-c2ccccc2)cc1 ; c1ccc(-c2cc(-c3cc(-c4cc(-c5ccccc5)nc(-c5ccccc5)n4)cc(-c4cc(-c5ccccc5)nc(-c5ccccc5)n4)c3)cc(-c3ccccc3)n2)cc1]

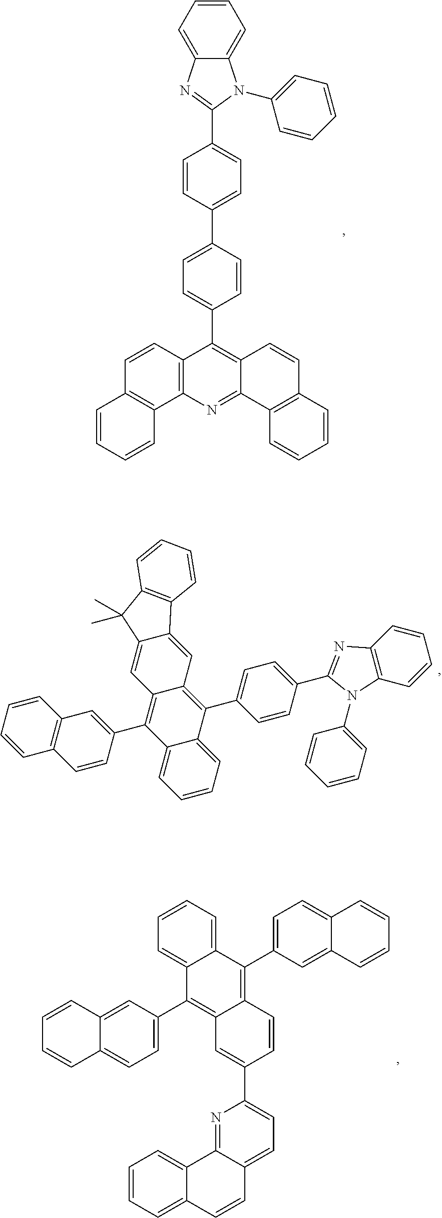 [SMILES: c1ccc(-n2c(-c3ccc(-c4ccc(-c5c6ccc7ccccc7c6nc6c5ccc5ccccc56)cc4)cc3)nc3ccccc32)cc1 ; CC1(C)c2ccccc2-c2cc3c(-c4ccc(-c5nc6ccccc6n5-c5ccccc5)cc4)c4ccccc4c(-c4ccc5ccccc5c4)c3cc21 ; c1ccc2cc(-c3c4ccccc4c(-c4ccc5ccccc5c4)c4cc(-c5ccc6ccc7ccccc7c6n5)ccc34)ccc2c1]

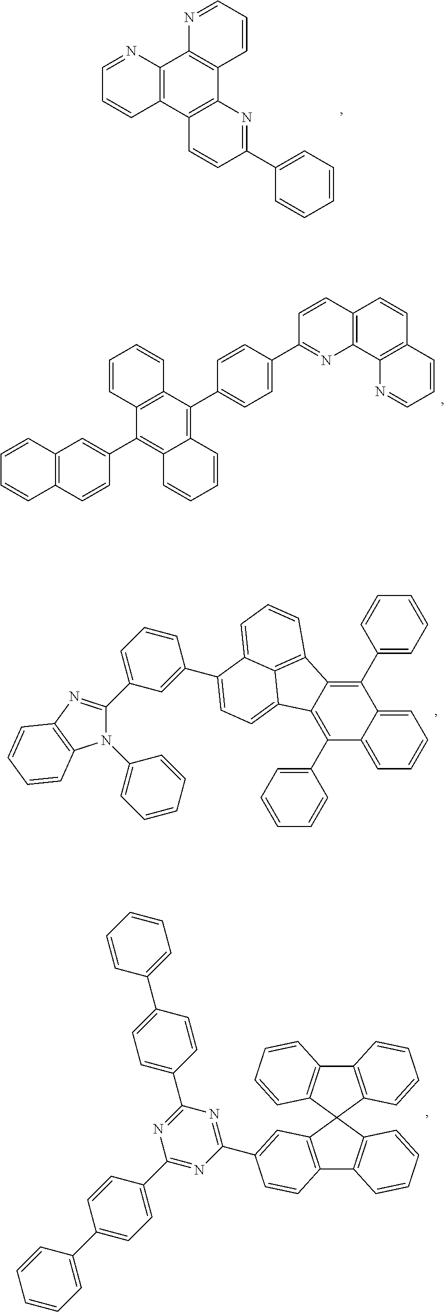 [SMILES: c1ccc(-c2ccc3c4cccnc4c4ncccc4c3n2)cc1 ; c1ccc2cc(-c3c4ccccc4c(-c4ccc(-c5ccc6ccc7cccnc7c6n5)cc4)c4ccccc34)ccc2c1 ; c1ccc(-c2c3c(c(-c4ccccc4)c4ccccc24)-c2ccc(-c4cccc(-c5nc6ccccc6n5-c5ccccc5)c4)c4cccc-3c24)cc1 ; c1ccc(-c2ccc(-c3nc(-c4ccc(-c5ccccc5)cc4)nc(-c4ccc5c(c4)C4(c6ccccc6-c6ccccc64)c4ccccc4-5)n3)cc2)cc1]

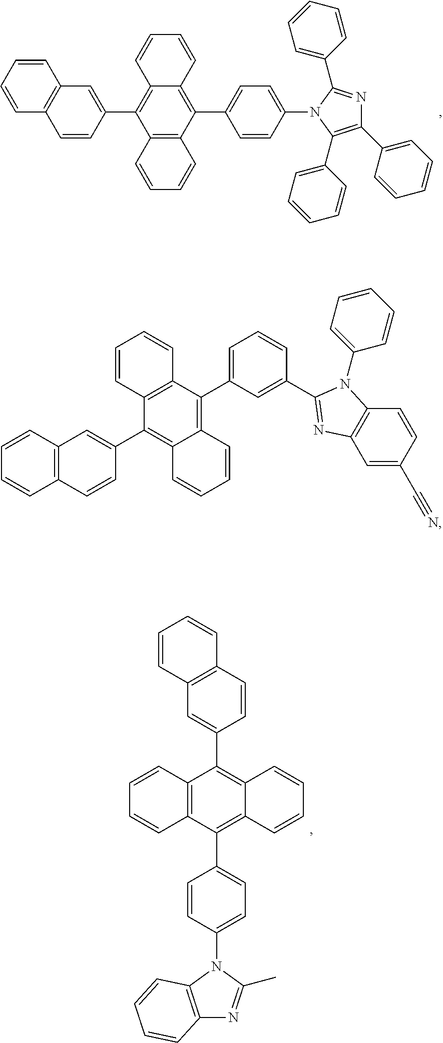 [SMILES: c1ccc(-c2nc(-c3ccccc3)n(-c3ccc(-c4c5ccccc5c(-c5ccc6ccccc6c5)c5ccccc45)cc3)c2-c2ccccc2)cc1 ; N#Cc1ccc2c(c1)nc(-c1cccc(-c3c4ccccc4c(-c4ccc5ccccc5c4)c4ccccc34)c1)n2-c1ccccc1 ; Cc1nc2ccccc2n1-c1ccc(-c2c3ccccc3c(-c3ccc4ccccc4c3)c3ccccc23)cc1]

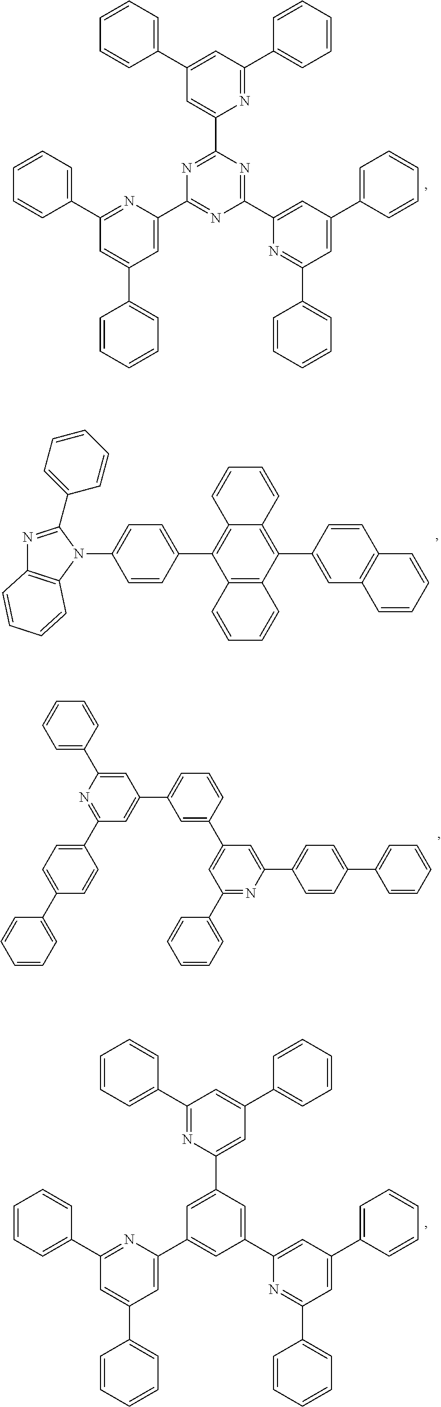 [SMILES: c1ccc(-c2cc(-c3ccccc3)nc(-c3nc(-c4cc(-c5ccccc5)cc(-c5ccccc5)n4)nc(-c4cc(-c5ccccc5)cc(-c5ccccc5)n4)n3)c2)cc1 ; c1ccc(-c2nc3ccccc3n2-c2ccc(-c3c4ccccc4c(-c4ccc5ccccc5c4)c4ccccc34)cc2)cc1 ; c1ccc(-c2ccc(-c3cc(-c4cccc(-c5cc(-c6ccccc6)nc(-c6ccc(-c7ccccc7)cc6)c5)c4)cc(-c4ccccc4)n3)cc2)cc1 ; c1ccc(-c2cc(-c3ccccc3)nc(-c3cc(-c4cc(-c5ccccc5)cc(-c5ccccc5)n4)cc(-c4cc(-c5ccccc5)cc(-c5ccccc5)n4)c3)c2)cc1]

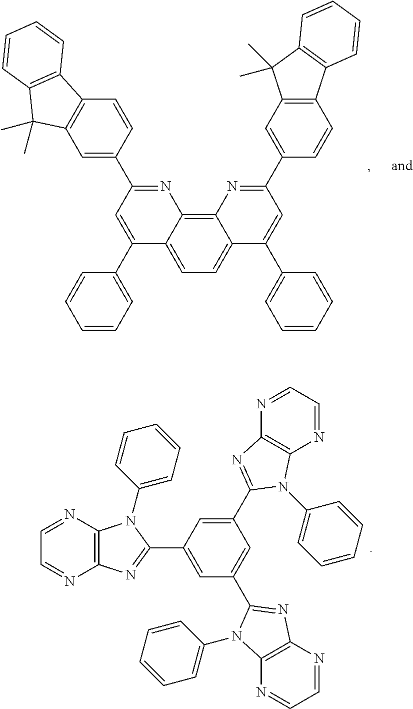 [SMILES: CC1(C)c2ccccc2-c2ccc(-c3cc(-c4ccccc4)c4ccc5c(-c6ccccc6)cc(-c6ccc7c(c6)C(C)(C)c6ccccc6-7)nc5c4n3)cc21 ; c1ccc(-n2c(-c3cc(-c4nc5nccnc5n4-c4ccccc4)cc(-c4nc5nccnc5n4-c4ccccc4)c3)nc3nccnc32)cc1]

### h) Charge Generation Layer (CGL)

In tandem or stacked OLEDs, the CGL plays an essential role in the performance, which is composed of an n-doped layer and a p-doped layer for injection of electrons and holes, respectively. Electrons and holes are supplied from the CGL and electrodes. The consumed electrons and holes in the CGL are refilled by the electrons and holes injected from the cathode and anode, respectively; then, the bipolar currents reach a steady state gradually. Typical CGL materials include n and p conductivity dopants used in the transport layers.

In any above-mentioned compounds used in each layer of the OLED device, the hydrogen atoms can be partially or fully deuterated. The minimum amount of hydrogen of the compound being deuterated is selected from the group consisting of 30%, 40%, 50%, 60%, 70%, 80%, 90%, 95%, 99%, and 100%. Thus, any specifically listed substituent, such as, without limitation, methyl, phenyl, pyridyl, etc. may be undeuterated, partially deuterated, and fully deuterated versions thereof. Similarly, classes of substituents such as, without limitation, alkyl, aryl, cycloalkyl, heteroaryl, etc. also may be undeuterated, partially deuterated, and fully deuterated versions thereof.

It is understood that the various embodiments described herein are by way of example only and are not intended to limit the scope of the invention. For example, many of the materials and structures described herein may be substituted with other materials and structures without deviating from the spirit of the invention. The present invention as claimed may therefore include variations from the particular examples and preferred embodiments described herein, as will be apparent to one of skill in the art. It is understood that various theories as to why the invention works are not intended to be limiting.

### EXPERIMENTAL EXAMPLES

Phosphorescent organic light emitting diodes (PHOLED) have been recognized as an efficient technology to achieve 100% internal efficiency in devices by harvesting both singlet and triplet excitons formed upon charge recombination (Adachi, C., et al., Journal of Applied Physics 2001, 90, 5048-5051; Kawamura, Y., et al., Applied Physics Letters 2005, 86 (7), 071104; Baldo, M. A., et al., Physical Review B 1999, 60, 14 422-14 428). Highly efficient and stable devices have been developed for green and red PHOLEDs. However, the performance of the blue PHOLEDs are still not comparable with its red and green counterparts, especially as the luminance efficiency for these devices degrades over long operational lifespans (Scholz, S., et al., Organic Electronics 2007, 8 (6), 709-717; Scholz, S., et al., Advanced Functional Materials 2008, 18 (17), 2541-2547; Kondakov, D. Y., et al., Journal of Applied Physics 2007, 101 (2), 024512; Lin, W. C., et al., Organic Electronics 2009, 10 (4), 581-586; Sivasubramaniam, V, et al., Journal of Fluorine Chemistry 2009, 130 (7), 640-649). This limitation remains one of the most serious problems that needs to be addressed for widespread adoption of PHOLEDs in commercial applications.

The poor performance of blue PHOLEDs is related to properties of the host materials used in these devices. Compounds which include carbazolyl (Holmes, R. J., et al., Applied Physics Letters 2003, 82 (15), 2422-2424; D'Andrade, B. W. and Forrest, S. R., Journal of Applied Physics 2003, 94 (5), 3101-3109; O'Brien, D. F., et al., Applied Physics Letters 1999, 74 (3), 442-444; Baldo, M. A., et al., Applied Physics Letters 1999, 75 (1), 4-6), phenylsilyl (Ren, X. F., et al., Chemistry of Materials 2004, 16 (23), 4743-4747 Holmes, R. J., et al., Applied Physics Letters 2003, 83 (18), 3818-3820) and fluorenyl (Shih, P. I., et al., Journal of Materials Chemistry 2007, 17 (17), 1692-1698; Wei, W., et al., Chemistry of Materials 2010, 22, 1724) derivatives have been widely used as hosts for PHOLEDs. However, these materials have their several disadvantages in blue PHOLEDs. Carbazolyl hosts such as (4,4′-N,N′-dicarbazole)biphenyl (CBP) and 4,4′,4″-tris(carbazol-9-yl)triphenylamine (TCTA) have been reported to be unstable in blue OLEDs. The C—N bonds between the aryl and carbazolyl groups in these hosts dissociate during device operation and produce charged or radical species. Arylsilyl compounds have been considered as alternative host materials due to their strong Si—C bonds and they have been utilized as large band gap host materials for blue PHOLEDs. However, the arylsilyl derivatives have poor electrical conductivity, and their deep HOMO energies (>7.0 eV) inhibit hole injection from the hole transport layer into the emissive layer of the devices. Fluorenylsilanes, which have both higher HOMO levels (6.6 eV) and charge mobilities, were developed later for use in blue PHOLEDs, but the large barrier for hole injection still leads to a low device efficiency.

Spirobifluorenyl derivatives have also have been used as host materials in PHOLEDs as they are reported to exhibit higher glass transition temperatures compared to the fluorenyl moieties. Spirobifluorenyl species also have much higher hole mobilities than fluorenyl derivatives although the latter have slightly higher electron mobilities. As mentioned previously the deep HOMO energy of the fluorenes (6.2 eV-6.6 eV) could impede hole injection in blue OLEDs. Considering the similar HOMO levels of the spirobifluorenes, the greater hole carrier mobility of this species may improve the charge balance in the OLED devices. Several spirobifluorenyl-based hosts have been reported to achieve good thermal stability and avoid labile heteroatom linkages such as C—S, C—P or C—N by adding aromatic groups such as phenyl, triphenyl, or spirobifluorenyl into the spirobifluorene backbone (Thiery, S., et al., Journal of Materials Chemistry C 2014, 2 (21), 4156-4166; Wong, K.-T., et al., Organic Letters 2005, 7 (23), 5131-5134; Tian, G., et al., New Journal of Chemistry 2016, 40 (11), 9500-9506). However, due to negligible steric hindrance between the moieties, these hosts have lower triplet energies compared to spirobifluorene (E_{T}=2.8 eV) and therefore are poor candidates for confining triplet excitons on blue phosphorescent dopants in PHOLEDs. To address this issue, highly twisted spirobifluorenyl dimers and oligomers with an ortho-ortho linkage between spirobifluorenes moieties were introduced (Jiang, Z., et al., Organic Letters 2009, 11 (12), 2607-2610; Fan, C., et al., Organic Letters 2010, 12 (24), 5648-5651; Sicard, L. J., et al., Angewandte Chemie International Edition 2019, 58 (12), 3848-3853), which inhibited conjugation and retained the high triplet energy of the parent spirofluorene.

Here is describe, a new design strategy to maintain high triplet energy in spirobifluorenyl-based hosts by introducing a tetravalent atom to isolate pendant phenyl rings. Specifically, a non-conjugated carbon core based triphenylmethyl spirobifluorenyl compound, SB—C (Scheme 1), and its triphenylsilyl analog, SB—Si (Scheme 2), were synthesized. Various studies were conducted to compare the properties of these host materials, and their performance was evaluated in blue and green phosphorescent organic light-emitting diodes (PHOLEDs).

### Synthesis

Both of SB—C and SB—Si were designed to maintain high singlet and triplet energies by using the pendant C or Si to isolate the aromatic groups of these two moieties. These two materials were synthesized using different synthetic methodologies starting from a common 2-bromo-9,9′-spirobifluorene (1) precursor. The synthesis of SB—C follows a four-step synthetic route as shown in Scheme 1 (Altobello, S., et al., Chemistry-a European Journal 2008, 14 (4), 1107-1116). A Grignard reagent prepared from 1 was treated with benzophenone to produce the diphenyl-9,9-spirobifluoren-2-yl methanol (2). A Friedel-Crafts reaction between 2 and aniline under a strong acidic condition afforded the p-(diphenyl-9,9-spirobifluoren-2-yl)methyl aniline (3). The amino group of 3 was then removed using tBuONO and H₃PO₂ to give the final product (SB—C). The overall yield of this multi-step synthesis is 33%. SB—Si was synthesized more efficiently as shown in Scheme 2 (You, Y., et al., Journal of Organic Chemistry 2007, 72 (16), 6241-6246; Liao, Y., et al., Chemical Communications 2002, (3), 252-253). Addition of Ph₃SiCl to 2-lithio-9,9′-spirobifluorene gives the SB—Si with a yield of 78% as a pure isolated product.

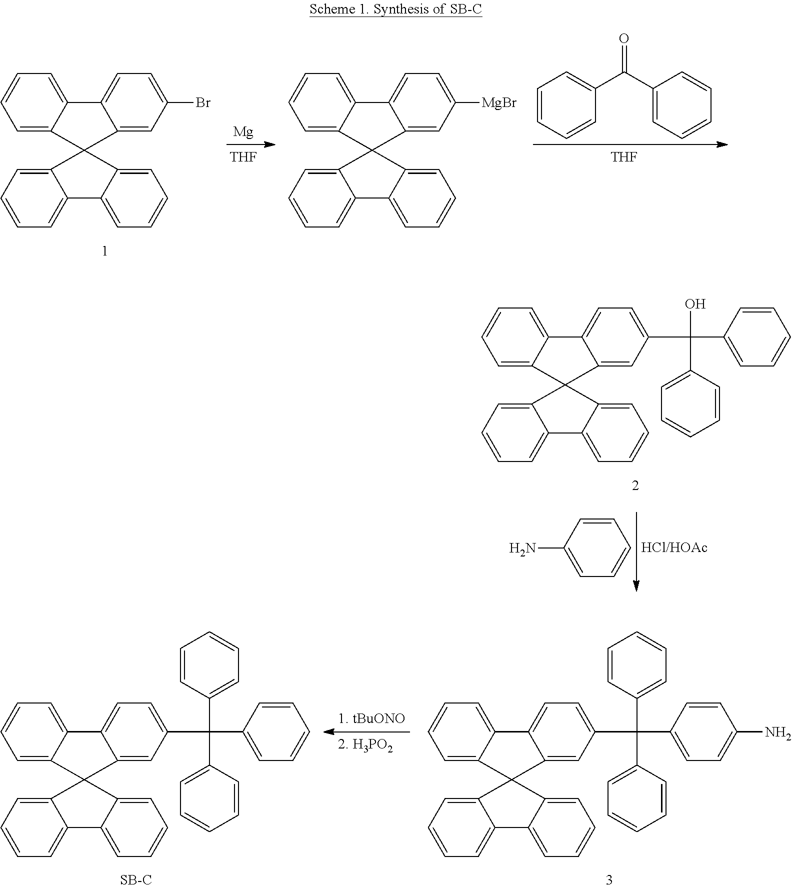

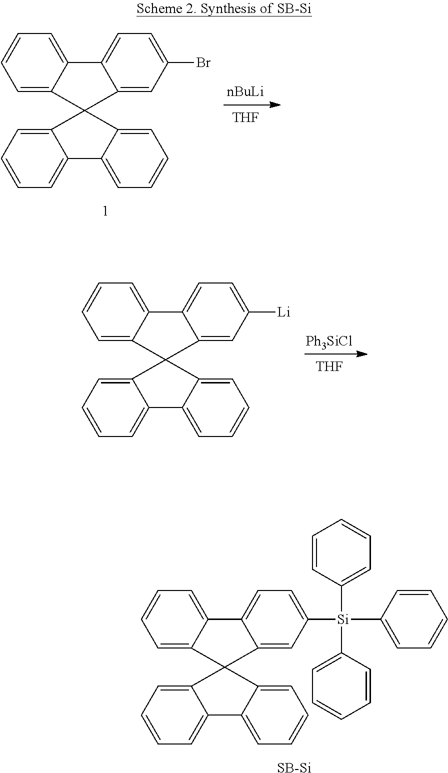

### X-ray Structures

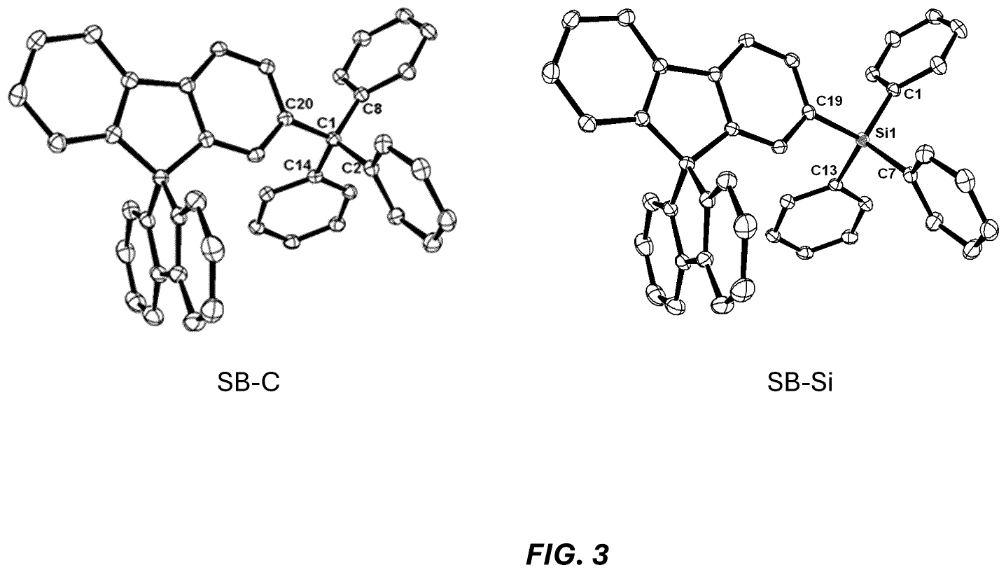

X-ray crystal structures for Sb—C and SB—Si were obtained and are shown in FIG. 3. The bond distance between the spirobifluorenyl carbon and the triphenylmethyl carbon center in SB—C(C1-C20=1.547 Å) is shorter than for the equivalent bond in SB—Si (Sil-C19=1.873 Å), as are the bond distances between the sp³ center to the atoms on the phenyl rings (Cl—C_{Ph}=1.548-1.554 Å for SB—C and Sil-C_{Ph}=1.874-1.880 Å for SB—Si). The packing of the molecules in a unit cell of each of the materials is shown in FIG. 4. No overlap of the aromatic rings is found for SB—C, whereas partial overlap was observed in SB—Si. However, it is worth noting that the shortest full face-to-face distance in SB—Si is approximately 5 Å, which is too long to be effective for π-π stacking interactions.

### Theoretical Calculations

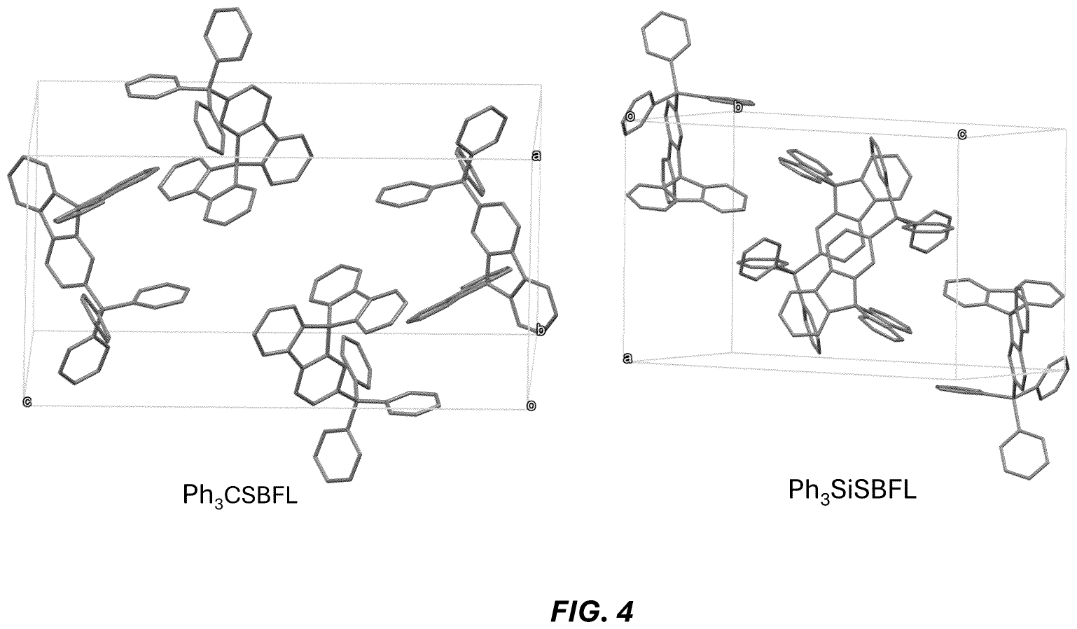

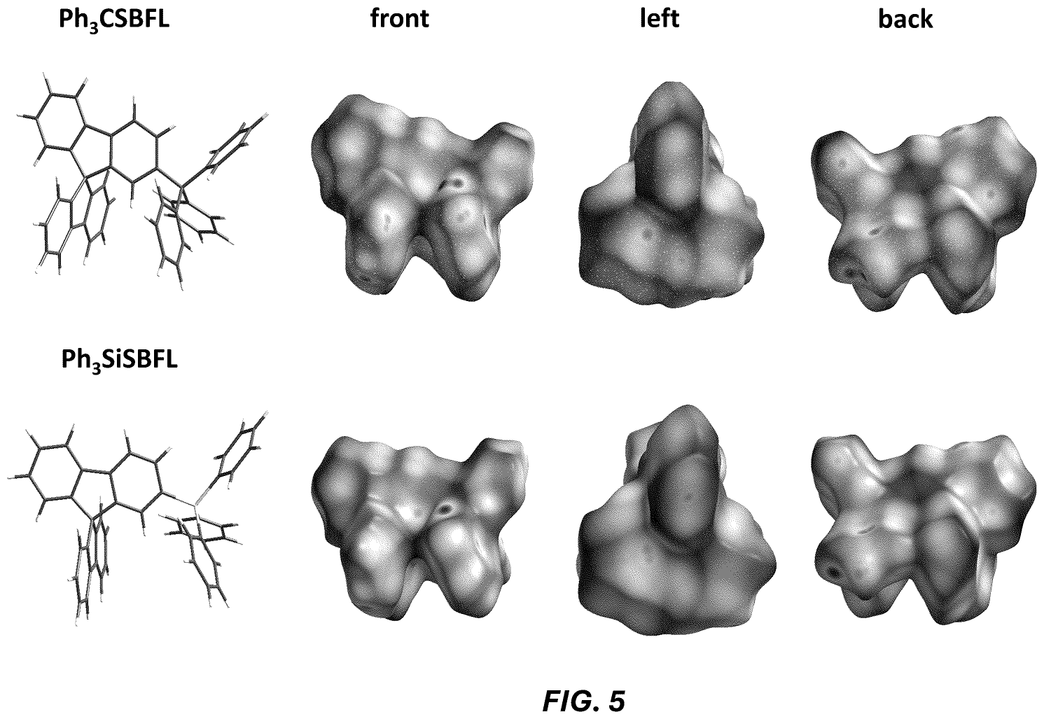

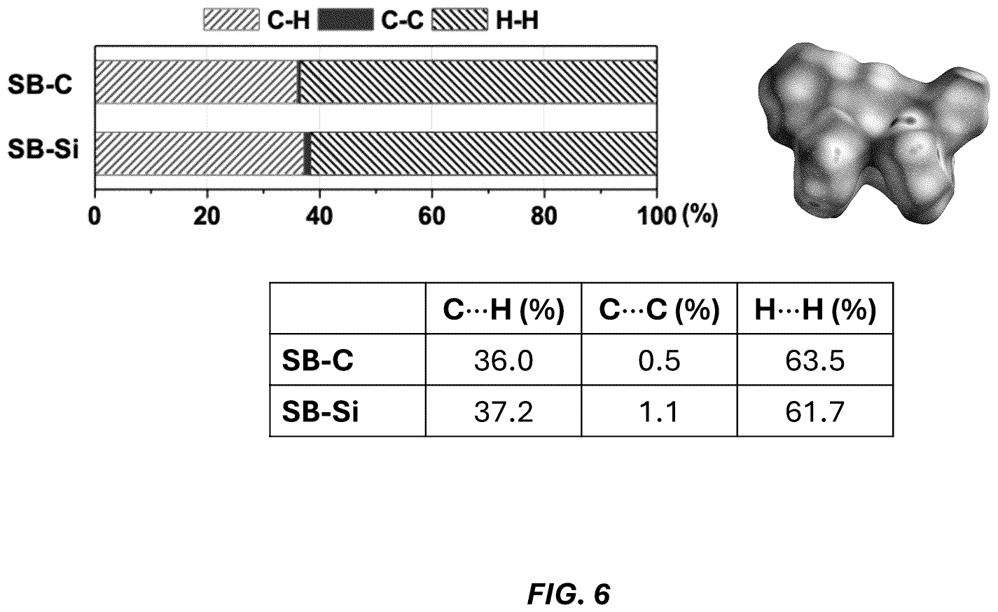

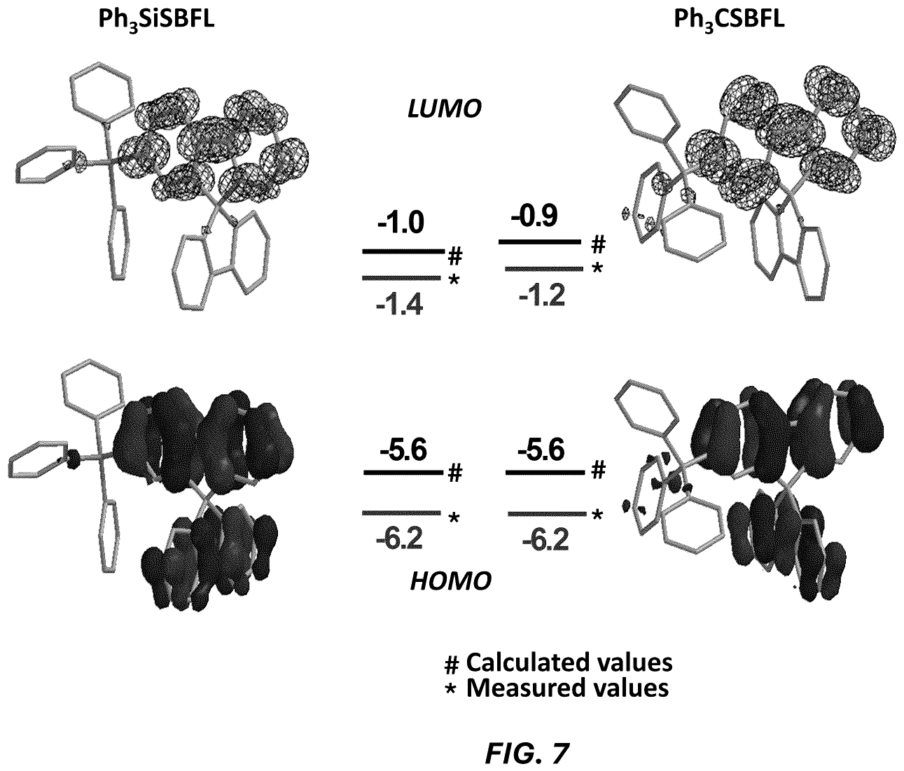

In order to quantitate other intermolecular interactions, Hirshfeld surface calculations were applied in conjugation with the X-ray data to explore the interatomic distances of these two materials (McKinnon, J. J., et al., Chemical communication 2007, (3814)). A Hirshfeld surface identifies regions where the intermolecular interactions of a molecule in the crystal lattice are shorter than a boundary defined by a hypothetical Van der Waals surface calculated for the isolated molecule (Spackman, M. A. and Jayatilaka, D., CrystEngComm 2009, 11 (1), 19-32). Areas of the molecules where the intermolecular interactions are closer can be quantified and compared to other regions where interactions are longer (FIG. 5). The fingerprint generated from the Hirshfeld surface can then provide detailed information regarding the types and percentages of these interactions. Crystalline SB-Si shows higher ratios of both C—C and C—H type interactions between molecules than found in SB—C, which instead has a higher ratio of H—H type intermolecular interactions (FIG. 6). Density functional theory (DFT) calculations also determined the energies for the highest occupied and lowest unoccupied molecular orbitals (HOMO and LUMO) of the two molecules (FIG. 7). These two molecules have similar HOMO and LUMO surfaces. The HOMO is delocalized across the entire spirobifluorenyl moiety whereas the LUMO is localized on the fluorenyl linkage substituted to the Ph₃C— or Ph₃Si— groups. The calculated HOMO and LUMO levels for both molecules are −5.6 eV and −1.0 eV, respectively.

### Electrochemistry

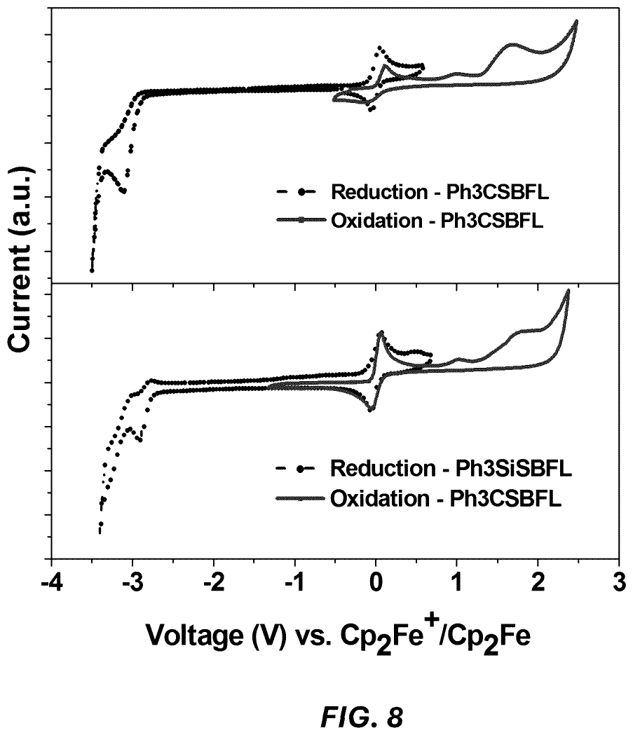

The electrochemical properties of SB—C and SB—Si were examined using cyclic voltammetry (Table 1 and FIG. 8). Both compounds are oxidized irreversibly at 1.1 V (vs. ferrocenium/ferrocene). Similar irreversible oxidation potentials have been reported for the parent spirobifluorene and its non-conjugated derivatives (Rault-Berthelot, J., et al., Synthetic Metals 1998, 97 (3), 211-215; Ye, S. H., et al., Chemistry of Materials 2009, 21 (7), 1333-1342). A second irreversible oxidation wave was also observed at 1.7 V for both SB—C and SB—Si (FIG. 8). These two waves are similar to oxidative processes that are reported to be dependent on the groups attached to the spirobifluorenes. The oxidation wave at 1.1 V was thus assigned to oxidation of the unsubstituted fluorenyl moiety, whereas the second wave is assigned to the fluorenyl moiety bound to the C or Si center. The reduction potentials of the SB—C and the SB—Si are slightly different as a quasi-reversible signal was detected at −3.0 V for the SB—C whereas a reversible reduction wave was found at −2.8 V for the SB—Si (Table 1, FIG. 8). Energy levels for the HOMO and LUMO were estimated from the electrochemical data of these two molecules using the correlations between redox potentials (Sworakowski, J., et al., Organic Electronics 2016, 33, 300-310). The HOMO levels are −6.2 eV for both molecules, whereas the LUMO levels are −1.2 eV for the SB—C and −1.4 eV for the SB—Si. The transport gaps calculated from the difference of the HOMO and LUMO levels are 4.8 eV and 5.0 eV for SB—C and SB—Si respectively. In contrast, the transport gaps reported for related fluorenylsilane hosts are 5.5 eV mainly due to the deep HOMO (6.6 eV) of these molecules, which is 1.3 eV lower than the typical hole transport material N, N′-bis(naphthalene-1-yl)-N,N′-bis(phenyl)-benzidine (NPD). This energy difference leads to a large hole injection barrier from the hole transport layer (HTL) to the emissive layer (EML). Hence, the 0.4 eV higher energy HOMO levels of SB—C and SB—Si could improve the hole injection process into the EML, compared to their fluorenyl counterparts.

TABLE 1
Electrochemical data. Measurements were performed using
0.1M TBAPF₆ electrolyte, and the potentials are listed
relative to a ferrocene internal reference.

| | Eₒₓ^{a} (V) | E_{red}^{b} (V) | HOMO^{c} (eV) | LUMO^{c} (eV) |
|---|---|---|---|---|
| SB-C | 1.1 | −3.0 | −6.06 | −1.29 |
| SB-Si | 1.1 | −2.8 | −6.06 | −1.53 |

^{a}In DMF;
^{b}in acetonitrile;
^{c}calculated using the equations HOMO = −1.15(Eₒₓ) − 4.79; LUMO = −1.18(E_{red}) − 4.83 according to (Sworakowski, J., et al., Organic Electronics 2016, 33, 300-310)

### Thermal Properties

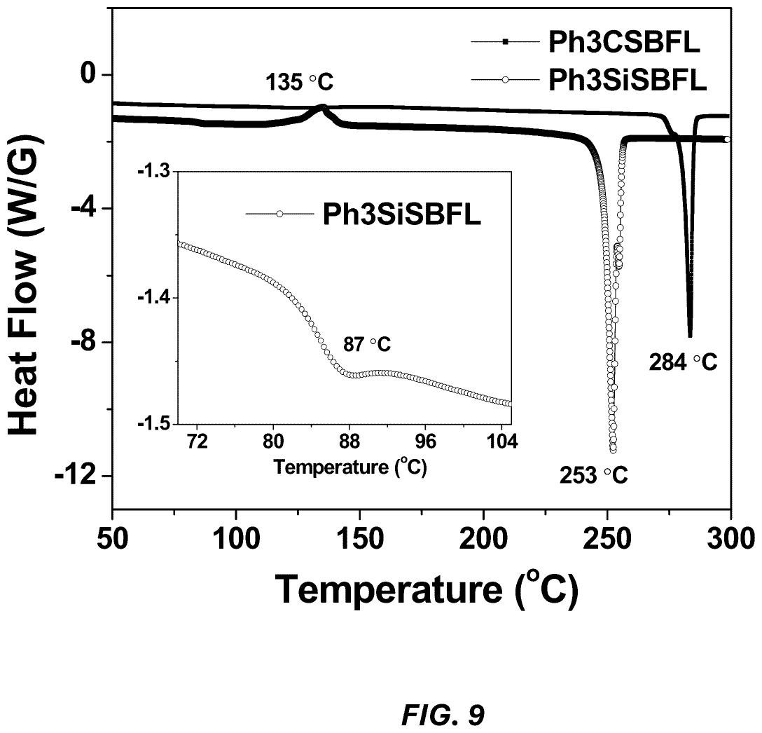

The glass transition temperatures (T_{g}) of the materials are considered to be an important factor for obtaining homogenous thin films in OLED devices (O'Brien, D. F., et al., Advanced Materials 1998, 10 (14), 1108; Koene, B. E., et al., Chemistry of Materials 1998, 10 (8), 2235-2250; Shirota, Y., Journal of Materials Chemistry 2000, 10 (1), 1-25; Shirota, Y., Journal of Materials Chemistry 2005, 15 (1), 75-93). Due to the steric bulk of the spirobifluorenyl substituent, a high glass transition temperature 87° C. was observed for SB—Si (Table 2 and FIG. 9). In contrast, we were not able to detect the glass transition temperature of SB—C. The melting temperature of SB—C(Tₘ=284° C.) is also higher than that of SB—Si (Tₘ=253° C.) (Table 2 and FIG. 9). The sublimation temperatures of these two molecules are not influenced by either the C or the Si center and both compounds can be sublimed at 245° C. in high yield (80-90%) using a gradient vacuum sublimator. This makes these two molecules suitable for OLED device fabrication using vapor deposition methods.

TABLE 2
DSC data

| | Tₘ (° C.) | T_{g} (° C.) | T_{sub} (° C.) |
|---|---|---|---|
| SB-C | 284 | — | 245 |
| SB-Si | 253 | 87 | 245 |

### Photophysics

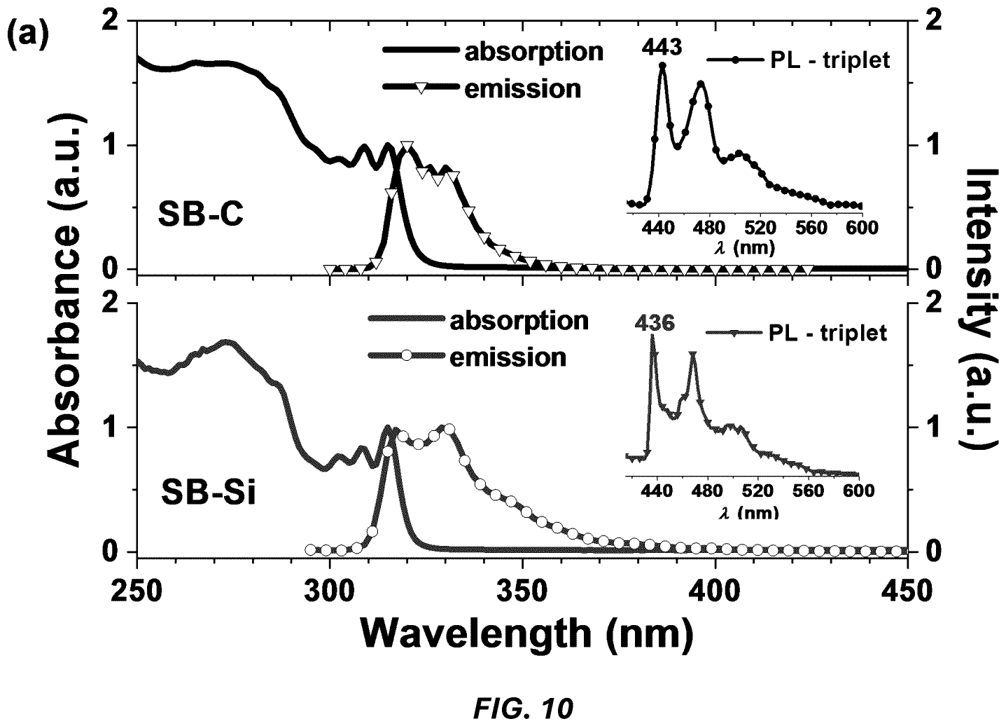

The UV-visible absorption and photoluminescence (PL) spectra of SB—C and SB—Si in 2-methyltetrahydrofuran (2-MeTHF) solutions are shown in FIG. 3a. Absorption bands appearing between 290 nm to 320 nm are attributed to p-p transitions on the spirobifluorene (Weisburger, J. H., et al., Journal of the American Chemical Society 1950, 72, 4253-4255). The lowest energy transitions of both molecules are at 315 nm (Table 3). The optical gaps determined from the long wavelength edge of the absorption spectra are near identical for the SB—C (λ=317 nm, 3.9 eV) and the SB—Si (λ=316 nm, 3.9 eV). These optical gaps are ˜1 eV smaller than the transport gaps determined from their respective redox potentials. Singlet emission typical for the fluorenyl moiety were observed from SB—C(λₘₐx=320 nm) and SB—Si (λₘₐₓ=318 nm) (Table 3 and FIG. 10). The phosphorescence spectra of SB—C(λₘₐₓ=443 nm) and SB—Si (λₘₐ=438 nm) were observed at low temperature (77 K gated), Table 3 and FIG. 10 (inset). The triplet energies for both molecules (E_{T}=2.80 eV) are only slightly lower compared to the parent fluorenylsilanes (λₘₐₓ=435 nm, E_{T}=2.85 eV).

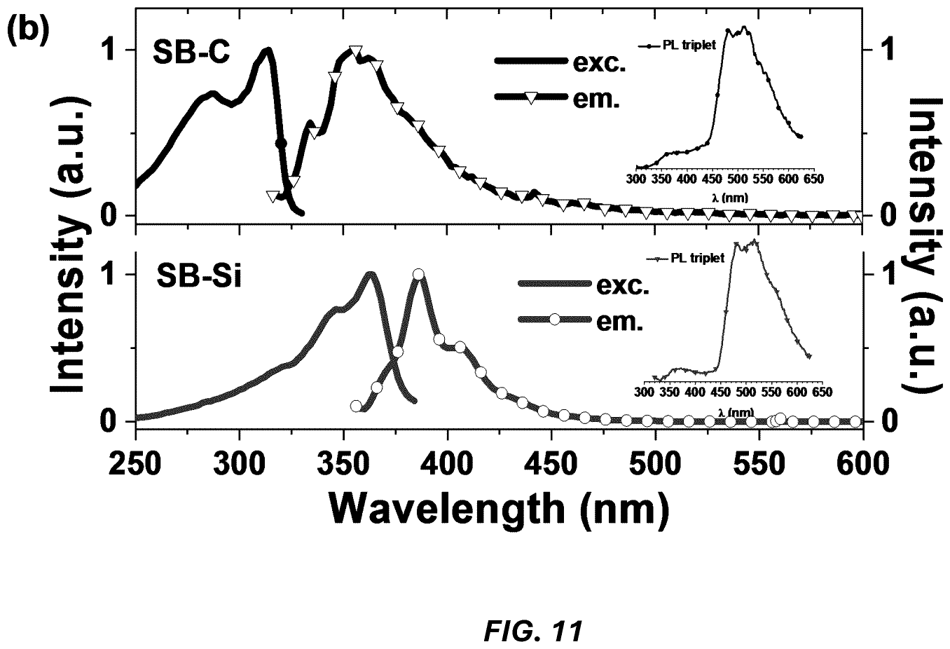

The excitation and emission spectra of crystals of SB—C and SB—Si were also measured so a direct correlation with their molecular arrangements in their solid-state could be made using the X-ray and photophysical data (FIG. 11). The excitation spectrum of SB—C crystals shows a maximum peak at 314 nm, which is 3 nm blue shifted from its solution absorption. A 36 nm red shift was also observed for the emission spectrum of crystalline SB-C from its spectrum in solution. In contrast, the excitation spectrum of SB—Si crystals shows a strong red shift (47 nm) from to its solution absorption, giving a maximum excitation at 362 nm (Table 3, FIG. 11). Associated with the red shift of the excitation, the emission of this compound is also red shifted for 59 nm from its emission in solution. The red shifted emission spectra of SB—C and SB—Si come from the intermolecular interactions between molecules in the crystals. The large red shifts of both excitation and emission spectra of SB—Si suggest that a greater number of close intermolecular interactions are present in the crystals than in SB—C. The Hirshfeld surface calculation discussed in the previous section also provides evidence of stronger intermolecular, C—C type interactions are present in the SB—Si crystals. However, similar phosphorescence spectra for SB—C and SB—Si (λₘₐₓ=450 nm) were observed at 77K for both compounds (Table 3, FIG. 11 inset).

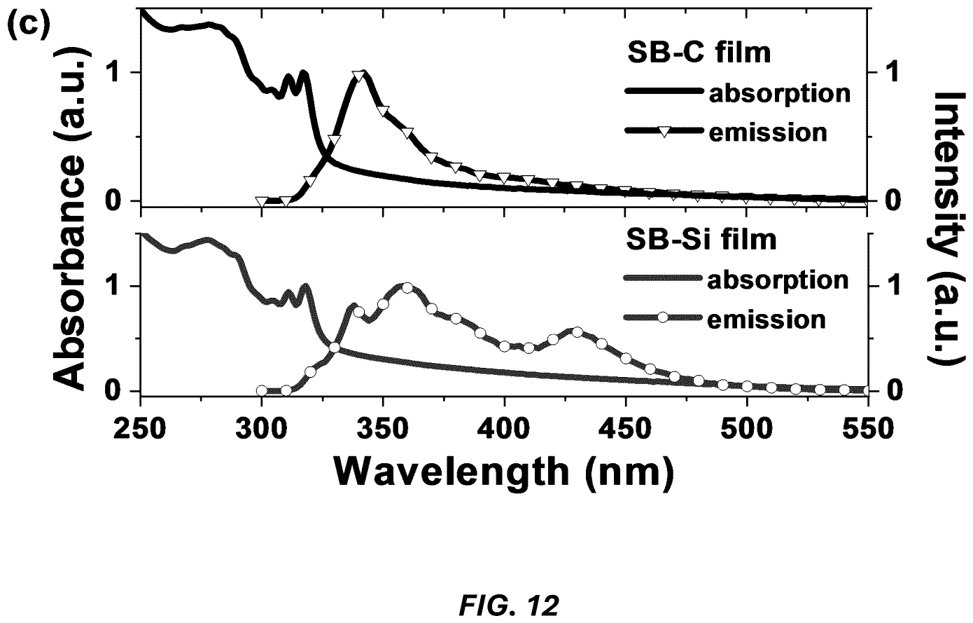

It is particularly important to investigate the photophysics of SB—C and SB—Si in amorphous thin films, since these two materials were designed for thin film semiconductor devices. Therefore, absorption and emission spectra of vacuum deposited thin film were measured and are shown in FIG. 12. The lowest energy absorption transitions appear at 318 nm for both materials and are close to values measured in dilute solution. The gradually sloping absorption band after 330 nm is due to light scattering. Even though films of these two compounds have similar absorption spectra, their emission spectra are quite different. Emission from the SB—C film peaks at 342 nm, whereas two different red shifted bands in SB—Si peak at 360 nm and 430 nm. The bands between 330 and 400 nm are assigned to be singlet emission from the molecules that are red shifted in the solid state. The red shift could be due to weak interactions between molecules in the films, considering that there are no interactions between individual molecules in a dilute solution. The emission band at 430 nm in SB—Si is similar to emission observed from solid films of dimethylfluorenyl silanes and has been assigned to fluorescence from more strongly aggregated molecules which act as luminescent trap states.

TABLE 3
Summary of photophysical data

| | λ_{Abs}^{a} | λ_{PL}^{a} | λ_{PL, 77K}^{a} | λ_{Abs, crystal}^{b} | λ_{PL, crystal}^{b} | λ_{PL, 7K crystal}^{b} | λ_{Abs, film}^{c} | λ_{PL, film}^{c} |
|---|---|---|---|---|---|---|---|---|
| | (nm) | (nm) | (nm) | (nm) | (nm) | (nm) | (nm) | (nm) |
| SB—C | 315 | 320, 443 | 443 | 317 | 342 | 480 | 314 | 356 |
| SB—Si | 315 | 318, 438 | 438 | 318 | 360, 428 | 480 | 362 | 386 |

^{a}In 2-MeTHF;
^{b}sublimed crystals;
^{c}amorphous thin film (40 nm)

### OLED Studies

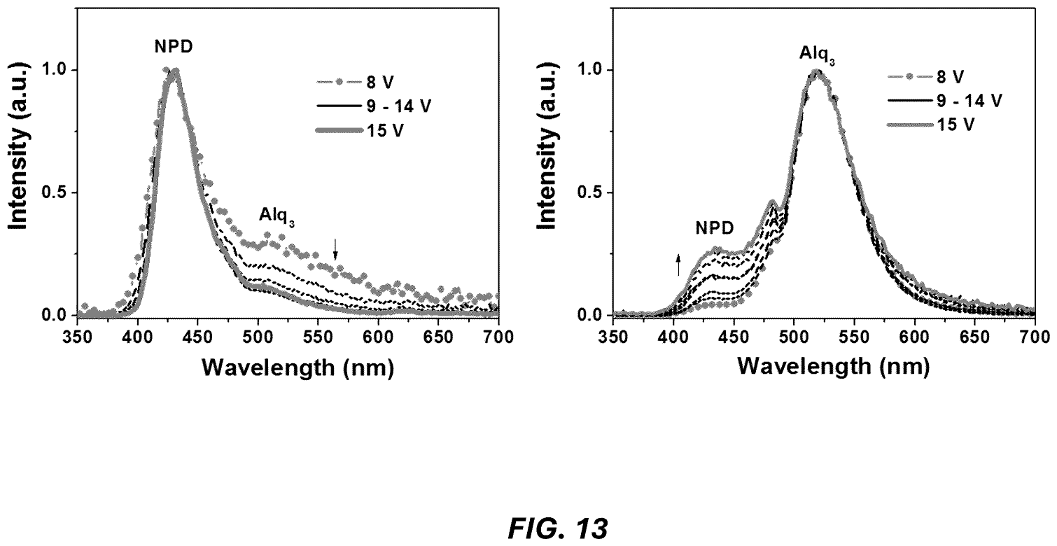

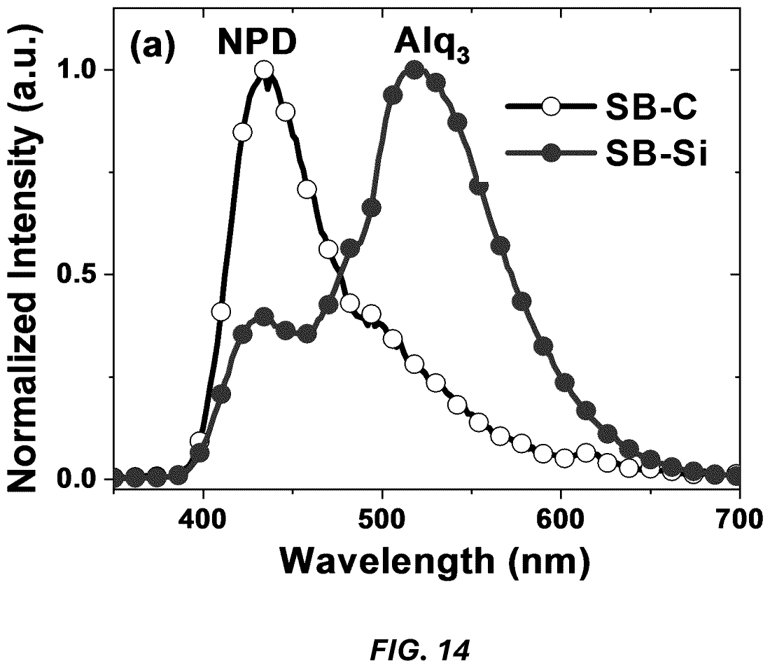

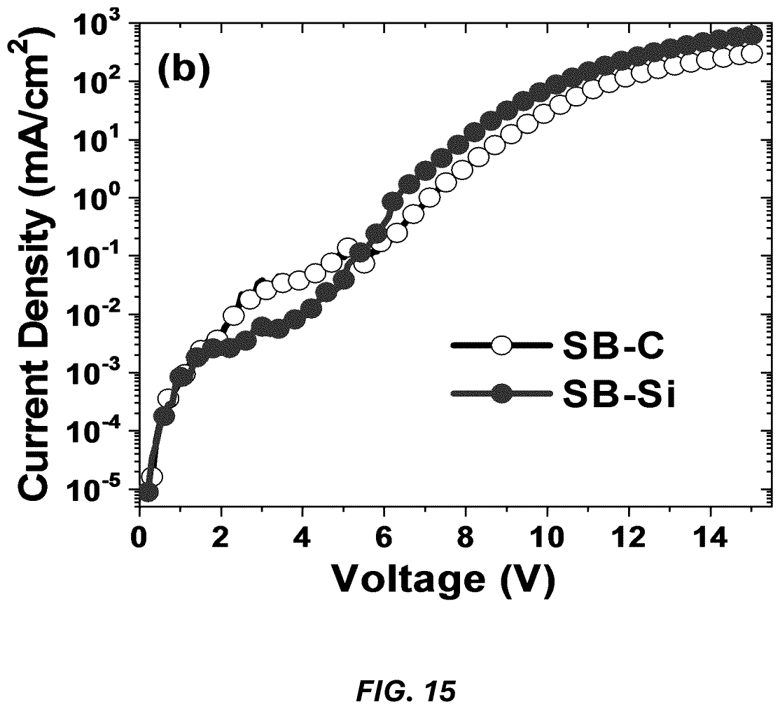

The charge transport properties of SB—C and SB—Si were evaluated by comparing the performance of undoped OLED devices fabricated with the structure: ITO/NPD (30 nm)/mCP (10 nm)/SB—C or —Si host (20 nm)/Alq₃ (20 nm)/LiF (1 nm)/Al (100 nm) (FIG. 13). The electroluminescence (EL) spectra of each host is voltage dependent in the range 8 V-15 V for both SB—C and SB—Si (FIG. 13). With increasing voltage, emission from NPD increases whereas emission from Alq₃ decreases. However, the SB—C device gives predominant emission from NPD in the whole range examined potentials, whereas the SB—Si device displays predominant emission from Alq₃ (FIG. 14). Since these two materials have similar HOMO and LUMO energies, the devices should have similar charge injection barrier for holes and electrons. Thus, the different EL spectra of these two materials may come about from the difference in the carrier mobilities in the two materials. The current voltage (J-V) characteristics of these two devices are shown in FIG. 15. A larger current was observed for the SB—Si device at high voltage. This difference could be because the SB—Si film has a higher percentage of aromatics rings in close enough proximity to facilitate charge transfer than does SB—C. This is consistent with the Hirshfeld surface calculations, which suggest that SB—Si has a larger proportion of C—C intermolecular interactions in the crystalline state.

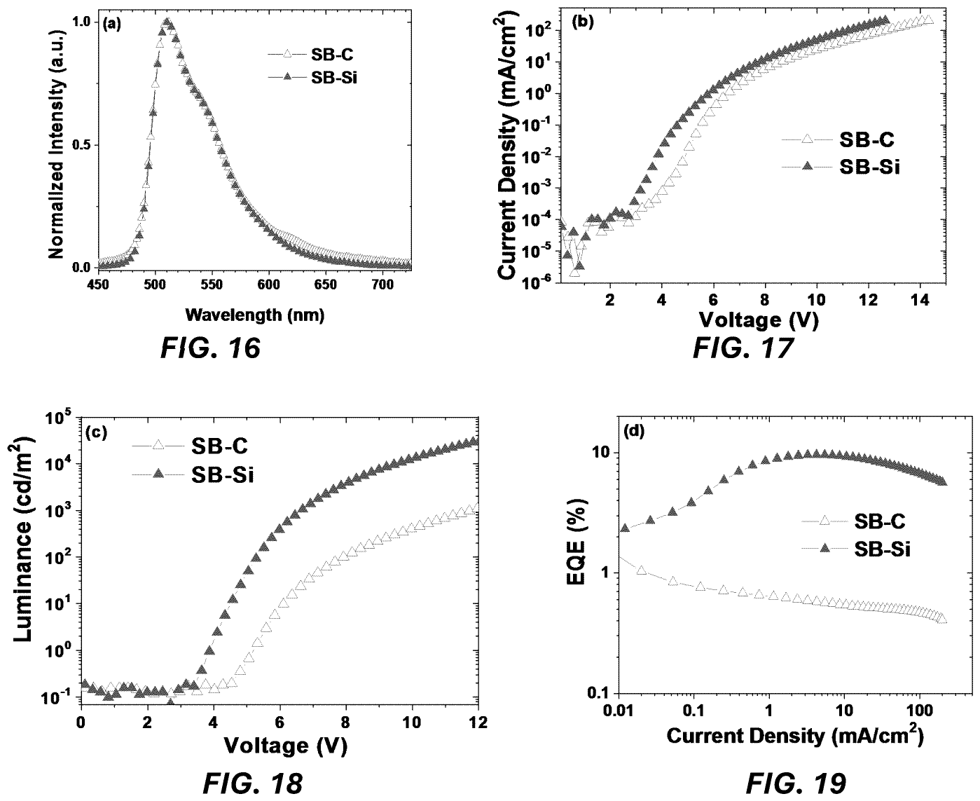

Phosphorescent devices using the green emissive dopant tris(2-phenylpyridyl)iridium(III) Ir(ppy)₃ were fabricated to investigate the properties of two hosts in PHOLEDs. The device structure chosen for these devices was: ITO/HATCN (10 nn)/NPD (30 nm)/(9% Jr(ppy)₃: SB—C or —Si host (30 nm)/BAlq (10 nn)/Alq₃ (40 nn)/LiF (1 nm)/Al (100 nm), using hexaazatriphenylenehexacarbonitrile (HATCN) as a hole injection material and bis(2-methyl-8-quinolinolato-N,O)-(1,1′-biphenyl-4-olato)aluminum (BAlq) as a hole blocking material. The performance of these two devices is summarized in Table 4. The EL spectra of these two devices are shown in FIG. 16. Both devices achieve good charge balance at the emissive layer, leading to pure Ir(ppy)₃ emission at 511 nm. The current density-voltage-luminance (J-L-V) characteristics of these two devices are shown in FIGS. 17 and 18. A higher current density and brightness is found at all voltages for the SB—Si device than for the SB—C device. Correspondingly, the SB—Si device turns on at a lower voltage (Vₜᵤᵣₙ₋ₒₙ=3.9 V) than the SB—C device (Vₜᵤᵣₙ₋ₒₙ=5.2 V). The device with the SB—Si host shows a maximum external quantum efficiency (EQE) of 9.6% at a current density of 4.24 mA/cm², whereas the maximum EQE of the SB—C device is only 1.2% (FIG. 19).

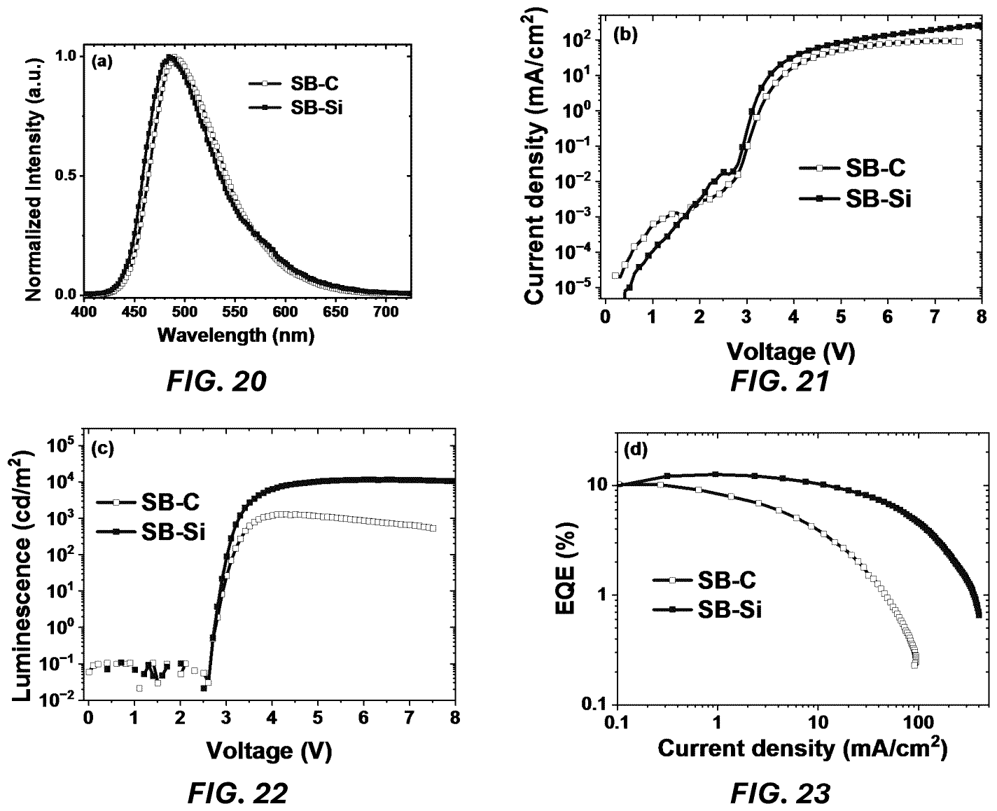

The two hosts materials were also examined in blue PHOLED devices using tris(N,N-di-p-tolyl-pyrazinoimidazol-2-yl)iridium(III) (Jr(tpz)3) as the phosphorescent emitter (Idris, M., et al., Advanced Optical Materials 2021, 9 (8), 2001994). A doping weight percentage of 20% was used in the SB—C and SB—Si hosts fabricated using the device structure: ITO/HATCN (5 nm)/TAPC (40 nm)/SB—C or —Si (10 nm)/(20% Ir(tpz)3 SB—C or —Si host, 25 nm)/BP4mPY (60 nm)/LiF (1 nn)/Al (100 nm). The performance of these two devices is summarized in Table 4. Here di-[4-(N,N-di-p-tolyl-amino)-phenyl]cyclohexane (TAPC) was used as a hole transporting layer, 3,3′,5,5′-tetra[(m-pyridyl)-phen-3-yl]biphenyl (BP4mPY) was used as an electron transporting layer, and the 10 nm undoped host was used as an electron blocking layer. Electroluminescence only from Ir(tpz)₃ was observed for both SB—C and SB—Si devices (FIG. 20). The SB—Si device exhibits higher current conduction and luminance than the SB—C device at any given voltage (FIGS. 21 and 22). For example, at 4 V the SB—C device gives a current density of 17.8 mA/cm² and a luminance of 1200 cd/m², whereas the SB—Si device reaches two times of the current (35 mA/cm²) and five times of the luminance (6300 cd/m²). The SB—C device reaches its highest efficiency (EQE=10.2%) with a current density of 0.01 mA/cm² (FIG. 23). A significant decrease of the external efficiency was observed in the SB—C device starting from a current density of 0.7 mA/cm², which could be due to triplet-triplet annihilation. The SB—Si device reaches its maximum external quantum efficiency (12.6%) at current of 1 mA/cm² and no significant drop in EQE was observed for this device until the current density increased to 10 mA/cm² (FIG. 23). Overall, devices using the SB—Si host exhibited superior conductivity, higher luminance and enhanced EQE at any given voltage over devices using the SB—C host. These improvements can be attributed to the increased intermolecular C—C interactions in SB—Si, as suggested by the calculated and photophysical data.

TABLE 4
Summary of OLED performance.

| | Vₜᵤᵣₙ₋ₒₙ^{a} | EQEₘₐₓ | @ 1000 cd m⁻² | | |
|---|---|---|---|---|---|
| EML | (V) | (%) | EQE (%) | J (mA/cm²) | λₘₐₓ (nm), CIE |

9 wt % Ir(ppy)₃

| | | | | | |
|---|---|---|---|---|---|
| SB-C | 5.2 | 1.2 | 0.6 | 61.9 | 511, (0.28, 0.61) |
| SB-Si | 3.9 | 9.6 | 9.6 | 3.2 | 512, (0.28, 0.63) |

20 wt % Ir(tpz)₃

| | | | | | |
|---|---|---|---|---|---|
| SB-C | 2.8 | 10.2 | 3.6 | 11.4 | 488, (0.26, 0.54) |
| SB-Si | 2.8 | 12.6 | 11.7 | 4.4 | 483, (0.20, 0.43) |

### SUMMARY

In this work, two spirobifluorenyl compounds, SB—C and SB—Si, were designed as host materials and analyzed for their chemical composition, optoelectronic properties and performance in OLED devices. Both compounds have large HOMO/LUMO gaps (5.0±0.2 eV) and high triplet energies (2.8 eV). Despite their similarities, Hirshfeld surface calculations and photophysical analysis of compounds in the solid-state reveal that SB—Si exhibits more intermolecular C—C interactions than does SB—C. In both undoped devices and PHOLED devices, the SB—Si material demonstrated superior charge transporting abilities compared to the SB—C, as indicated by better current conduction and higher brightness. These findings illustrate the relationship between material morphology and properties, and their impact on charge transport in PHOLED devices. Furthermore, while triplet-triplet annihilation occurred in all SB—C doped devices, an external quantum efficiency of 10.2% was still achieved for its blue Ir(tpz)₃ device. Deleterious dopant aggregation was effectively suppressed in the SB—Si devices, leading to high efficiencies for green Ir(ppy)₃ (EQE=9.6%) and blue It(tpz)₃ (EQE=12.6%) devices, with negligible roll-off below 40 mA/cm². Overall, the results highlight the potential of SiPh₃ substituted spirobifluorenyl materials for use in PHOLED devices and underscore the importance of carefully considering material morphology and intermolecular interactions in optimizing device performance.

### Materials and Methods

### Synthesis

All chemicals and solvents were purchased from commercial sources without further purification except for tetrahydrofuran (THF) that had been distilled over sodium/benzophenone.

Triphenyl-9,9-spirobifluoren-2-yl silane (SB—Si). To a solution of 0.78 g (2 mmol) 2-Bromo-9,9-spirobifluorene (1) in dry THF was added 1.38 ml (2.2 mmol) nBuLi (1.6 M in hexanes) under N₂ atmosphere to get an orange solution. Triphenylchlorosilane (0.56 g, 1.9 mmol) was initially weighed and dissolved in THF under N₂ atmosphere and was added using syringe into the solution after 1 hour. The solution was stirred overnight. Ethyl acetate and water were used to extract the organic layer, which was later dried over brine and magnesium sulfate. Organic solvents were reduced by rotary evaporation to get orange liquid of the product which was recrystallized in CH₂Cl₂ to get 0.89 g white solids.

Triphenyl-9,9-spirobifluoren-2-yl methane (SB—C). A solution of 1.74 gl was added dropwise to Mg in 8 ml THF. A solution of benzylphenone in 4 ml THF was slowly added into the prepared Grignard reagent at room temperature and the mixture was refluxed for three hours. After cooled down to the room temperature, ammonium chloride was used to quench the reaction. The organic layer was extracted by DCM and dried over MgSO₄. After the solvent was removed using rotary evaporation, a silica gel column with DCM/hexanes (1:3) was performed to give 1.63 white solids of diphenyl-spirobifluorenyl methanol (3), Yield: 81%. 3 (3.17 mmol, 1.58 g) was refluxed with aniline (4.8 mmol, 0.44 ml), HCl (0.5 ml) and acetic acid (10 ml) at 140° C. for 3 days. The reaction mixture was allowed to cool down to the room temperature and 100 ml water was added. NaOH solid was added until the solution becomes neutral. The product was filtered out as 1.65 g white solids of diphenylspirobifluorenylaniline methane (4). To a solution of 0.57 g 4 in 30 ml THF, a solution of 6 mmol H₃PO₂ in H₂O (0.5 ml) was added. After stirring for 10 mins, a solution of tBuONO in 5 ml THF was added and the mixture was stirred for 16 hrs at 40° C. After the THF was removed, the reaction mixture was extracted by DCM and water. The organic layer was washed by brine and dried over MgSO₄. After the solvent was removed with reduced pressure, recrystallization was performed to give 2.51 g white solids of the product.

¹H NMR, mass spectrometry and elemental analysis data of these compounds are shown as follows:

Triphenyl-9,9-spirobifluoren-2-yl silane (SB—Si) Yield: 78%. ¹H NMR (CDCl₃, 250 Hz): δ 7.80-7.87 (2H, dd, Ar—H), 7.74-7.78 (2H, d, Ar—H), 7.45-7.49 (1H, d, Ar—H), 7.29-7.41 (12H, m, Ar—H), 7.20-7.27 (6H, m, Ar—H), 7.08-7.15 (4H, dd, Ar—H), 7.05 (1H, s, Ar—H), 6.75-6.79 (2H, d, Ar—H), 6.71-6.75 (1H, d, Ar—H). MS (m/z): 574, 497, 316, 259. Ana. Calcd. for C₄₃H₃₀Si: C 89.85 H 5.26; Found: C 90.07 H 5.12.

Diphenyl-9,9-spirobifluoren-2-yl methanol (3), Yield: 81%. ¹H NMR (CDCl₃, 400 Hz) δ: 7.79-7.81 (1H, d, Ar—H), 7.77-7.79 (2H, d, Ar—H), 7.69-7.71 (1H, d, Ar—H), 7.33-7.38 (1H, d, Ar—H), 7.31-7.36 (2H, dd, Ar—H), 7.18-7.22 (4H, d, Ar—H), 7.18-7.21 (2H, dd, Ar—H), 7.12-7.17 (4H, dd, Ar—H), 7.04-7.10 (1H, dd, Ar—H), 6.92 (1H, s, Ar—H), 6.72-6.75 (2H, d, Ar—H), 6.67-6.70 (1H, d, Ar—H). ¹³C NMR (400 Hz): MS (m/z): 498, 482, 421, 315.

p-(Diphenyl-9,9-spirobifluoren-2-yl)methyl aniline (4), Yield: 91%. ¹H NMR (CDCl₃, 250 Hz): δ 7.75-7.79 (1H, d, Ar—H) 7.69-7.73 (2H, d, Ar—H), 7.25-7.32 (3H, m, Ar—H), 7.21-7.24 (1H, d, Ar—H), 7.01-7.10 (H, m, Ar—H), 6.80-6.83 (2H, d, Ar—H), 6.68-6.71 (2H, d, Ar—H), 6.65-6.68 (1H, d, Ar—H), 6.56-6.58 (1H, s, Ar—H), 6.40-6.43 (2H, d, Ar—H). MS (m/z): 572, 481, 258.

Triphenyl-9,9-spirobifluoren-2-yl methane (SB—C), Yield: 45%. ¹H NMR (CDCl₃, 400 Hz) δ: 7.76-7.79 (1H, d, Ar—H), 7.71-7.73 (2H, dd, Ar—H), 7.68-7.70 (1H, d, Ar—H), 7.30-7.34 (1H, dd, Ar—H), 7.27-7.31 (2H, dd, Ar—H), 7.23-7.26 (1H, d, Ar—H), 7.03-7.12 (18H, m, Ar—H), 6.68-6.70 (2H, d, Ar—H), 6.62-6.68 (1H, d, Ar—H), 6.55 (1H, s, Ar—H). MS (m/z): 558, 481, 403, 316. Ana. Calcd. for C₄₄H₃₀: C 94.59 H 5.41; Found: C 94.45; H 5.31.

### X-ray Crystallography

X-ray quality crystals were grown as indicated in the experimental procedures for each complex, and the crystals were mounted on a nylon fiber with Paratone-N oil. All Crystals were measured at 100K with a Rigaku Xta LAB Synergy S, equipped with an HyPix-600HE detector and an Oxford Cryostream 800 low Temperature unit, using Cu Ka PhotonJet-S X-ray source. The frames were integrated using the SAINT algorithm to give the hkl files. Data were corrected for absorption effects using the multi-scan method (SADABS) with Rigaku CrysalisPro. The structures were solved by intrinsic phasing and refined with the SHELXTL Software Package.4. Structures of SB—C and SB—Si were deposited in the CCDC (U.S. Pat. Nos. 2,221,201 and 2,216,982 reciprocally). The crystallographic data for these compounds are presented in Table 5.

TABLE 5
Crystallographic Data for Ph₃CSBFL and Ph₃SiSBFL

| Identification code | Ph₃CSBFL | Ph₃SiSBFL |
|---|---|---|
| Empirical formula | C₄₄H₃₀ | C₄₃H₃₀Si |
| Formula weight | 558.68 | 574.76 |
| Temperature/K | 101(1) | 102(2) |
| Crystal system | Monoclinic | monoclinic |
| Space group | P2₁/n | P2₁/n |
| a/Å | 13.2736(3) | 13.54470(12) |
| b/Å | 9.03871(19) | 9.29422(8) |
| c/Å | 24.5142(6) | 24.5334(2) |
| α/° | 90 | 90 |
| β/° | 91.929(2) | 91.1600(8) |
| γ/° | 90 | 90 |
| Volume/Å³ | 2939.45(11) | 3087.81(5) |
| Z | 4 | 4 |
| ρ_{calc}g/cm³ | 1.262 | 1.236 |
| μ/mm¹ | 0.541 | 0.888 |
| F(000) | 1176.0 | 1208.0 |
| Crystal size/mm³ | 0.164 × 0.11 × 0.039 | 0.576 × 0.201 × 0.1 |
| Radiation | Cu Kα (λ = 1.54184) | Cu Kα (λ = 1.54184) |
| 2Θ range for data collection/° | 7.216 to 160.454 | 7.208 to 160.704 |
| Index ranges | −16 ≤ h ≤ 16, −11 ≤ | −17 ≤ h ≤ 16, −8 ≤ |
| | k ≤ 7, −31 ≤ l ≤ 30 | k ≤ 11, −31 ≤ l ≤ 31 |
| Reflections collected | 23585 | 49890 |
| Independent reflections | 6180 [Rᵢₙₜ = 0.0386, | 6740 [Rᵢₙₜ = 0.0498, |
| | R_{sigma} = 0.0349] | R_{sigma} = 0.0289] |
| Data/restraints/parameters | 6180/0/398 | 6740/0/398 |
| Goodness-of-fit on F² | 1.051 | 1.057 |
| Final R indexes [I >= 2σ (I)] | R₁ = 0.0408, wR₂ = 0.1035 | R₁ = 0.0390, wR₂ = 0.1011 |
| Final R indexes [all data] | R₁ = 0.0489, wR₂ = 0.1078 | R₁ = 0.0418, wR₂ = 0.1032 |
| Largest diff. peak/hole/e Å⁻³ | 0.30/−0.21 | 0.45/−0.35 |
| #CCDC | 2221201 | 2216982 |

### Thermal Analysis

Differential Scanning Calorimetry (DSC) was performed on a TA Instruments DSC Q10 instrument with a scanning range from room temperature to 300° C. The sample was first scanned at a heating rate of 10° C. min⁻¹ and was cooled down to room temperature rapidly using liquid N₂. The second and third scans were performed at a heating rate of 5° C. min⁻¹. The glass transition temperatures were determined from either the second or the third scan for each compound.

### Electrochemistry

Cyclic voltammetry was performed using an EG&G potentiostat/galvanostat model 283 under N₂ atmosphere. A glass carbon rod was used as the working electrode. Tetrabutylammonium hexafluorophosphate (TBAH, 0.1 M) was used as the supporting electrolyte. Anhydrous acetonitrile was used as the solvent for the oxidation measurements and anhydrous DMIF was used as the solvent for the reduction measurements. The redox potentials are calculated relative to an internal reference ferrocenium/ferrocene (Cp₂Fe+/Cp₂Fe). The UV-visible spectra were measured by Hewlett-Packard 4853 diode array spectrophotometer. Singlet and triplet emission measurements were performed on a Photon Technology International QuantaMaster model C-60SE spectrofluorimeter at room temperature and 77 K.

### Device Fabrication

OLED devices were fabricated on pre-patterned ITO-coated glass substrates (20±5 Ω cm2, Thin Film Devices, Inc.). Prior to deposition, the substrates were cleaned with soap, rinsed with deionized water, and sonicated for 10 minutes. Afterwards, two subsequent rinses and 15-minute sonication baths were performed in acetone and isopropyl alcohol sequentially, followed by 10 min UV ozone exposure. EVO Vac 800 deposition system from Angstrom Engineering, at ˜6×10-7 Torr. Current-voltage-luminescence (J-V-L) curves were measured in an inert atmosphere by using a Keithley power source meter model 2400 and a Newport multifunction optical model 1835-C, PIN-220DP/SB blue enhanced silicon photodiodes (OSI optoelectronics Ltd.). Electroluminescence (EL) spectra of OLEDs were measured using the fluorimeter (model C-60 Photon Technology International QuantaMaster) at several different voltages. Thicknesses were determined on Silicon wafers using a Filmsense FS-1 Ellipsometer.

It is understood that the various embodiments described herein are by way of example only, and are not intended to limit the scope of the invention. For example, many of the materials and structures described herein may be substituted with other materials and structures without deviating from the spirit of the invention. The present invention as claimed may therefore include variations from the particular examples and preferred embodiments described herein, as will be apparent to one of skill in the art. It is understood that various theories as to why the invention works are not intended to be limiting.

What is claimed is:

1. A compound of Formula I: 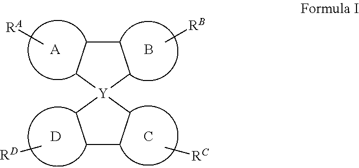
wherein ring A, ring B, ring C, and ring D are each independently a 5- or 6-membered aromatic or heteroaromatic ring;
Y is Si or C;
R^{A}, R^{B}, R^{C}, and R^{D} each represents mono to the maximum allowable substitution, or no substitution;
each R^{A}, R^{B}, R^{C}, and R^{D} are independently hydrogen or a substituent selected from the group consisting of deuterium, alkyl, haloalkyl, cycloalkyl, heteroalkyl, heterocycloalkyl, arylalkyl, alkoxy, aryloxy, silyl, alkenyl, cyano, cycloalkenyl, heteroalkenyl, alkynyl, aryl, heteroaryl, acyl, carboxylic acid, ether, ester, nitro, nitrile, isonitrile, sulfanyl, sulfinyl, sulfonyl, phosphino, and combinations thereof; wherein any two adjacent R^{A}, R^{B}, R^{C}, and R^{D} may optionally join to form a fused ring, which is optionally further substituted;
wherein at least one of R^{A}, R^{B}, R^{C}, and R^{D} represents a group of Formula A: 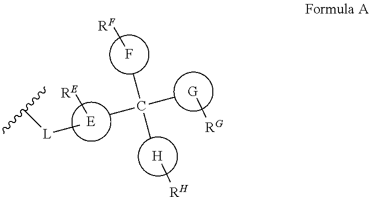
wherein ring E, ring F, ring G, and ring H are each independently an aromatic or heteroaromatic ring;
the wavy line represents connection to Formula I;
L represents a divalent linker or a single bond; wherein when L represents a single bond, ring E is directly connected to Formula I;
R^{E}, R^{F}, R^{G}, and R^{H} each represents mono to the maximum allowable substitution, or no substitution;
each R^{E}, R^{F}, R^{G}, and R^{H} are independently hydrogen or a substituent selected from the group consisting of deuterium, halogen, alkyl, cycloalkyl, heteroalkyl, heterocycloalkyl, arylalkyl, alkoxy, aryloxy, amino, silyl, alkenyl, cyano, cycloalkenyl, heteroalkenyl, alkynyl, aryl, heteroaryl, acyl, carboxylic acid, ether, ester, nitro, nitrile, isonitrile, sulfanyl, sulfinyl, sulfonyl, phosphino, and combinations thereof; provided that no two adjacent R^{E}, R^{F}, R^{G}, and R^{H} join to form a fused ring.

2. The compound of claim 1, wherein at least one of ring A, ring B, ring C, and ring D is a 5-membered aromatic ring.

3. The compound of claim 1, wherein at least one of ring E, ring F, ring G, and ring H is a 5-membered aromatic ring

4. The compound of claim 1, wherein each of ring A, ring B, ring C, ring D, ring E, ring F, ring G, and ring H represents a phenyl ring.

5. The compound of claim 1, wherein at least one of R^{A}, R^{B}, R^{C}, or R^{D} is deuterium, F, an alkyl, cycloalkyl, aryl, heteroaryl, or a combination thereof.

6. The compound of claim 1, wherein at least one of R^{A}, R^{B}, R^{C}, R^{D}, R^{E}, R^{F}, R^{G}, or R^{H} is deuterium.

7. The compound of claim 1, wherein Y is C.

8. The compound of claim 1, wherein Y is Si.

9. The compound of claim 1, wherein the compound is represented by one of the following structures:

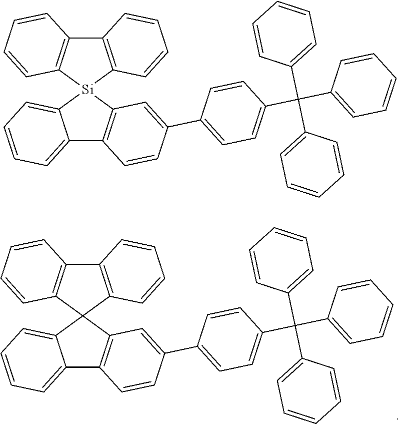

10. An organic light emitting device (OLED) comprising:
an anode;
a cathode; and
an organic layer disposed between the anode and the cathode,
wherein the organic layer comprises a compound of Formula I: 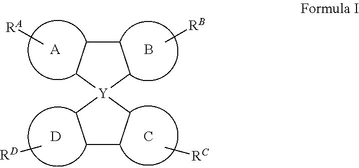
wherein ring A, ring B, ring C, and ring D are each independently a 5- or 6-membered aromatic or heteroaromatic ring;
Y is Si or C;
R^{A}, R^{B}, R^{C}, and R^{D} each represents mono to the maximum allowable substitution, or no substitution;
each R^{A}, R^{B}, R^{C}, and R^{D} are independently hydrogen or a substituent selected from the group consisting of deuterium, alkyl, haloalkyl, cycloalkyl, heteroalkyl, heterocycloalkyl, arylalkyl, alkoxy, aryloxy, silyl, alkenyl, cyano, cycloalkenyl, heteroalkenyl, alkynyl, aryl, heteroaryl, acyl, carboxylic acid, ether, ester, nitro, nitrile, isonitrile, sulfanyl, sulfinyl, sulfonyl, phosphino, and combinations thereof; wherein any two adjacent R^{A}, R^{B}, R^{C}, and R^{D} may optionally join to form a fused ring, which is optionally further substituted;
wherein at least one of R^{A}, R^{B}, R^{C}, and R^{D} represents a group of Formula A: 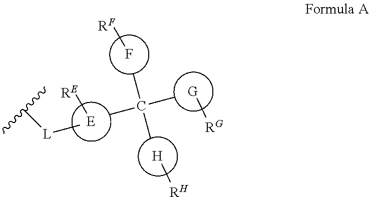
wherein ring E, ring F, ring G, and ring H are each independently an aromatic or heteroaromatic ring;
the wavy line represents connection to Formula I;
L represents a divalent linker or a single bond; wherein when L represents a single bond, ring E is directly connected to Formula I;
R^{E}, R^{F}, R^{G}, and R^{H} each represents mono to the maximum allowable substitution, or no substitution;
each R^{E}, R^{F}, R^{G}, and R^{H} are independently hydrogen or a substituent selected from the group consisting of deuterium, halogen, alkyl, cycloalkyl, heteroalkyl, heterocycloalkyl, arylalkyl, alkoxy, aryloxy, amino, silyl, alkenyl, cyano, cycloalkenyl, heteroalkenyl, alkynyl, aryl, heteroaryl, acyl, carboxylic acid, ether, ester, nitro, nitrile, isonitrile, sulfanyl, sulfinyl, sulfonyl, phosphino, and combinations thereof; provided that no two adjacent R^{E}, R^{F}, R^{G}, and R^{H} join to form a fused ring.

11. The OLED of claim 10, wherein the organic layer is an emissive layer and the compound can be an emissive dopant or a non-emissive dopant.

12. The OLED of claim 10, wherein the organic layer is selected from the group consisting of a hole injection layer, hole transporting layer, electron blocking layer, emissive layer, hole blocking layer, electron transport layer, and electron injection layer.

13. The OLED of claim 10, wherein the compound is a host, and the organic layer is an emissive layer that comprises a phosphorescent emitter.

14. The OLED of claim 13, wherein the phosphorescent emitter is a transition metal complex having at least one ligand or part of the ligand if the ligand is more than bidentate selected from the group consisting: 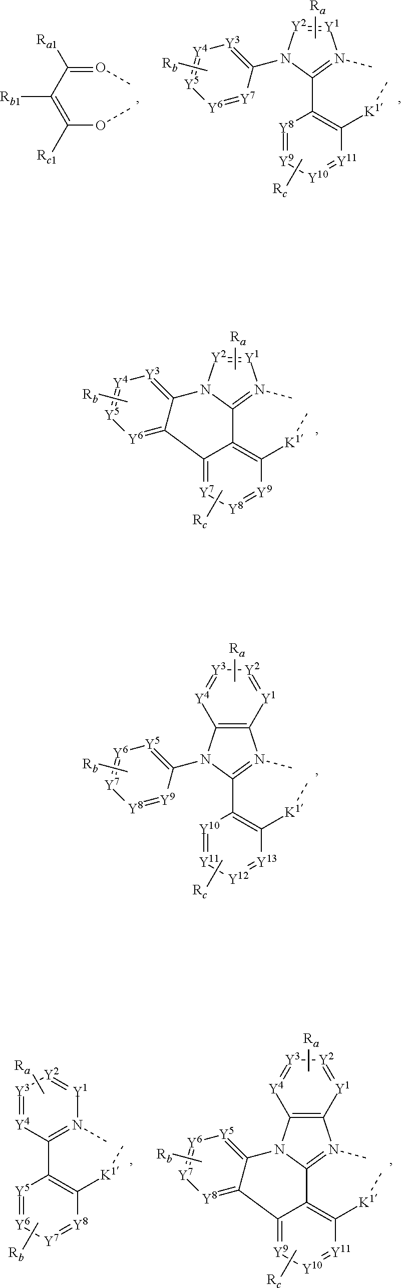 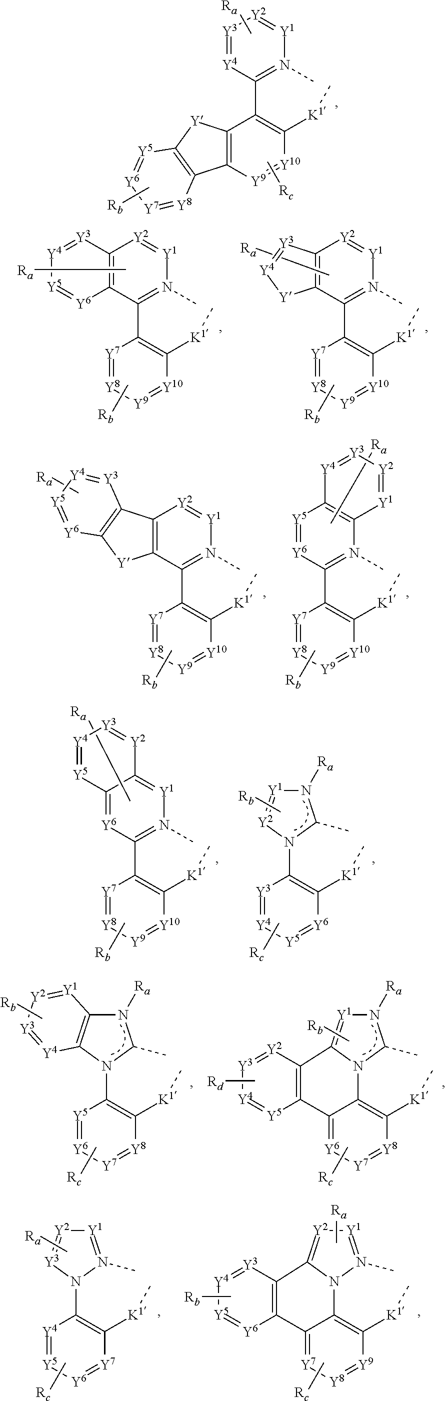 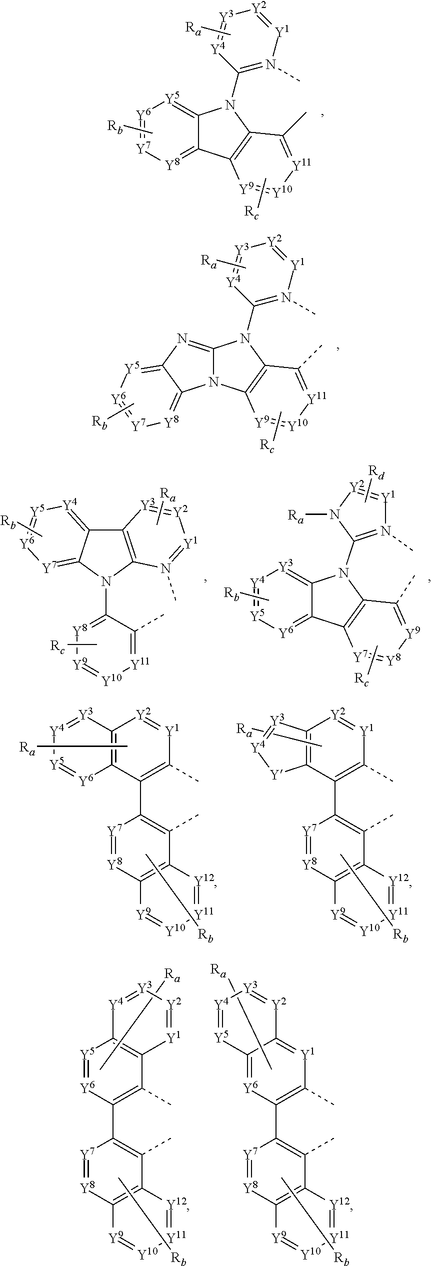 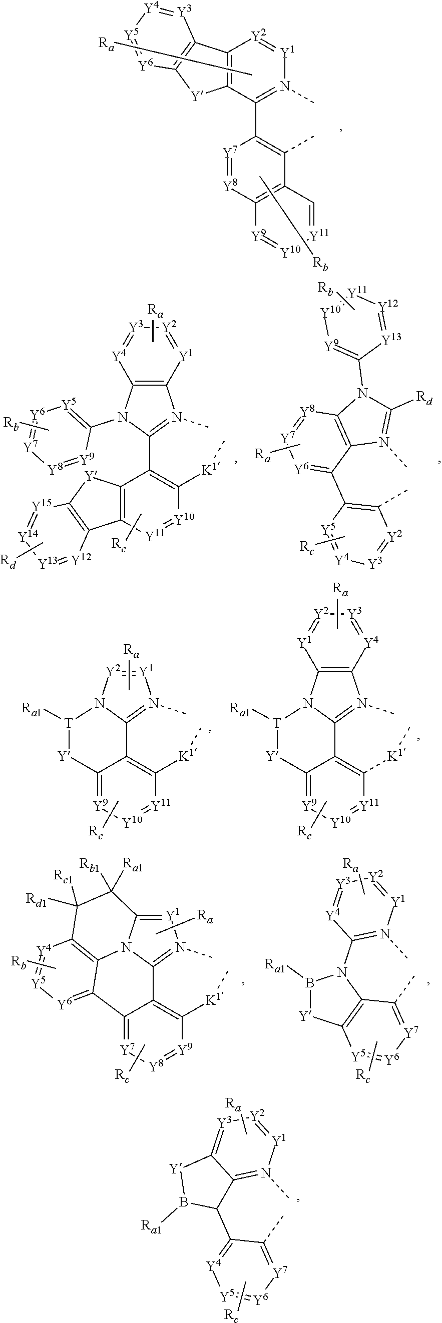 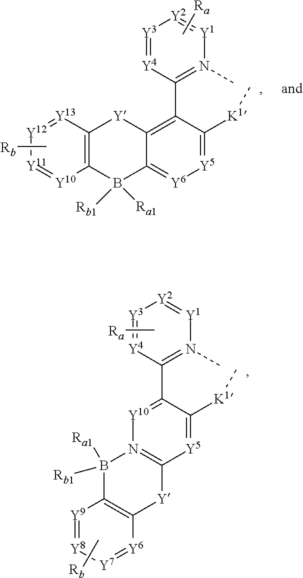
T is selected from the group consisting of B, Al, Ga, and In;
K¹′ is selected from the group consisting of a single bond, O, S, NRₑ, PRₑ, BRₑ, CRₑR_{f}, and SiRₑR_{f};
each of Y¹ to Y¹³ is independently selected from the group consisting of C and N;
Y′ is selected from the group consisting of BRₑ, BRₑR_{f}, NRₑ, PRₑ, P(O)Rₑ, O, S, Se, C═O, C═S, C═Se, C═NRₑ, C═CRₑR_{f}, S═O, SO₂, CRₑR_{f}, SiRₑR_{f}, and GeRₑR_{f};
Rₑ and R_{f} can be fused or joined to form a ring;
each Rₐ, R_{b}, R_{c}, and R_{d} independently represents from mono to the maximum allowed number of substitutions, or no substitution;
each of Rₐ₁, R_{b1}, R_{c1}, R_{d1}, Rₐ, R_{b}, R_{c}, R_{d}, Rₑ, and R_{f} is independently a hydrogen or a subsituent selected from the group consisting of deuterium, halide, alkyl, cycloalkyl, heteroalkyl, arylalkyl, alkoxy, aryloxy, amino, silyl, germyl, boryl, alkenyl, cycloalkenyl, heteroalkenyl, alkynyl, aryl, heteroaryl, acyl, carbonyl, carboxylic acid, ester, nitrile, isonitrile, sulfanyl, selenyl, sulfinyl, sulfonyl, phosphino, and combinations thereof; and
any two substituents of Rₐ₁, R_{b1}, R_{c1}, R_{d1}, Rₐ, R_{b}, R_{c}, and R_{d} can be fused or joined to form a ring or form a multidentate ligand.

15. The OLED of claim 10, wherein the compound is an acceptor, and the OLED further comprises a sensitizer selected from the group consisting of a delayed fluorescence emitter, a phosphorescent emitter, and combination thereof.

16. The OLED of claim 10, wherein the compound is a fluorescent emitter, a delayed fluorescence emitter, or a component of an exciplex that is a fluorescent emitter or a delayed fluorescence emitter.

17. A consumer product comprising an organic light-emitting device (OLED) comprising:
an anode;
a cathode; and
an organic layer disposed between the anode and the cathode,
wherein the organic layer comprises a compound of Formula I: 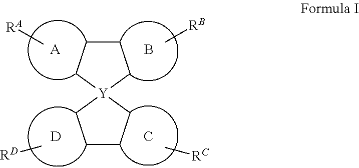
wherein ring A, ring B, ring C, and ring D are each independently a 5- or 6-membered aromatic or heteroaromatic ring;
Y is Si or C;
R^{A}, R^{B}, R^{C}, and R^{D} each represents mono to the maximum allowable substitution, or no substitution;
each R^{A}, R^{B}, R^{C}, and R^{D} are independently hydrogen or a substituent selected from the group consisting of deuterium, alkyl, haloalkyl, cycloalkyl, heteroalkyl, heterocycloalkyl, arylalkyl, alkoxy, aryloxy, silyl, alkenyl, cyano, cycloalkenyl, heteroalkenyl, alkynyl, aryl, heteroaryl, acyl, carboxylic acid, ether, ester, nitro, nitrile, isonitrile, sulfanyl, sulfinyl, sulfonyl, phosphino, and combinations thereof; wherein any two adjacent R^{A}, R^{B}, R^{C}, and R^{D} may optionally join to form a fused ring, which is optionally further substituted;
wherein at least one of R^{A}, R^{B}, R^{C}, and R^{D} represents a group of Formula A: 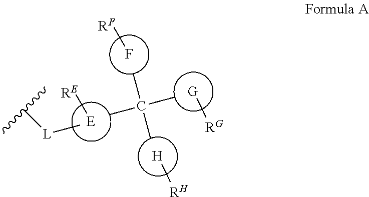
wherein ring E, ring F, ring G, and ring H are each independently an aromatic or heteroaromatic ring;
the wavy line represents connection to Formula I;
L represents a divalent linker or a single bond; wherein when L represents a single bond, ring E is directly connected to Formula I;
R^{E}, R^{F}, R^{G}, and R^{H} each represents mono to the maximum allowable substitution, or no substitution;
each R^{E}, R^{F}, R^{G}, and R^{H} are independently hydrogen or a substituent selected from the group consisting of deuterium, halogen, alkyl, cycloalkyl, heteroalkyl, heterocycloalkyl, arylalkyl, alkoxy, aryloxy, amino, silyl, alkenyl, cyano, cycloalkenyl, heteroalkenyl, alkynyl, aryl, heteroaryl, acyl, carboxylic acid, ether, ester, nitro, nitrile, isonitrile, sulfanyl, sulfinyl, sulfonyl, phosphino, and combinations thereof; provided that no two adjacent R^{E}, R^{F}, R^{G}, and R^{H} join to form a fused ring.

18. The consumer product of claim 17, wherein the consumer product is selected from the group consisting of a flat panel display, a computer monitor, a medical monitor, a television, a billboard, a light for interior or exterior illumination and/or signaling, a heads-up display, a fully or partially transparent display, a flexible display, a laser printer, a telephone, a cell phone, tablet, a phablet, a personal digital assistant (PDA), a wearable device, a laptop computer, a digital camera, a camcorder, a viewfinder, a micro-display that is less than 2 inches diagonal, a 3-D display, a virtual reality or augmented reality display, a vehicle, a video wall comprising multiple displays tiled together, a theater or stadium screen, a light therapy device, and a sign.

19. A formulation comprising a compound according to claim 1.

20. A chemical structure selected from the group consisting of a monomer, a polymer, a macromolecule, and a supramolecule, wherein the chemical structure comprises a compound according to claim 1 or a monovalent or polyvalent variant thereof.
